(19) United States
(12) Patent Application Publication
(10) Pub. No.: US 2025/0079798 A1
(43) Pub. Date: Mar. 6, 2025

(54) SURFACE EMITTING DEVICE, LIGHT SOURCE DEVICE, AND METHOD FOR MANUFACTURING SURFACE EMITTING DEVICE

(71) Applicant: SONY GROUP CORPORATION, TOKYO (JP)

(72) Inventors: KOICHI SATO, TOKYO (JP); SHOETSU NAGANE, TOKYO (JP); TATSUSHI HAMAGUCHI, TOKYO (JP); KENTARO HAYASHI, TOKYO (JP); EIJI NAKAYAMA, TOKYO (JP)

(21) Appl. No.: 18/730,262

(22) PCT Filed: Dec. 8, 2022
(86) PCT No.: PCT/JP2022/045300

§ 371 Date: Jul. 18, 2024

(30) Foreign Application Priority Data
Jan. 27, 2022 (JP) 2022-011249

(51) Int. Cl. H01S 5/183

(52) U.S. Cl. CPC H01S 5/18361

(57) ABSTRACT

Provided is a surface emitting device that can restrain increase in the misalignment between a current injection region of a light emission layer and a concave mirror. The surface emitting device provided according to the present technology includes a substrate, a first structure provided on one surface of the substrate and including a light emission layer, and a second structure provided on another surface of the substrate and including a concave mirror, the substrate is transparent to a prescribed wavelength, the first structure has an opaque part and a transparent part with respect to the prescribed wavelength, and the first and second structures have substantially similar forms in plan view and their centers of gravity do not coincide.

### TECHNICAL FIELD

The technology according to the present disclosure (hereinafter, also referred to as the “present technology”) relates to a surface emitting device, a light source device, and a method for manufacturing the surface emitting device.

### BACKGROUND ART

Conventional surface emitting devices including a light emission layer and a concave mirror have been known (see, for example, PTL 1). In such devices, the light emission region (current injection region) of the light emission layer and the concave mirror are placed on each other during manufacture.

### CITATION LIST

### Patent Literature

### PTL 1

WO 2018/083877

### SUMMARY

### Technical Problem

In the conventional surface emitting devices, however, the light emission region of the light emission layer and the concave mirror may be significantly misaligned from each other.

Therefore, it is a main object of the present technology to provide a surface emitting device having a configuration that can restrain misalignment between the light emission region of the light emission layer and the concave mirror from increasing.

### Solution to Problem

The present technology provides a surface emitting device including a substrate; a first structure provided on one surface of the substrate and including a light emission layer; and
a second structure provided on another surface of the substrate and including a concave mirror,
wherein
the substrate is transparent with respect to a prescribed wavelength,
the first structure has an opaque part and a transparent part with respect to the prescribed wavelength,
the first and second structures have substantially similar forms in plan view, and their centers of gravity are not coincident.

The distance between a center of the light emission region of the light emission layer and a center of the concave mirror may be shorter than the distance between the centers of gravity of the first and second structures in plan view.

The distance between the centers of gravity of the first and second structures may be at least 50 nm in plan view.

The distance between a center of the light emission region of the light emission layer and a center of the concave mirror may be at most 500 nm in plan view.

The second structure may have a plan view shape which is a Fourier transformed shape of a plan view shape of the first structure.

The second structure may have a plan view shape which is a similar form to a Fourier transformed shape of a plan view shape of the first structure, with a coefficient of determination of at least 70%.

The opaque part may have first and second parts arranged in an in-plane direction. The second part may surround the first part.

The opaque part may have a connection part which connects the first and second parts. The connection part may overlap at least one of the first and second parts.

The first structure may have a support substrate connected through a conductive material to the opaque part and/or the transparent part.

The opaque part may be made of dielectric or a metal.

The second structure may include a photosensitive material provided between the other surface and the concave mirror.

The other surface may have a convex surface structure, and the concave mirror may be provided along the convex surface structure.

There may be a plurality of pairs of the first and second structures, wherein the distances between centers of gravity of the plurality of pairs of the first and second structures may be substantially equal in plan view, and separation directions of the centers of gravity of the plurality of pairs of the first and second structures may substantially coincide in plan view.

The first structure may include a reflector provided on a side of the light emission layer opposite to the concave mirror.

The present technology also provides a light source device including the surface emitting device, and
a laser driver connected to the first structure of the surface emitting device through a conductive bump.

The present technology provides a method for manufacturing a surface emitting device including:
forming a first structure including a light emission layer on one surface of a substrate transparent to a prescribed wavelength, the first structure having an opaque part and a transparent part with respect to the prescribed wavelength;
applying a photosensitive material on another surface of the substrate;
performing oblique exposure with light having the prescribed wavelength from the side of the first structure; and
forming a second structure including a concave mirror using a pattern formed on the photosensitive material.

The first structure may include a current constriction region that defines a light emission region of the light emission layer, and in forming the first structure, the current constriction region is formed so that the light emission region is in a position corresponding to an exposure condition in the oblique exposure and a total of the thickness of the first structure and the thickness of the substrate.

The exposure condition may be set according to the total or the total may be set according to the exposure condition.

### BRIEF DESCRIPTION OF DRAWINGS

FIG. 1 is a cross-sectional view of a surface emitting device according to Example 1 of one embodiment of the present technology.

FIG. 2A is a plan view of the surface emitting device shown in FIG. 1. FIG. 2B is a view of a second structure of the surface emitting device in FIG. 1 as viewed from the side of the first structure.

FIG. 3 is a flowchart for illustrating a first example of a method for manufacturing the surface emitting device in FIG. 1.

FIGS. 4A and 4B are cross-sectional views for illustrating the first example of the method for manufacturing the surface emitting device in FIG. 1 for each step.

FIGS. 5A and 5B are cross-sectional views for illustrating the first example of the method for manufacturing the surface emitting device in FIG. 1 for each step.

FIGS. 6A and 6B are cross-sectional views for illustrating the first example of the method for manufacturing the surface emitting device in FIG. 1 for each step.

FIGS. 7A and 7B are cross-sectional views for illustrating the first example of the method for manufacturing the surface emitting device in FIG. 1 for each step.

FIGS. 8A and 8B are cross-sectional views for illustrating the first example of the method for manufacturing the surface emitting device in FIG. 1 for each step.

FIGS. 9A and 9B are cross-sectional views for illustrating the first example of the method for manufacturing the surface emitting device in FIG. 1 for each step.

FIGS. 10A and 10B are cross-sectional views for illustrating the first example of the method for manufacturing the surface emitting device in FIG. 1 for each step.

FIGS. 11A and 11B are cross-sectional views for illustrating the first example of the method for manufacturing the surface emitting device in FIG. 1 for each step.

FIGS. 12A and 12B are cross-sectional views for illustrating the first example of the method for manufacturing the surface emitting device in FIG. 1 for each step.

FIGS. 13A and 13B are cross-sectional views for illustrating the first example of the method for manufacturing the surface emitting device in FIG. 1 for each step.

FIG. 14 is a flowchart for illustrating a second example of the method for manufacturing the surface emitting device in FIG. 1.

FIGS. 15A and 15B are cross-sectional views for illustrating the second example of the method for manufacturing the surface emitting device in FIG. 1 for each step.

FIGS. 16A and 16B are cross-sectional views for illustrating the second example of the method for manufacturing the surface emitting device in FIG. 1 for each step.

FIGS. 17A and 17B are cross-sectional views for illustrating the second example of the method for manufacturing the surface emitting device in FIG. 1 for each step.

FIGS. 18A and 18B are cross-sectional views for illustrating the second example of the method for manufacturing the surface emitting device in FIG. 1 for each step.

FIGS. 19A and 19B are cross-sectional views for illustrating the second example of the method for manufacturing the surface emitting device in FIG. 1 for each step.

FIGS. 20A and 20B are cross-sectional views for illustrating the second example of the method for manufacturing the surface emitting device in FIG. 1 for each step.

FIG. 21 is a cross-sectional view for illustrating the second example of the method for manufacturing the surface emitting device in FIG. 1 for each step.

FIG. 22 is a cross-sectional view of a surface emitting device according to Example 2 of the embodiment of the present technology.

FIG. 23A is a plan view of the surface emitting device in FIG. 22. FIG. 23B is a view of a second structure of the surface emitting device in FIG. 22 as viewed from the side of the first structure.

FIG. 24 is a flowchart for illustrating an example of a method for manufacturing the surface emitting device in FIG. 22.

FIGS. 25A and 25B are cross-sectional views for illustrating the example of the method for manufacturing the surface emitting device in FIG. 22 for each step.

FIGS. 26A and 26B are cross-sectional views for illustrating the example of the method for manufacturing the surface emitting device in FIG. 22 for each step.

FIGS. 27A and 27B are cross-sectional views for illustrating the example of the method for manufacturing the surface emitting device in FIG. 22 for each step.

FIGS. 28A and 28B are cross-sectional views for illustrating the example of the method for manufacturing the surface emitting device in FIG. 22 for each step.

FIGS. 29A and 29B are cross-sectional views for illustrating the example of the method for manufacturing the surface emitting device in FIG. 22 for each step.

FIGS. 30A and 30B are cross-sectional views for illustrating the example of the method for manufacturing the surface emitting device in FIG. 22 for each step.

FIG. 31 is a cross-sectional view of a surface emitting device according to Example 3 of the embodiment of the present technology.

FIG. 32A is a plan view of the surface emitting device in FIG. 31. FIG. 32B is a view of a second structure of the surface emitting device in FIG. 31 from the side of a first structure.

FIG. 33 is a flowchart for illustrating an example of a method for manufacturing the surface emitting device in FIG. 31.

FIGS. 34A and 34B are cross-sectional views for illustrating the example of the method for manufacturing the surface emitting device in FIG. 31 for each step.

FIGS. 35A and 35B are cross-sectional views for illustrating the example of the method for manufacturing the surface emitting device in FIG. 31 for each step.

FIGS. 36A and 36B are cross-sectional views for illustrating the example of the method for manufacturing the surface emitting device in FIG. 31 for each step.

FIGS. 37A and 37B are cross-sectional views for illustrating the example of the method for manufacturing the surface emitting device in FIG. 31 for each step.

FIGS. 38A and 38B are cross-sectional views for illustrating the example of the method for manufacturing the surface emitting device in FIG. 31 for each step.

FIGS. 39A and 39B are cross-sectional views for illustrating the example of the method for manufacturing the surface emitting device in FIG. 31 for each step.

FIG. 40 is a cross-sectional view for illustrating the example of the method for manufacturing the surface emitting device in FIG. 31 for each step.

FIG. 41 is a cross-sectional view of a surface emitting device according to Example 4 of the embodiment of the present technology.

FIG. 42A is a plan view of the surface emitting device in FIG. 41. FIG. 42B is a view of a second structure of the surface emitting device in FIG. 41 as viewed form the side of the first structure.

FIG. 43 is a flowchart for illustrating an example of a method for manufacturing the surface emitting device in FIG. 41.

FIGS. 44A and 44B are cross-sectional views for illustrating the example of the method for manufacturing the surface emitting device in FIG. 41 for each step.

FIGS. 45A and 45B are cross-sectional views for illustrating the example of the method for manufacturing the surface emitting device in FIG. 41 for each step.

FIGS. 46A and 46B are cross-sectional views for illustrating the example of the method for manufacturing the surface emitting device in FIG. 41 for each step.

FIGS. 47A and 47B are cross-sectional views for illustrating the example of the method for manufacturing the surface emitting device in FIG. 41 for each step.

FIGS. 48A and 48B are cross-sectional views for illustrating the example of the method for manufacturing the surface emitting device in FIG. 41 for each step.

FIGS. 49A and 49B are cross-sectional views for illustrating the example of the method for manufacturing the surface emitting device in FIG. 41 for each step.

FIGS. 50A and 50B are cross-sectional views for illustrating the example of the method for manufacturing the surface emitting device in FIG. 41 for each step.

FIGS. 51A and 51B are cross-sectional views for illustrating the example of the method for manufacturing the surface emitting device in FIG. 41 for each step.

FIG. 52 is a cross-sectional view of a surface emitting device according to Example 5 of the embodiment of the present technology.

FIG. 53A is a plan view of the surface emitting device in FIG. 52. FIG. 53B is a view of a second structure of the surface emitting device in FIG. 52 as viewed from the side of the first structure.

FIG. 54 is a flowchart for illustrating an example of a method for manufacturing the surface emitting device in FIG. 52.

FIGS. 55A and 55B are cross-sectional views for illustrating the example of the method for manufacturing the surface emitting device in FIG. 52 for each step.

FIGS. 56A and 56B are cross-sectional views for illustrating the example of the method for manufacturing the surface emitting device in FIG. 52 for each step.

FIGS. 57A and 57B are cross-sectional views for illustrating the example of the method for manufacturing the surface emitting device in FIG. 52 for each step.

FIGS. 58A and 58B are cross-sectional views for illustrating the example of the method for manufacturing the surface emitting device in FIG. 52 for each step.

FIGS. 59A and 59B are cross-sectional views for illustrating the example of the method for manufacturing the surface emitting device in FIG. 52 for each step.

FIGS. 60A and 60B are cross-sectional views for illustrating the example of the method for manufacturing the surface emitting device in FIG. 52 for each step.

FIGS. 61A and 61B are cross-sectional views for illustrating the example of the method for manufacturing the surface emitting device in FIG. 52 for each step.

FIGS. 62A and 62B are cross-sectional views for illustrating the example of the method for manufacturing the surface emitting device in FIG. 52 for each step.

FIGS. 63A and 63B are cross-sectional views for illustrating the example of the method for manufacturing the surface emitting device in FIG. 52 for each step.

FIG. 64A is a cross-sectional view of a light source device including a surface emitting device according to Example 6 of the embodiment of the present technology indicating the state of the device before flip chip connection. FIG. 64B is a cross-sectional view of the light source device including the surface emitting device according to Example 6 of the embodiment of the present technology.

FIG. 65 is a flowchart for illustrating a method for manufacturing the light source device in FIG. 64B.

FIG. 66 is a view for illustrating a method for obtaining the distance between the centers of gravity of first and second structures in plan view.

FIG. 67A is a plan view of an exemplary array configuration of surface emitting devices including a plurality of surface emitting devices arranged in an array according to an embodiment of the present technology. FIG. 67B is a view of a second structures in the surface emitting device array as viewed from the side of a first structures.

FIG. 68A is a cross-sectional view of a light source device including a surface emitting device according to Modification 1 of Example 6 of the embodiment of the present technology indicating the state of the light source device before flip chip connection. FIG. 68B is a cross-sectional view of the light source device including the surface emitting device according to Modification 1 of Example 6 of the embodiment of the present technology.

FIG. 69A is a cross-sectional view of a light source device including a surface emitting device according to Modification 2 of Example 6 of the embodiment of the present technology indicating the state of the light source device before flip chip connection. FIG. 69B is a cross-sectional device of the light source device including the surface emitting device according to Modification 2 of Example 6 of the embodiment of the present technology.

FIG. 70A is a cross-sectional view of a surface emitting device according to a comparative example. FIG. 70B is a view for illustrating a problem associated with conventional exposure.

FIG. 71 is a cross-sectional view of a surface emitting device according to a modification of the embodiment of the present technology.

FIG. 72 is a cross-sectional view of the surface emitting device According to a modification of Example 1 of the embodiment of the present technology.

FIG. 73 is a diagram illustrating an example of application of the surface emitting device according to the present technology to a distance measuring device.

FIG. 74 is a block diagram of an exemplary schematic configuration of a vehicle control system.

FIG. 75 is a view for illustrating an example of an installation position for the distance measurement device.

### DESCRIPTION OF EMBODIMENTS

Preferred embodiments of the present technology will be described in detail with reference to the accompanying figures below. In the present specification and the drawings, components having substantially the same functional configuration will be denoted by the same reference numerals, and thus repeated descriptions thereof will be omitted. The embodiments to be described below show a representative embodiment of the present technology and the scope of the present technology should not be narrowly instructed on the basis of this.

Herein, even if multiple advantageous effects are described as being brought about by a surface emitting device, a light source device, and a method for manufacturing the surface emitting device, the surface emitting device, the light source device, and the method of manufacturing the surface emitting device need only exhibit at least one advantageous effect. The advantageous effects described herein are merely exemplary and should not be construed as limiting, and other advantageous effects may be provided.

The description will be made in the following order.
0. Introduction
1. Surface emitting device according to Example 1 of an embodiment of the present technology
2. Surface emitting device according to Example 2 of the embodiment of the present technology
3. Surface emitting device according to Example 3 of the embodiment of the present technology
4. Surface emitting device according to Example 4 of the embodiment of the present technology
5. Surface emitting device according to Example 5 of the embodiment of the present technology
6. Surface emitting device according to Example 6 of the embodiment of the present technology and a light source device including the surface emitting device
7. Surface emitting device array including multiple surface emitting devices arranged in an array according to an embodiment of the present technology
8. Surface emitting device according to Modification 1 of Example 6 of the embodiment of the present technology
9. Surface emitting device according to Modification 2 of Example 6 of the embodiment of the present technology
10. Surface emitting device according to a modification of the embodiment of the present technology
11. Surface emitting device according to a modification of Example 1 of the embodiment of the present technology
12. Other modifications of the present technology
13. Example of application to an electronic device
14. Example of application of the surface emitting device to a distance measurement device
15. Example of a distance measurement device provided in a mobile object

### 0. INTRODUCTION

For example, in a conventional surface emitting device such as a vertical cavity surface emitting laser (VCSEL), it has been proposed to introduce a concave mirror on one side of the light emission layer in order to eliminate diffraction loss attributable to confinement of the light field in the lateral direction (see PTL 1).

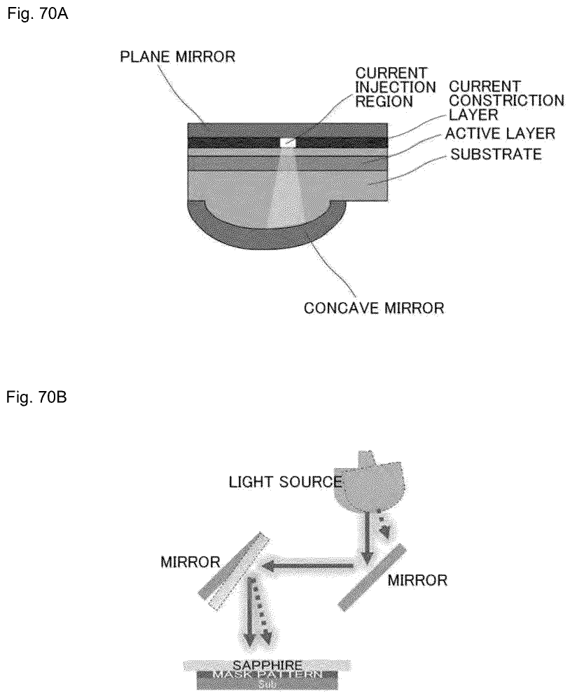

During the process of manufacturing the surface emitting device, alignment marks on the substrate surface and alignment marks on a photomask must be aligned over the substrate so that the current injection region of the light emission layer is registered with the center of the concave mirror in plan view. At the time, the alignment marks may be misaligned for various factors. For example, the refractive index difference between the substrate and air causes the center of the alignment mark on the substrate to be misaligned with the center of the alignment mark on the photomask, and if exposure is performed in the state, misalignment beyond the specification of the exposure device can occur. Also, when the exposure is performed obliquely due to the tilting of the light source and the mirror in the exposure device (see FIG. 70B), the current injection region and the concave mirror can be significantly misaligned (see FIG. 70A). This therefore necessitates a mask for exposure suitable for the situation. Large misalignment between the current injection region and the concave mirror can increase the threshold current and deteriorate the yield. Only a few exposure devices can handle exposure over a substrate, and a large sum of money needs to be invested to improve the alignment accuracy. When the misalignment is measured, the measurement must be conducted over the substrate, which can result in large measurement errors, and the measurement may not be conducted correctly. This can lead to lower the yield, which in turn can delay development and ultimately increase the development cost.

Therefore, the inventors have diligently studied and successfully developed the surface emitting device according to the present technology which has a configuration that can restrain misalignment between the current injection region (emission region) of the light emission layer and the concave mirror from increasing.

Hereinafter, a surface emitting devices according to embodiments of the present technology will be described with reference to several examples.

### 1. SURFACE EMITTING DEVICE ACCORDING TO EXAMPLE 1 OF AN EMBODIMENT OF THE PRESENT TECHNOLOGY

Hereinafter, a surface emitting device according to Example 1 of an embodiment of the present technology will be described with reference to the drawings.

### Configuration of Surface Emitting Device

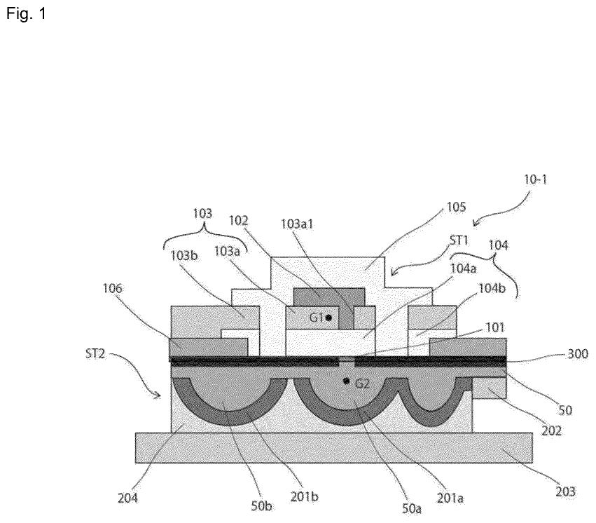

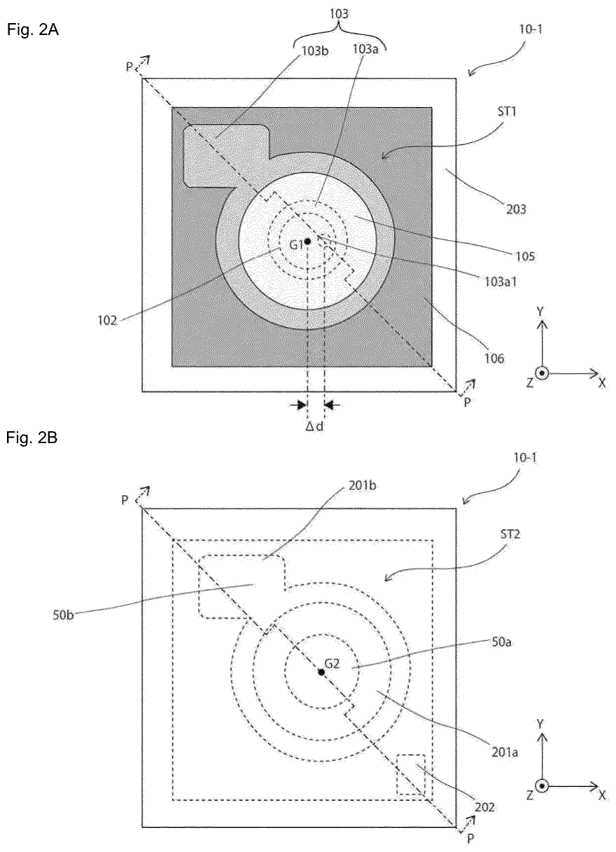

FIG. 1 is a cross-sectional view of a surface emitting device 10-1 according to Example 1 of the embodiment of the present technology. FIG. 2A is a cross-sectional view of the surface emitting device in FIG. 1. FIG. 2B is a view of a second structure of the surface emitting device in FIG. 1 as viewed from the side of a first structure. FIG. 1 is a cross-sectional view taken along line P-P in FIGS. 2A and 2B. In the following description, the XYZ three-dimensional Cartesian coordinate system shown for example in FIGS. 2A and 2B will be used as appropriate. The upper side and the lower side in a cross-sectional view such as FIG. 1 will be referred to as the upper side and the lower side for the sake of convenience.

As will be described in detail, the surface emitting device 10-1 is a vertical cavity surface emitting laser (VCSEL) having a vertical cavity type structure in which the light emission layer is sandwiched between first and second reflectors. The surface emitting device 10-1 is driven by a laser driver by way of example.

For example, as shown in FIG. 1, the surface emitting device 10-1 includes a substrate 50, a first structure ST1 provided on one surface (upper surface) of the substrate 50 and including a light emission layer 101, and a second structure ST2 provided on another surface (lower surface) of the substrate 50 and including a concave mirror 201a as the second reflector.

### [First Structure]

The first structure ST1 further includes a reflector 102 as a first reflector, located on the side of the light emission layer 101 (upper side) opposite to the side of concave mirror 201a (lower side). The first structure ST1 further includes an anode electrode 103, a first transparent conductive film 104, a second transparent conductive film 105, and an insulating layer 106.

### (Light Emission Layer)

The light emission layer 101 is for example provided on one surface (a front or upper surface) of the substrate 50. The light emission layer 101 may include a 5-layer multiple quantum well structure having In_{0.04}Ga_{0.96}N layers (barrier layers) and In_{0.16}Ga_{0.84}N layers (well layers) stacked on each other. The light emission layer 101 is also referred to as the “active layer”.

In the periphery of the light emission layer 101, a current constriction region 300 is provided. The area surrounded by the current constriction region 300 of the light emission layer 101 is the current injection region (light emission region). The current constriction region 300 may be provided outside of the light emission layer 101. In this case, the region of the light emission layer 101 corresponding to the area surrounded by the current constriction region 300 is the current injection region (light emission region). In other words, the current constriction region 300 is a region that defines the light emission region of the light emission layer 101.

The current constriction region 300 is for example an ion implantation region. The ion implantation region is a region implanted with high-concentration ions (for example, B++). The ion-implanted region has higher resistance (lower carrier conductivity) than the current-injection region surrounded by the ion-implanted region. The current constriction diameter by the ion-implanted region can be several μm (for example, 4 μm or less).

### [Substrate]

The substrate 50 for example may be a n-GaN substrate. On the other side (back or lower surface) of the substrate 50, a first convex surface structure 50a and a second convex surface structure 50b surrounding the first convex surface structure 50a are provided. The first convex surface structure 50a for example has a hemispherical shape that protrudes downward and is in a position corresponding to the current injection region. The second convex surface structure 50b surrounds the first convex surface structure 50a in an annular shape for example with a substantially semicircular cross section. For example, the center of the first convex surface structure 50a overlaps the current injection region in plan view. The radius of curvature of the first convex surface structure 50a is for example 50 μm.

### (Anode Electrode)

The anode electrode 103 includes a first electrode pad 103a and a second electrode pad 103b that surrounds the first electrode pad 103a (see FIG. 2A). The distance between the first and second electrode pads 103a and 103b is for example 10 μm. The outer diameter of the first electrode pad 103a is 30 μm. The first and second electrode pads 103a and 103b are electrically connected through the second transparent conductive film 105. The first electrode pad 103a has a through hole 103a1 in a position corresponding to the current injection region. Light from the light emission layer 101 passes through the through hole 103a1. More specifically the first electrode pad 103a serves also as a light confinement part that confines light from the light emission layer 101 within the through hole 103a1. For example, the center of the through hole 103a1 is apart from the center of gravity G1 of the first structure ST1 in the +X direction by Δd in plan view (see FIG. 2A). The second electrode pad 103b serves as an electrical contact with the anode side of the laser driver.

The anode electrode 103 may include at least one metal (including an alloy) selected from the group consisting of Au, Ag, Pd, Pt, Ni, Ti, V W, Cr, Al, Cu, Zn, Sn and In. When formed in a stacked structure, the anode electrode 103 may include materials such as Ti/Au, Ti/Al, Ti/Al/Au, Ti/Pt/Au, Ni/Au, Ni/Au/Pt, Ni/Pt, Pd/Pt, and Ag/Pd. The anode electrode 103 is connected to the anode (positive electrode) of the laser driver.

### (Reflector)

An example of the reflector 102 is a plane mirror. The reflector 102 has a part provided on the first electrode pad 103a of the anode electrode 103 and a part provided in the through hole 103a1 of the first electrode pad 103a. The reflector 102 may include a dielectric multilayer film reflector. The dielectric multilayer film reflector may include Ta₂O₅/SiO₂ or SiN/SiO₂. The reflectance of the reflector 102 as the first reflector is set slightly lower than the reflectance of the concave mirror 201a as the second reflector by way of example. The reflector 102 is a reflector on the output side. In other words, the surface emitting device 10-1 is a surface emitting type surface emitting laser that emits light toward the surface (upper surface) of the substrate 50. The reflector 102 may be a concave mirror.

### (First Transparent Conductive Film)

The first transparent conductive film 104 is for example provided between the light emission layer 101 and the anode electrode 103. The first transparent conductive film 104 has a first part 104a that corresponds to the first electrode pad 103a and a second part 104b that corresponds to the second electrode pad 103b and surrounds the first part 104a. The first and second parts 104a and 104b are electrically connected through the second transparent conductive film 105. The first transparent conductive film 104 serves as a buffer layer to increase the efficiency of hole injection into the light emission layer 101 and to prevent leakage. The first transparent conductive film 104 is for example made of ITO, ITiO, AZO, ZnO, SnO, SnO₂, SnO₃, TiO, TiO₂, or graphene.

### (Second Transparent Conductive Film)

The second transparent conductive film 105 is provided for example to cover the reflector 102, the first electrode pad 103a of the anode electrode 103 and the first part 104a of the first transparent conductive film 104 from the side (upper side) opposite to the light emission layer 101 (lower side). The second transparent conductive film 105 serves as a buffer layer to increase the efficiency of hole injection into the light emission layer 101 and to prevent leakage. The second transparent conductive film 105 is for example made of ITO, ITiO, AZO, ZnO, SnO, SnO₂, SnO₃, TiO, TiO₂, or graphene. The second transparent conductive film 105 may or may not be made of the same material as the first transparent conductive film 104.

### (Insulating Layer 106)

The insulating layer 106 is for example provided in an annular shape on the surface (upper surface) of the light emission layer 101 to surround the lower part of the first transparent conductive film 104. The insulating layer 106 has a refractive index difference with respect to the first transparent conductive film 104 and functions as a light confinement part. The insulating layer 106 is for example made of a dielectric such as SiO₂, SiN, and SiON.

### [Second Structure]

The second structure ST2 further includes a cathode electrode 202 provided on the back (lower) surface of the substrate 50. The second structure ST2 further has a support substrate 203 attached to the concave mirror 201a through wax 204.

In plan view, the center of gravity G2 of the second structure ST2 is for example apart from the center of gravity G1 of the first structure ST1 by Δd in the +X direction. In other words, in plan view, the center of gravity G2 of the second structure ST2 for example substantially coincides with the center of the through hole 103a1 of the first electrode pad 103a.

### (Concave Mirror)

The use of the concave mirror 201a with positive power as the second reflector allows light from the light emission layer 101 to be reflected and focused on the light emission layer 101 regardless of the resonator length (which provides the light-field confinement effect in the lateral direction), and the diffraction loss can be reduced.

The concave mirror 201a is provided along the surface of the first convex surface structure 50a. In other words, the concave mirror 201a has a shape that conforms to the first convex surface structure 50a.

The concave mirror 201a may be a dielectric multilayer film reflector as an example. The dielectric multilayer film reflector may be made of Ta₂O₅/SiO₂, SiO₂/SiN, or SiO₂/Nb₂O₅.

The concave mirror 201a for example has a substantially hemispherical shell shape and has at least an upper part located at a position corresponding to the current injection region (on the optical path of light from the light emission layer 101). The concave mirror 201a has at least an apex surface that is curved (such as a spherical surface and a parabolic surface). The surface of the concave mirror 201a except for the apex may also be planar.

A dielectric multilayer film 201b identical to the dielectric multilayer film that constitutes the concave mirror 201a is provided along the surface of the second convex surface structure 50b.

### (Cathode Electrode)

The cathode electrode 202 is for example made of at least one metal (including an alloy) selected from the group consisting of Au, Ag, Pd, Pt, Ni, Ti, V W, Cr, Al, Cu, Zn, Sn, and In. When formed in a stacked structure, the cathode electrode 202 is for example made of materials such as Ti/Au, Ti/Al, Ti/Al/Au, Ti/Pt/Au, Ni/Au, Ni/Au/Pt, Ni/Pt, Pd/Pt, and Ag/Pd. The cathode electrode 202 is connected to the cathode (negative electrode) of the laser driver.

### <<Characteristic Configuration of the Present Technology>>

Hereinafter, a characteristic configuration of the present technology will be described.

The substrate 50 is transparent with respect to a prescribed wavelength (exposure wavelength which will be described).

The first structure ST1 has a transparent part and an opaque part with respect to the above-described prescribed wavelength. Specifically, the anode electrode 103 is for example made of a metal that is opaque to the prescribed wavelength.

The first and second transparent conductive films 104 and 105 are for example transparent with respect to the prescribed wavelength. The reflector 102 is for example made of a dielectric that is opaque to the prescribed wavelength. The current constriction region 300 is for example transparent to the prescribed wavelength. In other words, the first structure ST1 functions as a mask having a mask pattern with a light-shielding part that shields light with the prescribed wavelength and a transmission part that transmits the light.

The anode electrode 103, which is an opaque part of the first structure ST1, has the first electrode pad 103a as a first part and the second electrode pad 103b as a second part arranged in the in-plane direction. As an example, the second part or the second electrode pad 103b surrounds the first part or the first electrode pad 103a.

The first and second structures ST1 and ST2 have substantially similar forms in plan view and their centers of gravity do not coincide (see FIGS. 1, 2A, and 2B).

In plan view, the distance between the center of the light emission region (current injection region) of the light emission layer 101 and the center of the concave mirror 201a (center of the first convex structure 50a) is shorter than the distance Δd between the centers of gravity G1 and G2 of the first and second structures ST1 and ST2.

The distance between the centers of gravity G1 and G2 of the first and second structures ST1 and ST2 in plan view is preferably at least 50 nm as an example. For example, the distance between the center of the light emission region (current injection region) of the light emission layer 101 and the center of the concave mirror 201a in plan view may be at most 500 nm.

A plan view shape of the second structure ST2 may be a Fourier transformed shape of a plan view shape of the first structure ST1. A plan view shape of the second structure ST2 may be a similar form to a Fourier transformed shape of a plan view shape of the first structure ST1 with a coefficient of determination of at least 70%.

### <<Operation of Surface Emitting Device>>

Hereinafter, the operation of the surface emitting device 10-1 will be described. In the surface emitting device 10-1, when drive voltage is applied between the anode electrode 103 and the cathode electrode 202 by the laser driver, current passed from the anode side of the laser driver through the anode electrode 103 is injected into the light emission layer 101 while being constricted in the current constriction region 300 through the first transparent conductive film 104. At the time, the light emission layer 101 emits light, the light travels back and forth between the concave mirror 201a and the reflector 102 while being confined in the through-hole 103a1 of the first electrode pad 103a and amplified by the light emission layer 101 (in this case, the light is reflected while being focused near for example the light emission region by the concave mirror 201a and is then reflected toward the light emission layer 101 as parallel light or weak diffused light by the reflector 102), and when the oscillation conditions are met, the light is emitted as laser light from the reflector 102 through the second transparent conductive film 105. The current injected into the light emission layer 101 is passed from the cathode electrode 202 through the substrate 50 to the cathode side of the laser driver.

### <<First Example of Method for Manufacturing Surface Emitting Device>>

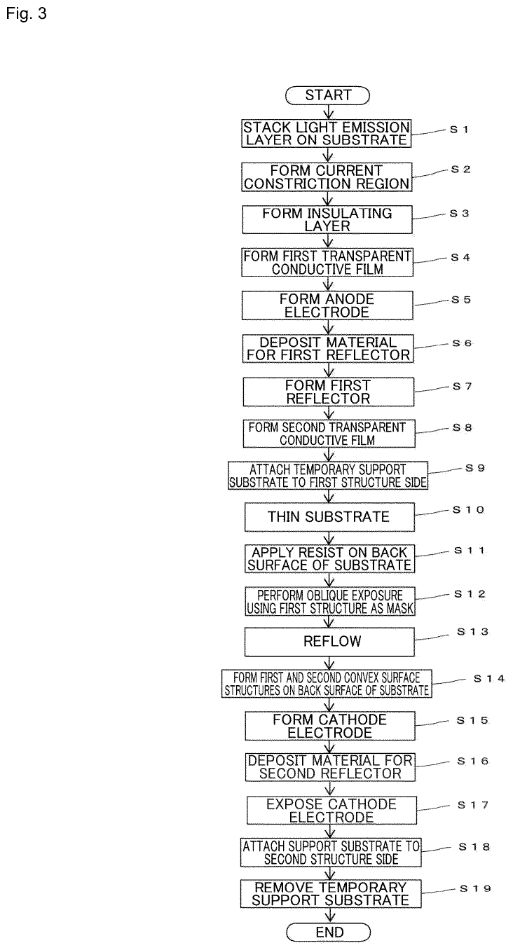

A first example of a method for manufacturing the surface emitting device 10-1 will be described for example with reference to the flowchart in FIG. 3. Here, as an example, a plurality of surface emitting devices 10-1 are simultaneously produced on a single wafer (semiconductor substrate (such as an n-GaN substrate)) that is to be a base material for the substrate 50. Then, the plurality of surface emitting devices 10-1 in an integral form are separated from each other to obtain chip-shaped surface emitting devices 10-1 (surface emitting device chips).

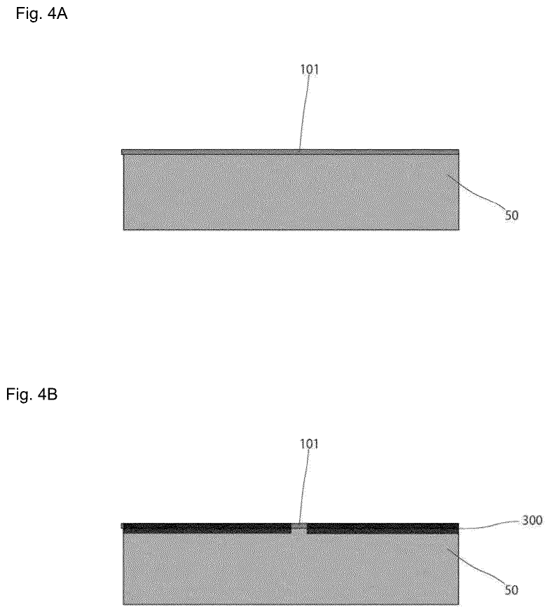

In the first step S1, the light emission layer 101 (active layer) is stacked on the substrate 50 (see FIG. 4A). Specifically a laminate is produced by stacking the light emission layer 101 on the substrate 50 in a growth chamber by metal organic chemical vapor deposition (MOCVD) or molecular beam epitaxy (MBE).

In the next step S2, the current constriction region 300 is formed (see FIG. 4B). Specifically to start with, a protection film made for example of resist and SiO₂ is formed to cover the part of the laminate other than the part where the current constriction region 300 is to be formed (the part where the current injection region is to be formed). During the process, the protection film is formed so that the center of the current injection region is at a position apart from the center of gravity G1 of the first structure ST1 by Δd in the +X direction in plan view. Then, using the protection film as a mask, ions (for example, B++) are implanted into the laminate from the side of the light emission layer 101. In this case, the ions are implanted to such a depth that they reach inside of the substrate 50.

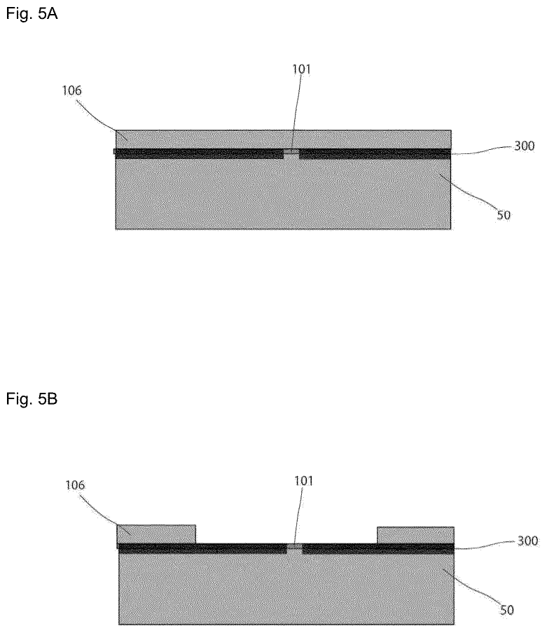

In the next step S3, the insulating layer 106 is formed. Specifically to start with, the insulating layer 106 is deposited on the entire surface for example by vacuum evaporation or sputtering (see FIG. 5A). Then, a center part of the insulating layer 106 is removed by photolithography to form the insulating layer 106 in an annular shape (see FIG. 5B).

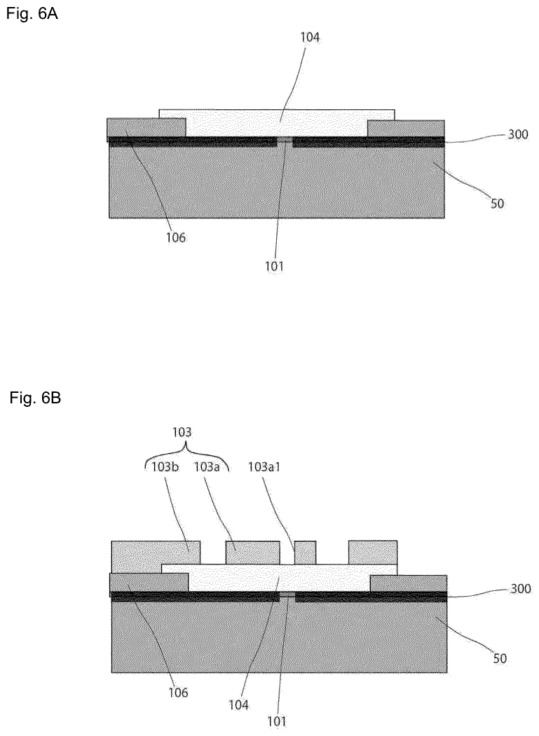

In the next step S4, the first transparent conductive film 104 is formed (see FIG. 6A). Specifically to start with, a transparent conductive film, which is a material for the first transparent conductive film 104, is deposited on the entire surface for example by vacuum evaporation or sputtering. Then, the first transparent conductive film 104 is formed by removing a peripheral part of the transparent conductive film by photolithography.

In the next step S5, the anode electrode 103 is formed (see FIG. 6B). Specifically the first and second electrode pads 103a and 103b of the anode electrode 103 are formed for example by lift-off. During the process, the first electrode pad 103a is formed so that the center of the through hole 103a1 of the first electrode pad 103a and the center of the current injection region substantially coincide in plan view. The electrode material for the anode electrode 103 is deposited for example by vacuum evaporation or sputtering.

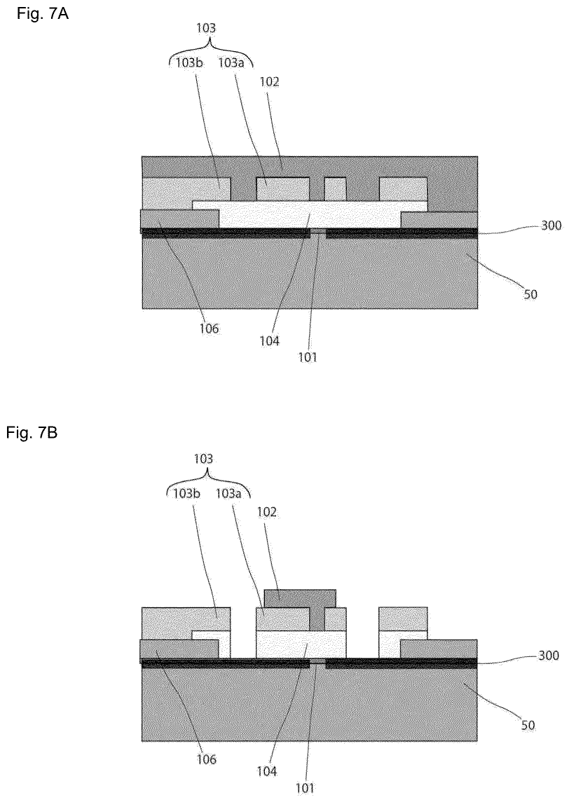

In the next step S6, a material for the reflector 102 as the first reflector is deposited (see FIG. 7A). Specifically a dielectric multilayer film, which is a material for the reflector 102 (for example, plane mirror), is deposited on the entire surface for example by vacuum evaporation, sputtering, or CVD.

In the next step S7, the reflector 102 as the first reflector is formed (see FIG. 7B). Specifically the part of the dielectric multilayer film other than the part to be the reflector 102 is removed by dry etching to form the reflector 102. During the process, the corresponding part of the first transparent conductive film 104 is also removed.

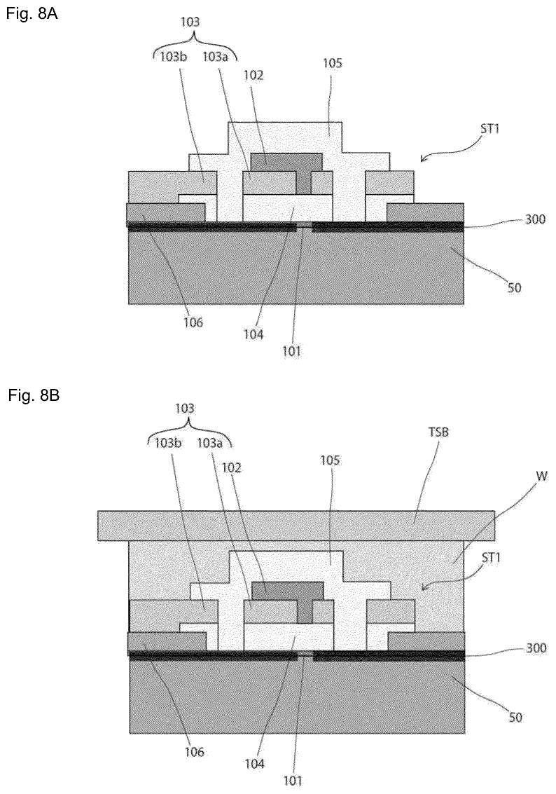

In the next step S8, the second transparent conductive film 105 is formed (see FIG. 8A). Specifically to start with, a transparent conductive film, which is a material for the second transparent conductive film 105, is deposited on the entire surface for example by vacuum evaporation or sputtering. Then, a peripheral part of the transparent conductive film is removed by photolithography to form the second transparent conductive film 105.

In the next step S9, a temporary support substrate TSB is attached to the side of the first structure ST1 (see FIG. 8B). Specifically the temporary support substrate TSB (such as a sapphire substrate) is attached to the side of the first structure ST1 through wax W.

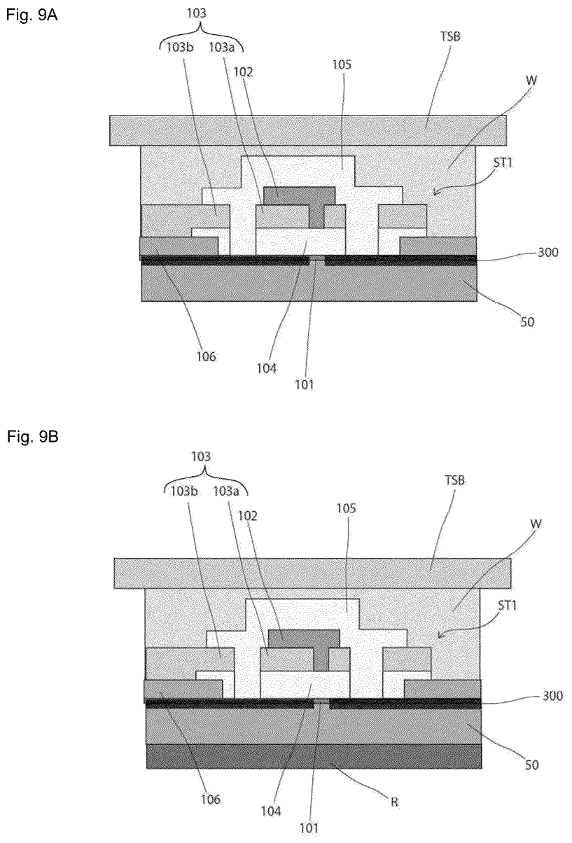

In the next step S10, the substrate 50 is thinned (see FIG. 9A). Specifically the substrate 50 is thinned by polishing the back surface of the substrate 50 using for example a CMP (chemical mechanical polishing) device.

In the next step S11, resist R (such as positive photoresist) is applied on the back surface of the substrate 50 (see FIG. 9B). Specifically the resist R is applied flat on the back surface of the substrate 50.

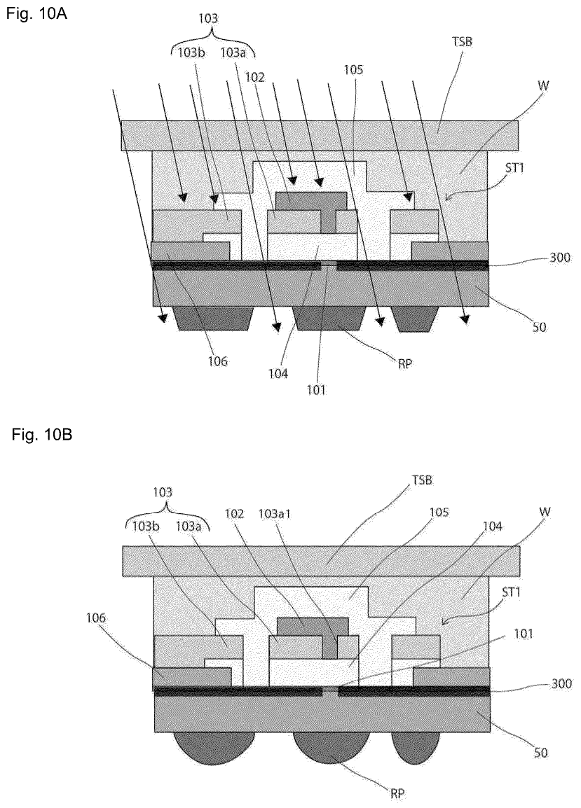

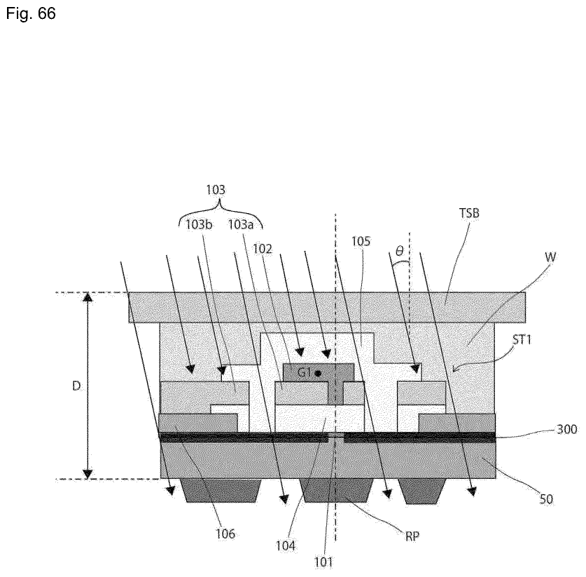

In the next step S12, oblique exposure is performed using the first structure ST1 as a mask (see FIG. 10A). Specifically, to start with, exposure light with the above-described prescribed wavelength (exposure wavelength) is obliquely entered at a prescribed angle of incidence θ (see FIG. 66) along an XZ plane (see FIG. 2A) from the side of the first structure ST1 by an exposure device. The exposure light is blocked by the anode electrode 103 and the reflector 102, which are opaque parts with respect to the prescribed wavelength and transmitted through the first and second transparent conductive films 104 and 105 which are transparent parts with respect to the prescribed wavelength. As a result, a latent image corresponding to the mask pattern of the first structure ST1 is formed on the resist R. Then, the resist R is immersed in a developing solution, so that the latent image is revealed (the exposed part is dissolved). As a result, a resist pattern RP is formed, which is made of an image by the parts not irradiated with the exposure light (non-exposed part). The resist pattern RP has a substantially similar form in plan view to the first structure ST1, and its center of gravity does not coincide with that of the first structure ST1.

Here, the displacement (the amount of misalignment) between the centers of gravity of the first structure ST1 and the resist pattern RP is determined by the angle of incidence of the exposure light θ and the distance D between the back surface (lower surface) of the substrate 50 and the surface (upper surface) of the temporary support substrate TSB as shown in FIG. 66. The distance D is the total of the thickness of the first structure ST1 and the thickness of the substrate 50.

Specifically when the distance D is 30 μm and the angle of incidence θ is 0.95°, the displacement between the above centers of gravity is 0.5 μm. When the distance D is 10 μm and the angle of incidence θ is 2.86°, the displacement between the above centers of gravity is 0.5 μm.

When the distance D is 30 μm and the angle of incidence θ is 0.57°, the displacement between the above centers of gravity is 0.3 μm. When the distance D is 10 μm and the angle of incidence θ is 1.72°, the displacement between the above centers of gravity is 0.3 μm.

When the distance D is 30 μm and the angle of incidence θ is 0.19°, the displacement between the above centers of gravity is 0.1 μm. When the distance D is 10 μm and the angle of incidence θ is 0.57°, the displacement between the above centers of gravity is 0.1 μm.

When the distance D is 30 μm and the angle of incidence θ is 0.10°, the displacement between the above centers of gravity is 0.05 μm. When the distance D is 10 μm and the angle of incidence θ is 0.29°, the displacement between the above centers of gravity is 0.05 μm.

As can be understood from the above description, when the angle of incidence θ is set corresponding to the distance D or the distance D is set according to the angle of incidence θ, the displacement between the above centers of gravity can be set to a desired value. In other words, the angle of incidence θ can be selected to set the displacement between the above centers of gravity to a desired value according to the distance D, or the distance D can be selected to set the displacement between the above centers of gravity to a desired value according to the angle of incidence θ. Here, the angle of incidence θ corresponding to the distance D and Δd is selected in order to shift the center of gravity of the resist pattern RP by Δd in the +X direction from the center of gravity G1 of the first structure ST1 in plan view. The angle of incidence θ should preferably be set while directly measuring the angle of incidence of the exposure light emitted from the exposure device and entered on the first structure ST1. The angle of incidence θ can be adjusted for example by changing the angle of the mirror in the exposure device (see FIG. 70B).

A specific example of the exposure method will be described. For example, when the distance D is 30 μm, photoresist coated on the (000-1) plane of the substrate 50 is exposed from the (0001) surface by an aligner (exposure device) patterned. In this case, the aligner to used should allow ultraviolet light to be inclined 0.95° from the (000-1) surface in the [−12-10] direction due to the tilt of the mirror in the device. In this case, the through hole 103a1 of the first electrode pad 103a is displaced 0.5 μm from the center of the first transparent conductive film 104 in the [−12-10] direction. In this way, if the direction of exposure (direction of incidence) is known, the displacement between the through hole 103a1 and the resist pattern RP can be corrected depending on the distance D, which is advantageous in that the need for maintenance of the device is eliminated.

In the next step S13, reflow is performed (see FIG. 10B). Specifically, the resist pattern balls up by reflow (for example at 200° C.) and is formed into a substantially hemispherical convex surface shape (see FIG. 10B).

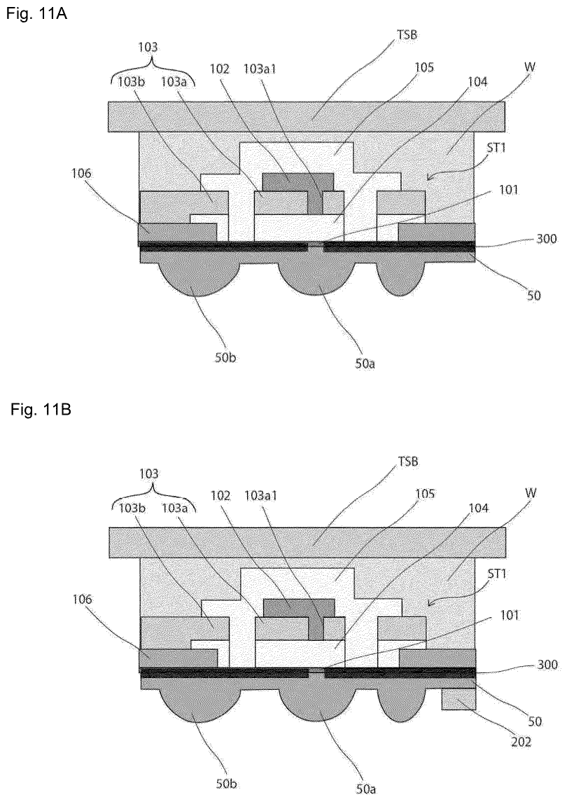

In the next step S14, the first and second convex surface structures 50a and 50b are formed on the back surface of the substrate 50 (see FIG. 11A). Specifically, the first and second convex surface structures 50a and 50b are formed by etching (for example by dry etching) the substrate 50 using the balled-up resist pattern RP as a mask.

In the next step S15, the cathode electrode 202 is formed (see FIG. 11B). Specifically, the cathode electrode 202 is formed on the back surface of the substrate 50 for example by lift-off. In this case, the electrode material for the cathode electrode 202 is deposited for example by vacuum evaporation or the sputtering.

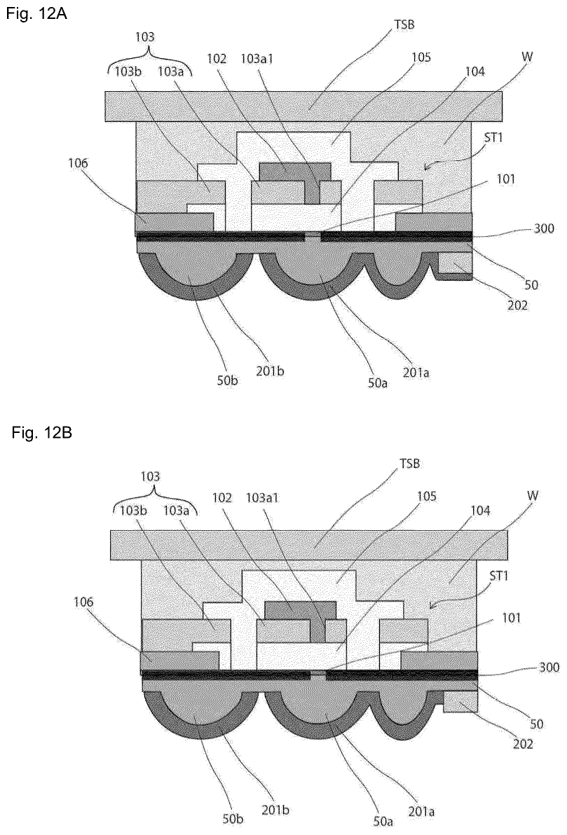

In the next step S16, a material for the concave mirror 201a as the second reflector is deposited (see FIG. 12A). Specifically, a dielectric multilayer film, which is a material for the concave mirror 201a, is deposited on the entire surface for example by vacuum evaporation, sputtering, or CVD.

In the next step S17, the cathode electrode 202 is exposed (see FIG. 12B). Specifically the dielectric multilayer film on the cathode electrode 202 is removed for example by dry etching.

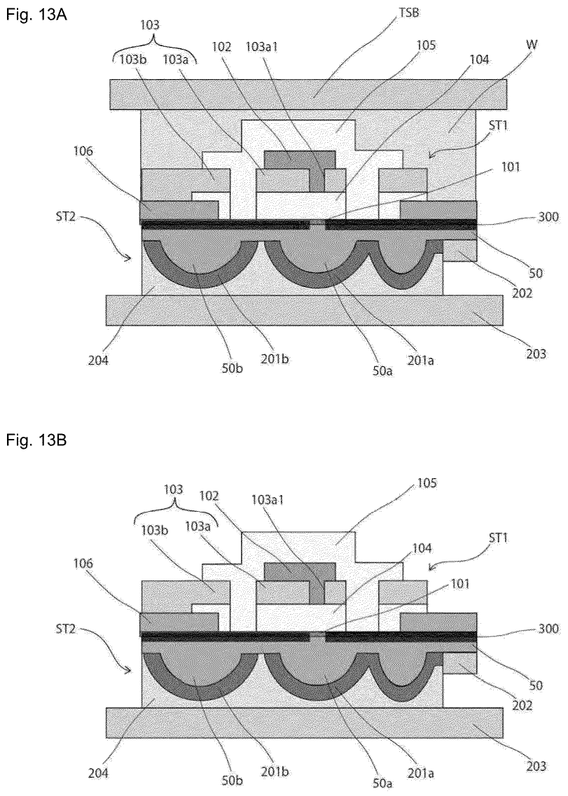

In the next step S18, the support substrate 203 is attached to the side of the second structure ST2 (see FIG. 13A). Specifically the support substrate 203 is attached to the side of the second structure ST2 through wax 204.

In the final step S19, the temporary support substrate TSB is removed (see FIG. 13B). Specifically the wax W is dissolved by heating, and the temporary support substrate TSB and the wax W are removed. As a result, a plurality of surface emitting devices 10-1 are produced on the wafer (semiconductor substrate (such as an n-GaN substrate)). The plurality of surface emitting devices 10-1 in an integral form are then separated by dicing to obtain chip-shaped surface emitting devices 10-1 (surface emitting device chips).

### <<Second Example of Method for Manufacturing Surface Emitting Device>>

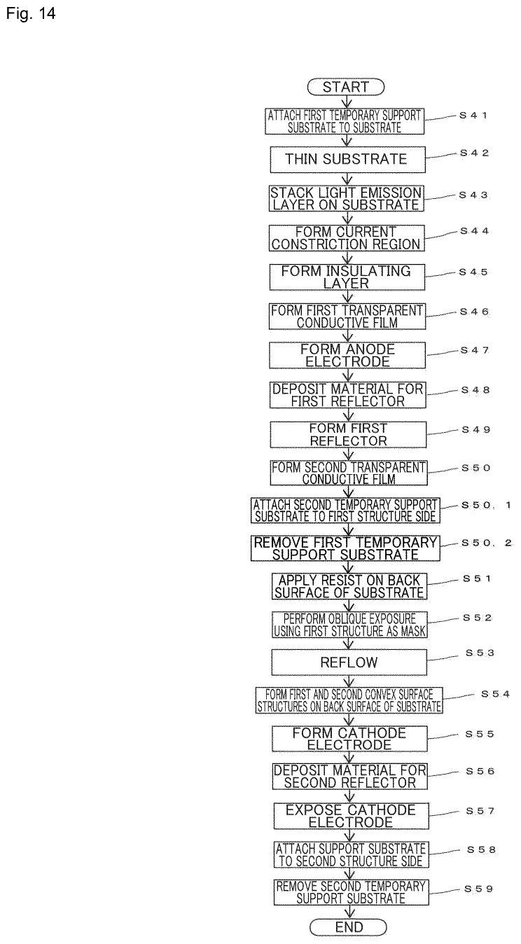

A second example of the method for manufacturing the surface emitting device 10-1 will be described with reference to the flowchart in FIG. 14. Here, a plurality of surface emitting devices 10-1 are simultaneously produced on a single wafer (semiconductor substrate (such as a n-GaN substrate)) that serves as the base material for the substrate 50 by way of illustration. Then, the plurality of surface emitting devices 10-1 in an integral form are separated from each other to obtain chip-shaped surface emitting devices 10-1 (surface emitting device chips).

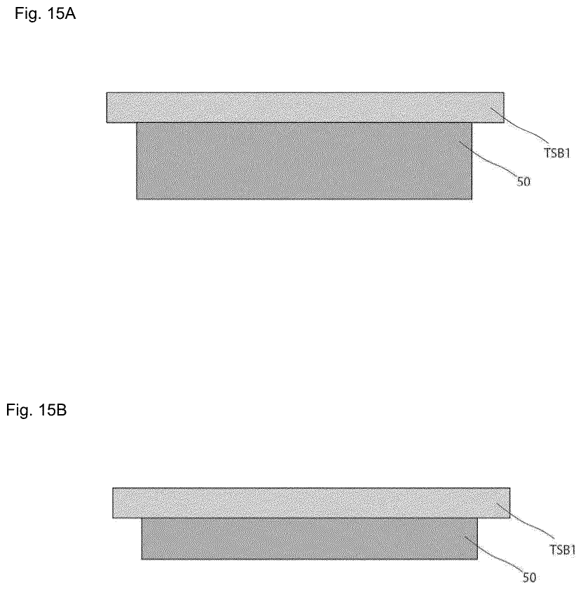

In the first step S41, a first temporary support substrate TSB1 is attached to the substrate 50 (see FIG. 15A). Specifically, the first temporary support substrate TSB1 (such as a sapphire substrate) is attached to the substrate 50 for example through wax.

In the next step S42, the substrate 50 is thinned (see FIG. 15B). Specifically, the substrate 50 is thinned by polishing the backside of the substrate 50 using for example a CMP (chemical mechanical polishing) device.

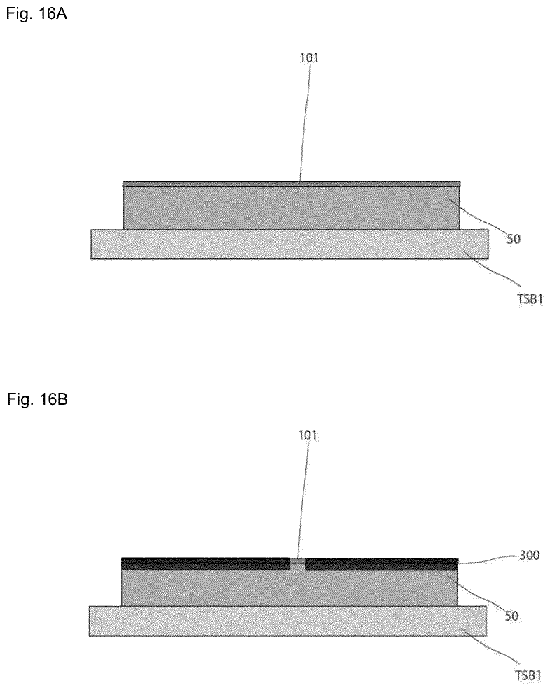

In the next step S43, the light emission layer 101 (active layer) is stacked on the substrate 50 (see FIG. 16A). Specifically a laminate is produced by stacking the light emission layer 101 on the substrate 50 in a growth chamber for example by metal organic chemical vapor deposition (MOCVD) or molecular beam epitaxy (MBE).

In the next step S44, the current constriction region 300 is formed (see FIG. 16B). Specifically to start with, a protection film made for example of resist and SiO₂ is formed to cover the part of the laminate other than the part where the current constriction region 300 is to be formed (the part where the current injection region is to be formed). During the process, the protection film is formed so that the center of the current injection region is at a position apart from the center of gravity G1 of the first structure ST1 by Δd in the +X direction in plan view. Then, using the protection film as a mask, ions (for example, B++) are implanted into the laminate from the side of the light emission layer 101. In this case, the ions are implanted to such a depth that they reach inside of the substrate 50.

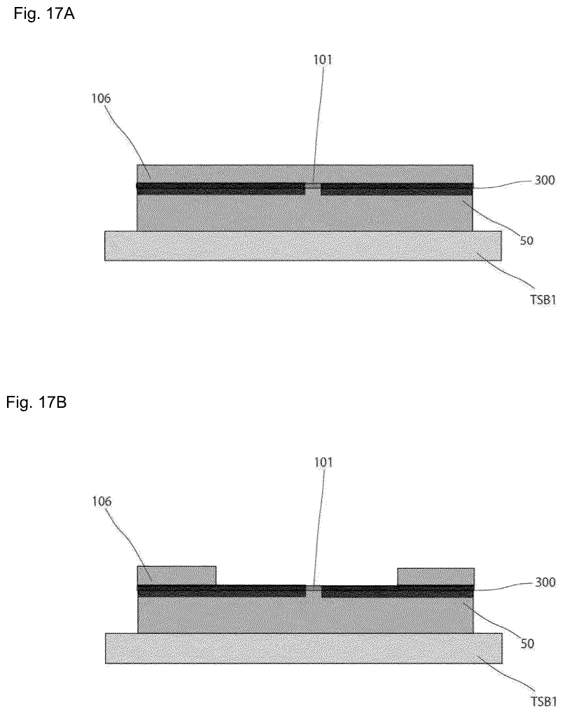

In the next step S45, the insulating layer 106 is formed. Specifically to start with, the insulating layer 106 is deposited on the entire surface for example by vacuum evaporation or sputtering (see FIG. 17A). Then, a center part of the insulating layer 106 is removed by photolithography to form the insulating layer 106 in an annular shape (see FIG. 17B).

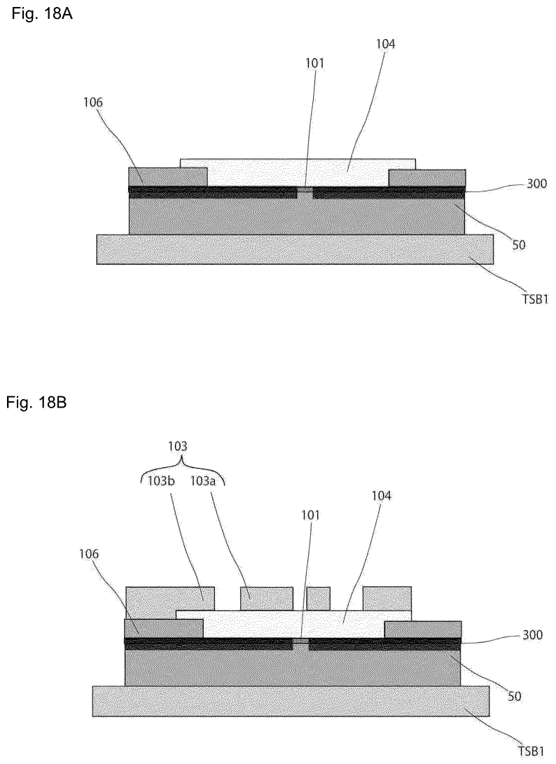

In the next step S46, the first transparent conductive film 104 is formed (see FIG. 18A). Specifically to start with, a transparent conductive film, which is a material for the first transparent conductive film 104, is deposited on the entire surface for example by vacuum evaporation or sputtering. Then, the first transparent conductive film 104 is formed by removing a peripheral part of the transparent conductive film by photolithography.

In the next step S47, the anode electrode 103 is formed (see FIG. 18B). Specifically, the first and second electrode pads 103a and 103b of the anode electrode 103 are formed for example by lift-off. During the process, the first electrode pad 103a is formed so that the center of the through hole 103a1 of the first electrode pad 103a and the center of the current injection region substantially coincide in plan view. The electrode material for the anode electrode 103 is deposited for example by vacuum evaporation or sputtering.

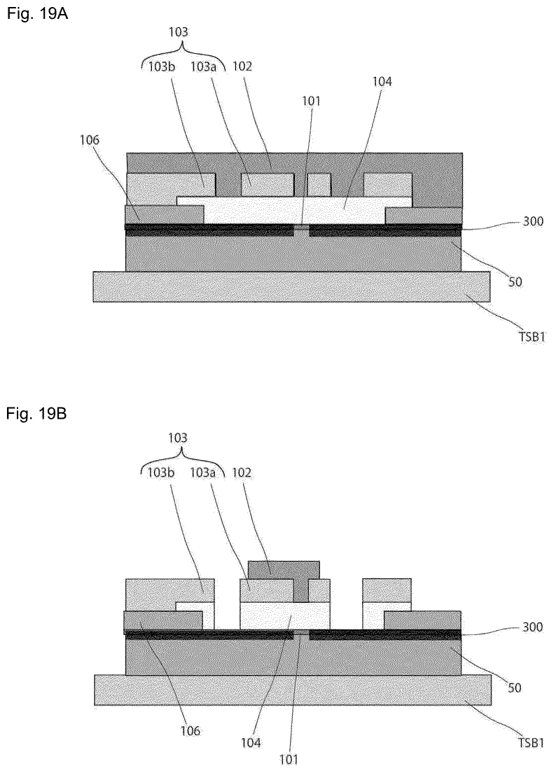

In the next step S48, a material for the reflector 102 as the first reflector is deposited (see FIG. 19A). Specifically, a dielectric multilayer film, which is the material for the reflector 102 (for example, a plane mirror), is deposited on the entire surface for example by vacuum evaporation, sputtering, or CVD.

In the next step S49, the reflector 102 as the first reflector is formed (see FIG. 19B). Specifically, the part of the dielectric multilayer film other than the part to be the reflector 102 is removed for example by dry etching to form the reflector 102. During the process, the corresponding part of the first transparent conductive film 104 is also removed.

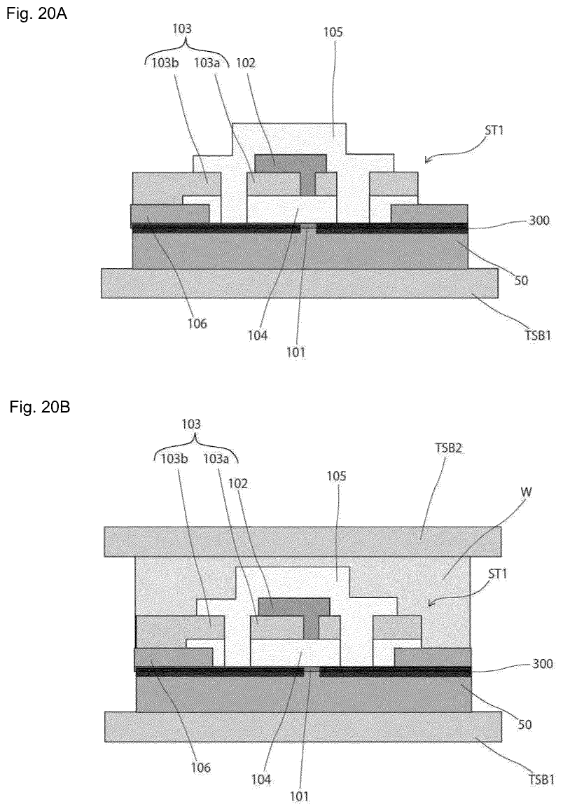

In the next step S50, the second transparent conductive film 105 is formed (see FIG. 20A). Specifically to start with, a transparent conductive film, which is a material for the second transparent conductive film 105, is deposited on the entire surface for example by vacuum evaporation or sputtering. The, a peripheral part of the transparent conductive film is removed by photolithography to form the second transparent conductive film 105.

In the next step S50.1, a second temporary support substrate TSB2 is attached to the side of the first structure ST1 (see FIG. 20B). Specifically the second temporary support substrate TSB2 is attached to the side of the first structure ST1 through wax W.

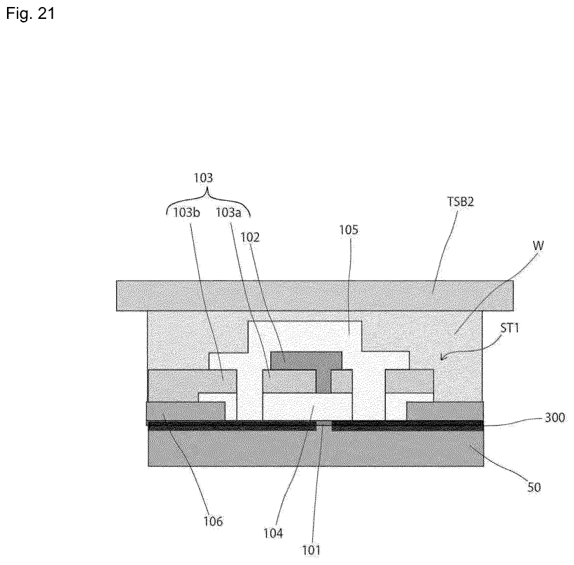

In the next step S50.2, the first temporary support substrate TSB1 is removed (see FIG. 21). Specifically the wax that adheres the substrate 50 and the first temporary support substrate TSB1 is heated to remove the first temporary support substrate TSB1.

In the next step S51, resist R (such as positive photoresist) is applied on the back surface of the substrate 50 (see FIG. 9B). Specifically the resist R is applied flat on the back surface of substrate 50.

In the next step S52, oblique exposure is performed using the first structure ST1 as a mask (see FIG. 10A). Specifically, to start with, exposure light with the above-described prescribed wavelength (exposure wavelength) is allowed to enter obliquely at a prescribed angle of incidence θ (see FIG. 66) along an XZ plane (see FIG. 2A) from the side of the first structure ST1 by an exposure device. At the time, the exposure light is blocked by the anode electrode 103 and the reflector 102, which are opaque parts with respect to the prescribed wavelength and transmitted through the first and second transparent conductive films 104 and 105, which are transparent parts with respect to the prescribed wavelength. As a result, a latent image corresponding to the mask pattern of the first structure ST1 is formed on the resist R. Then, the resist R is immersed in a developing solution, so that the latent image is revealed. As a result, a resist pattern RP is formed by the parts not irradiated with the exposure light. The resist pattern RP has a substantially similar form in plan view to the first structure ST1, and its center of gravity does not coincide with that of the first structure ST1. Here, the angle of incidence θ corresponding to the distance D and Δd is selected in order to shift the center of gravity of the resist pattern RP from the center of gravity G1 of the first structure ST1 in the +X direction by Δd in plan view. The angle of incidence θ is preferably set while directly measuring the angle of incidence of the exposure light emitted from the exposure device and entered on the first structure ST1.

In the next step S53, reflow is performed (see FIG. 10B). Specifically, the resist pattern balls up by reflow (for example at 200° C.) and is formed into a substantially hemispherical convex surface shape (see FIG. 10B).

In the next step S54, the first and second convex surface structures 50a and 50b are formed on the back surface of the substrate 50 (see FIG. 11A). Specifically, the first and second convex surface structures 50a and 50b are formed by etching (for example by dry etching) the substrate 50 using the balled-up resist pattern RP as a mask.

In the next step S55, the cathode electrode 202 is formed (see FIG. 11B). Specifically the cathode electrode 202 is formed on the back surface of the substrate 50 for example by lift-off. In this case, the electrode material for the cathode electrode 202 is deposited for example by vacuum evaporation sputtering.

In the next step S56, a material for the concave mirror 201a as the second reflector is deposited (see FIG. 12A). Specifically a dielectric multilayer film, which is a material for the concave mirror 201a, is deposited on the entire surface for example by vacuum evaporation, sputtering, or CVD.

In the next step S57, the cathode electrode 202 is exposed (see FIG. 12B). Specifically the dielectric multilayer film on the cathode electrode 202 is removed for example by dry etching.

In the next step S58, the support substrate 203 is attached to the side of the second structure ST2 (see FIG. 13A). Specifically, the support substrate 203 is attached to the side of the second structure ST2 through wax 204.

In the final step S59, the second temporary support substrate TSB2 is removed (see FIG. 13B). Specifically the wax W is dissolved by heating, so that the second temporary support substrate TSB2 (TSB in FIG. 13B) and the wax W are removed. As a result, a plurality of surface emitting devices 10-1 are produced on the wafer (a semiconductor substrate (such as an n-GaN substrate)). Thereafter, the plurality of surface emitting devices 10-1 in an integral form are separated by dicing to obtain chip-shaped surface emitting devices 10-1 (surface emitting device chips).

### <<Advantageous Effects of Surface Emitting Device and Manufacturing Method Therefor>>

Hereinafter, advantageous effects of the surface emitting device 10-1 according to Example 1 of the embodiment of the present technology and the manufacturing method therefor will be described.

The surface emitting device 10-1 according to Example 1 of the embodiment of the present technology includes a substrate 50, a first structure ST1 provided on one side of the substrate 50 and including a light emission layer 101, and a second structure ST2 provided on another side of the substrate 50 and including a concave mirror 201a, the substrate 50 is transparent to a prescribed wavelength (exposure wavelength), the first structure ST1 has an anode electrode 103, which is an opaque part with respect to the prescribed wavelength and first and second transparent conductive films 104 and 105, which are transparent parts with respect to the prescribed wavelength, the first and second structures ST1 and ST2 have substantially similar forms in plan view and their centers of gravity do not coincide.

The surface emitting device 10-1 has a configuration in which the concave mirror 201a can be formed by oblique exposure performed using the first structure ST1 including the light emission layer 101 as a mask. In other words, the surface emitting device 10-1 has a configuration that can restrain the misalignment between the current injection region of the light emission layer 101 and the concave mirror 201a from increasing. The misalignment can be restrained from increasing, so that the threshold current can be kept from increasing or the reduction in the yield can be reduced.

In plan view, the distance between the center of the light emission region (current injection region) of the light emission layer 101 and the center of the concave mirror 201a is shorter than the distance between the centers of gravity G1 and G2 of the first and second structures ST1 and ST2. As a result, if the distance between the centers of gravity G1 and G2 of the first and second structures ST1 and ST2 in plan view is relatively long, the distance between the center of the light emission region of the light emission layer 101 and the center of the concave mirror 201a in plan view can be short.

The distance between the centers of gravity G1 and G2 of the first and second structures ST1 and ST2 in plan view is at least 50 nm. In this way, as compared to the misalignment (for example, less than 50 nm) which would be caused when the first and second structures ST1 and ST2 are aligned using alignment marks so that the centers of gravity G1 and G2 coincide for example in plan view, the misalignment between the current injection region and the concave mirror 201a can be smaller.

The distance between the center of the light emission region of the light emission layer 101 and the center of the concave mirror 201a in plan view is at most 500 nm. This effectively keeps the threshold current from increasing and the yield decreasing.

The plan view shape of the second structure ST2 may be a Fourier transformed shape of a plan view shape of the first structure ST1. This ensures alignment accuracy.

A plan view shape of the second structure ST2 may be a similar shape to a Fourier transformed shape of a plan view shape of the first structure ST1, with a coefficient of determination of at least 70%. This allows the misalignment to be kept within a practically acceptable range.

The anode electrode 103 as the opaque part has the first and second electrode pads 103a and 103b arranged in the in-plane direction. This allows the anode electrode 103 as a light-shielding pattern to have a simple structure.

The second electrode pad 103b surrounds the first electrode pad 103a. This allows the contact points for electrical connection with the laser driver to be arranged in a peripheral manner in the anode electrode 103.

The anode electrode 103 as the opaque part is made of metal, and the reflector 102 as the opaque part is made of dielectric. This makes it possible to form a light-shielding pattern with commonly available materials for surface emitting devices.

The first convex surface structure 50a is provided on another surface of the substrate 50, and the concave mirror 201a is provided along the first convex surface structure 50a. This secures the shape stability of the concave mirror 201a.

The first structure ST1 includes the reflector 102 provided on the side of the light emission layer 101 opposite to the side of the concave mirror 201a. As a result, the surface emitting device 10-1 can constitute a surface emitting laser.

The first and second examples of the method for manufacturing the surface emitting device 10-1 include forming a first structure ST1 including a light emission layer 101 on one side of a substrate 50 transparent to a prescribed wavelength (exposure wavelength), the first structure having opaque and transparent parts with respect to the above prescribed wavelength, applying a photosensitive material on another surface of the substrate 50, performing oblique exposure with light having the above prescribed wavelength from the side of the first structure ST1, and forming a second structure ST2 including a concave mirror 201a using a pattern formed on resist R (photosensitive material).

According to the first and second example of the method for manufacturing the surface emitting device 10-1, the concave mirror 201a can be formed by performing oblique exposure using the first structure ST1 including the light emission layer 101 as a mask. In other words, according to the method for manufacturing the surface emitting device 10-1, a surface emitting device having a configuration that can keep the misalignment between the current injection region of the light emission layer 101 and the concave mirror 201a from increasing can be provided.

The first structure ST1 includes the current constriction region 300 that defines the light emission region of the light emission layer 101, and in the step of forming the first structure ST1, the current constriction region 300 is preferably formed so that the light emission region is in a position corresponding to an exposure condition in the step of oblique exposure (for example, the direction of incidence of the exposure light to the first structure ST1) and the total of the thickness of the first structure ST1 and the thickness of the substrate 50. This allows the light emission region (current injection region) to be precisely aligned with the concave mirror 201a.

The exposure condition is preferably set on the basis of the total, or the total is preferably set on the basis of the exposure condition. This allows the light emission region (current injection region) and the concave mirror 201a to be aligned highly accurately.

In the second example of the method for manufacturing the surface emitting device 10-1, the thinning step, which is likely to cause the substrate 50 to crack, is performed in an early stage, and an additional manufacturing cost that would be necessitated by the cracking of the substrate 50 can be reduced.

As can be clearly understood from the above description, the surface emitting device 10-1 can also exhibit the following advantageous effects.

The alignment accuracy can be improved without adding any special function to the device.

The current injection region and the concave mirror 201a can be aligned and patterned with the alignment accuracy on the surface side of the substrate 50.

Patterning can be performed without being affected by the expansion and contraction of the substrate 50 in thinning the substrate 50.

The misalignment is reduced, so that the electrical characteristics, optical characteristics, and yield improve.

Since the first structure ST1 functions as a mask, the need to manufacture a separate mask is eliminated, which can reduce the manufacturing cost.

The manufacturing cost can be reduced when for example a mask is manufactured for partial exposure.

The manufacturing cost can be reduced by simplifying the alignment step and the exposure device.

The diameter of the first convex surface structure 50a can be controlled by controlling the outer diameter of the first electrode pad 103a, which allows the lateral mode to be controlled.

The pattern of the outer periphery of the resist R becomes unclear, so that the resist R can be tapered. In this way the radius of curvature can be increased, and the pitch can be narrowed.

The frequency of maintenance of the device can be reduced.

The total of the thickness of the first structure ST1 and the thickness of the substrate 50 and/or the direction of incidence of the exposure light can be controlled to reduce the misalignment between the current injection region and the concave mirror 201a.

### 2. SURFACE EMITTING DEVICE ACCORDING TO EXAMPLE 2 OF THE EMBODIMENT OF THE PRESENT TECHNOLOGY

Hereinafter, a surface emitting device according to Example 2 of the embodiment of the present technology will be described with reference to the drawings.

### <<Configuration of Surface Emitting Device>>

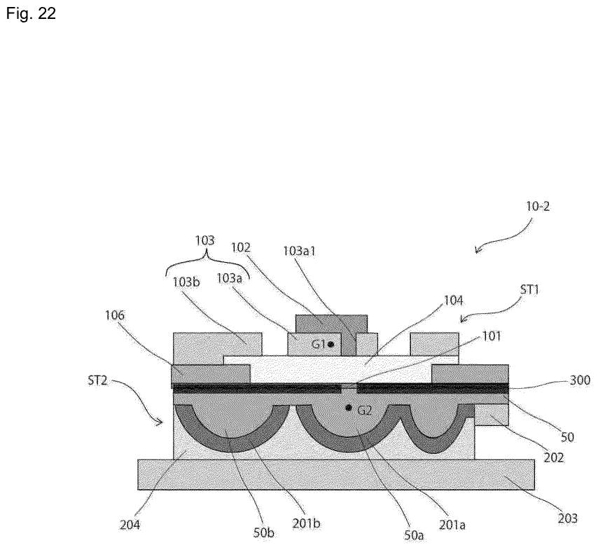

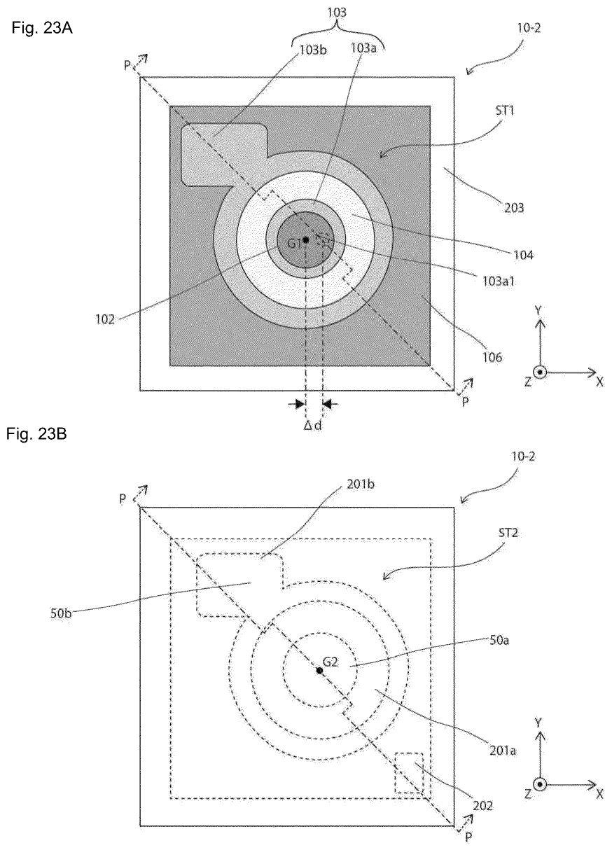

FIG. 22 is a cross-sectional view of a surface emitting device 10-2 according to Example 2 of the embodiment of the present technology FIG. 23A is a plan view of the surface emitting device in FIG. 22. FIG. 23B is a view of a second structure of the surface emitting device in FIG. 22 as viewed from the side of a first structure. FIG. 22 is a cross-sectional view along line P-P in FIGS. 23A and 23B. As shown in FIGS. 22, 23A, and 23B, the surface emitting device 10-2 has the same configuration as the surface emitting device 10-1 according to Example 1, except that the second transparent conductive film 105 is not provided.

### <<Operation of Surface Emitting Device>>

The surface emitting device 10-2 operates substantially in the same manner as the surface emitting device 10-1 according to Example 1.

### <<Method for Manufacturing Surface Emitting Device>>

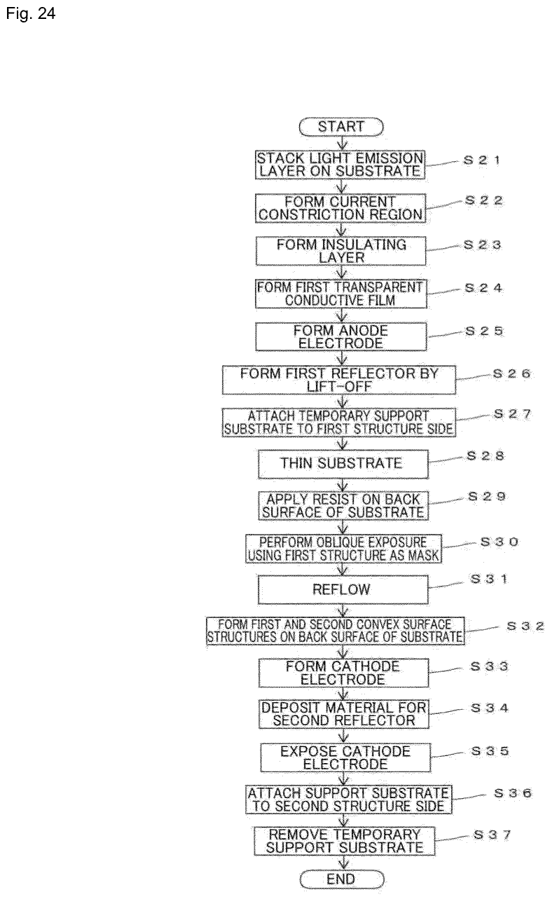

Hereinafter, a method for manufacturing the surface emitting device 10-2 will be described with reference to the flowchart in FIG. 24. Here, as an example, a plurality of surface emitting devices 10-2 are simultaneously produced on a single wafer (semiconductor substrate (such as an n-GaN substrate)) that is to be a base material for the substrate 50. Then, the plurality of surface emitting devices 10-2 in an integral form are separated from each other to obtain chip-shaped surface emitting devices 10-2 (surface emitting device chips).

In the first step S21, the light emission layer 101 (active layer) is stacked on the substrate 50 (see FIG. 4A). Specifically a laminate is produced by stacking the light emission layer 101 on the substrate 50 in a growth chamber for example by metal organic chemical vapor deposition (MOCVD) or molecular beam epitaxy (MBE).

In the next step S22, the current constriction region 300 is formed (see FIG. 4B). Specifically to start with, a protection film made for example of resist and SiO₂ is formed to cover the part of the laminate other than the part where the current constriction region 300 is to be formed (the part where the current injection region is to be formed). During the process, the protection film is formed so that the center of the current injection region is at a position apart from the center of gravity G1 of the first structure ST1 by Δd in the +X direction in plan view. Then, using the protection film as a mask, ions (for example, B++) are implanted into the laminate from the side of the light emission layer 101. In this case, the ions are implanted to such a depth that they reach inside of the substrate 50.

In the next step S23, the insulating layer 106 is formed. Specifically to start with, the insulating layer 106 is deposited on the entire surface for example by vacuum evaporation or sputtering (see FIG. 5A). Then, a center part of the insulating layer 106 is removed by photolithography to form the insulating layer 106 in an annular shape (see FIG. 5B).

In the next step S24, the first transparent conductive film 104 is formed (see FIG. 6A). Specifically to start with, a transparent conductive film, which is the material for the first transparent conductive film 104, is deposited on the entire surface for example by vacuum evaporation or sputtering. Then, the first transparent conductive film 104 is formed by removing a peripheral part of the transparent conductive film by photolithography.

In the next step S25, the anode electrode 103 is formed (see FIG. 6B). Specifically, the first and second electrode pads 103a and 103b of the anode electrode 103 are formed for example by lift-off. During the process, the first electrode pad 103a is formed so that the center of the through hole 103a1 of the first electrode pad 103a and the center of the current injection region substantially coincide in plan view. The electrode material for the anode electrode 103 is deposited for example by vacuum evaporation or sputtering.

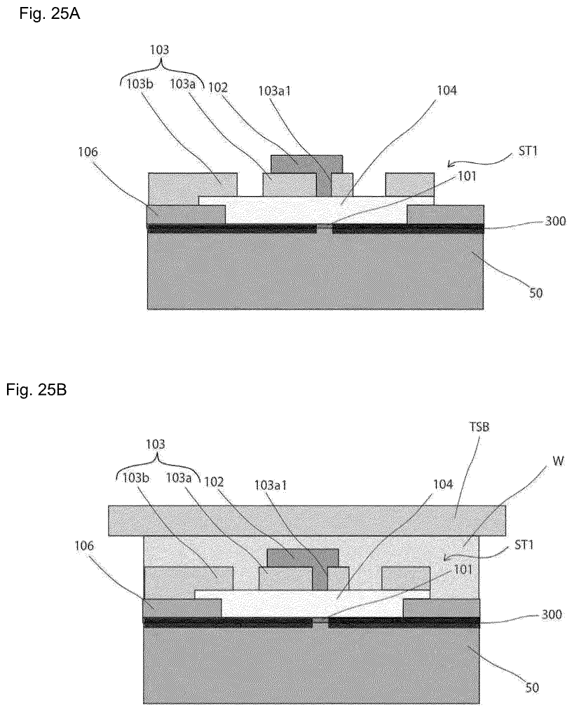

In the next step S26, the reflector 102 as the first reflector is formed by lift-off (see FIG. 25A). Specifically to start with, resist is formed to cover the area where the reflector 102 (for example, plane mirror) is not formed. Then, a dielectric multilayer film, which is a material for the reflector 102, is deposited on the entire surface for example by vacuum evaporation, sputtering, or CVD. Then, the resist and the dielectric multilayer film on the resist are removed. As a result, the reflector 102 is formed.

In the next step S27, a temporary support substrate TSB is attached to the side of the first structure ST1 (see FIG. 25B). Specifically, the temporary support substrate TSB (such as a sapphire substrate) is attached to the side of the first structure ST1 through wax W.

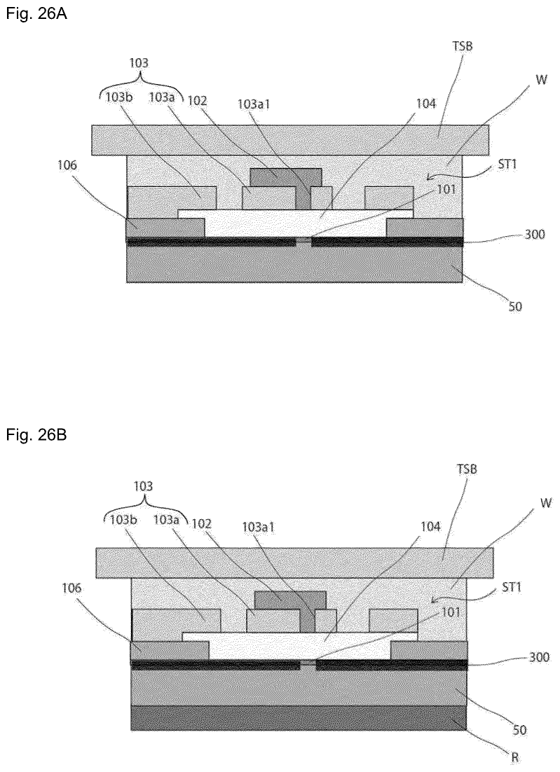

In the next step S28, the substrate 50 is thinned (see FIG. 26A). Specifically, the substrate 50 is thinned by polishing the back surface of the substrate 50 using for example a CMP (chemical mechanical polishing) device.

In the next step S29, resist R (such as positive photoresist) is applied on the back surface of the substrate 50 (see FIG. 26B). Specifically the resist R is applied flat on the back surface of the substrate 50.

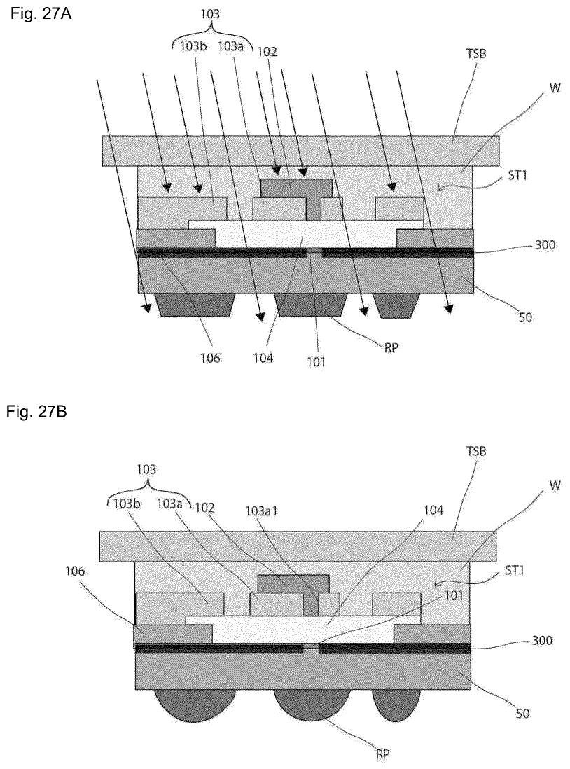

In the next step S30, oblique exposure is performed using the first structure ST1 as a mask (see FIG. 27A). Specifically to start with, exposure light with the above-described prescribed wavelength (exposure wavelength) is obliquely entered at a prescribed angle of incidence θ along an XZ plane (see FIG. 23A) from the side of the first structure ST1 by an exposure device. At the time, the exposure light is blocked by the anode electrode 103 and the reflector 102, which are opaque with respect to the prescribed wavelength and transmitted through the first transparent conductive film 104, which is transparent to the prescribed wavelength. As a result, a latent image corresponding to the mask pattern of the first structure ST1 is formed on the resist R. Then, the resist R is immersed in a developing solution to reveal the latent image. As a result, a resist pattern RP is formed by the parts not irradiated with the exposure light. The resist pattern RP has a substantially similar form in plan view to the first structure ST1, and its center of gravity does not coincide with that of the first structure ST1. Here, the angle of incidence θ corresponding to the distance D and Δd is selected in order to shift the center of gravity of the resist pattern RP from the center of gravity G1 of the first structure ST1 by Δd in the +X direction in plan view. The angle of incidence θ is preferably set while directly measuring the angle of incidence of the exposure light emitted from the exposure device and entered on the first structure ST1.

In the next step S31, reflow is performed (see FIG. 27B). Specifically the resist pattern balls up by reflow (for example at 200° C.) and is formed into a substantially hemispherical convex surface shape.

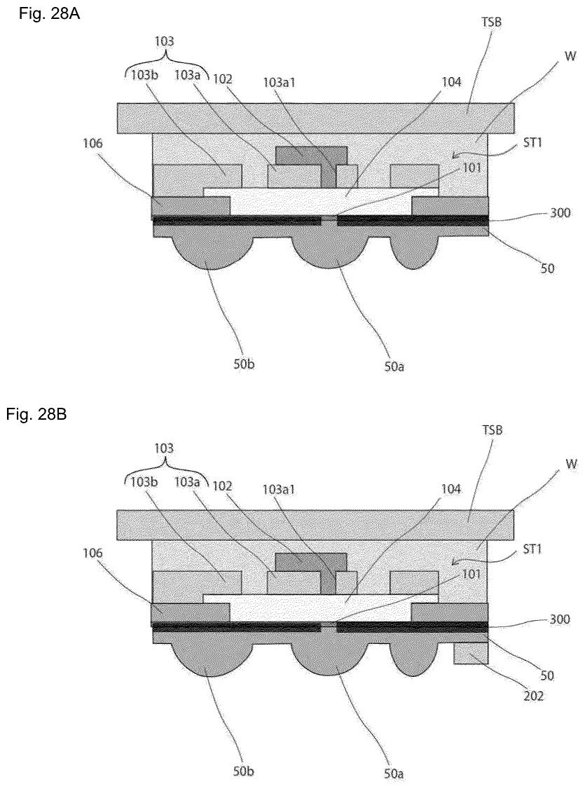

In the next step S32, the first and second convex surface structures 50a and 50b are formed on the back surface of the substrate 50 (see FIG. 28A). Specifically the first and second convex surface structures 50a and 50b are formed by etching (for example by dry etching) the substrate 50 using the resist pattern RP which has balled up as a mask.

In the next step S33, the cathode electrode 202 is formed (see FIG. 28B). Specifically the cathode electrode 202 is formed on the back surface of the substrate 50 for example by lift-off. In this case, the electrode material for the cathode electrode 202 is deposited for example by vacuum evaporation or sputtering.

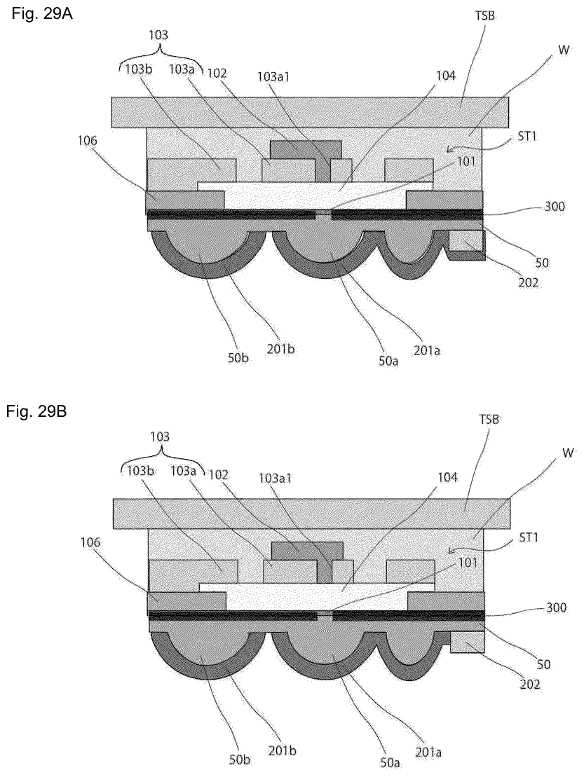

In the next step S34, a material for the concave mirror 201a as the second reflector is deposited (see FIG. 29A). Specifically a dielectric multilayer film, which is a material for the concave mirror 201a, is deposited on the entire surface for example by vacuum evaporation, sputtering, or CVD.

In the next step S35, the cathode electrode 202 is exposed (see FIG. 29B). Specifically the dielectric multilayer film on the cathode electrode 202 is removed for example by dry etching.

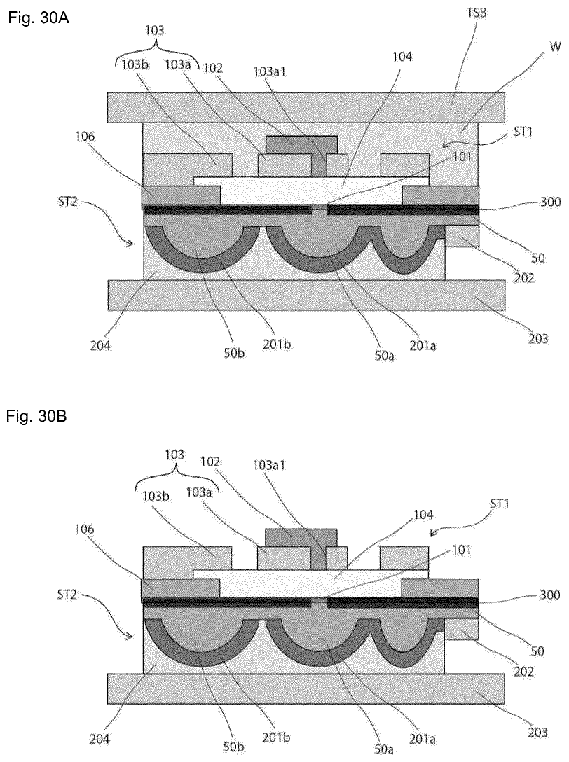

In the next step S36, the support substrate 203 is attached to the side of the second structure ST2 (see FIG. 30A). Specifically, the support substrate 203 is attached to the side of the second structure ST2 through wax 204.

In the final step S37, the temporary support substrate TSB is removed (see FIG. 30B). Specifically the wax W is dissolved by heating, and the temporary support substrate TSB and the wax W are removed. In this way a plurality of surface emitting devices 10-2 are produced on the wafer (semiconductor substrate (such as an n-GaN substrate)). Thereafter, the plurality of surface emitting devices 10-2 in an integral form are separated by dicing to obtain chip-shaped surface emitting devices 10-2 (surface emitting device chips).

### <<Advantageous Effects of Surface Emitting Device and Method for Manufacturing Therefor>>

The surface emitting device 10-2 does not have the second transparent conductive film 105, and therefore can have a simplified structure. According to the method for manufacturing the surface emitting device 10-2, since the reflector 102 is formed by lift-off, damage to the first transparent conductive film 104 can be reduced and the electrical characteristics and yield can be improved. Furthermore, the step of etching the reflector 102 and the step of forming the second transparent conductive film 105 can be omitted, which can reduce the manufacturing cost.

### 3. SURFACE EMITTING DEVICE ACCORDING TO EXAMPLE 3 OF THE EMBODIMENT OF THE PRESENT TECHNOLOGY

Hereinafter, a surface emitting device according to Example 3 of the embodiment of the present technology will be described with reference to the drawings.

### <<Configuration of Surface Emitting Device>>

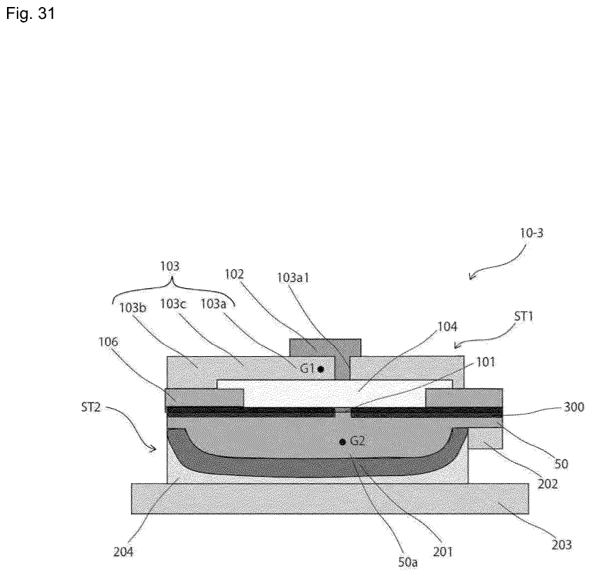

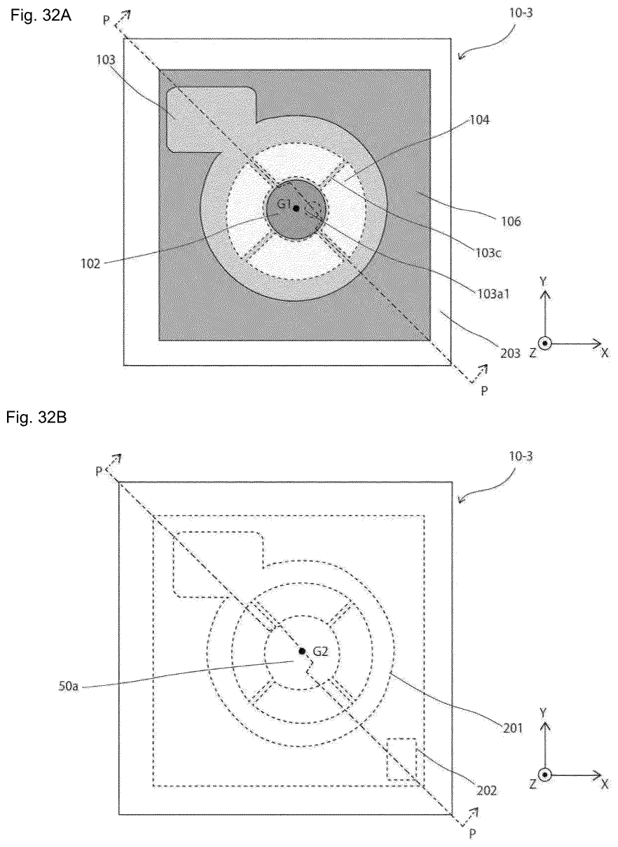

FIG. 31 is a cross-sectional view of a surface emitting device 10-3 according to Example 3 of the embodiment of the present technology. FIG. 32A is a plan view of the surface emitting device in FIG. 31. FIG. 32B is a view of a second structure of the surface emitting device in FIG. 31 as viewed from the side of a first structure. FIG. 31 is a cross-sectional view taken along line P-P in FIGS. 32A and 32B.

As shown in FIGS. 31, 32A, and 32B, the surface emitting device 10-3 has substantially the same configuration as the surface emitting device 10-2 according to Example 2 except that the second convex surface structure 50b is not provided, the first convex surface structure 50a constitutes a convex surface structure with a large diameter, and the anode electrode 103 has a connection part 103c that connects the first and second electrode pads 103a and 103b.

In the surface emitting device 10-3, as an example, a plurality (such as four) of the connection parts 103c that connect the first and second electrode pads 103a and 103b extend radially (for example, in four directions) from the first electrode pad 103a to the second electrode pad 103b (see FIG. 32A). In other words, in the surface emitting device 10-3, the anode electrode 103 includes a single electrode pad in which the first and second electrode pads 103a and 103b are connected through the plurality of connection parts 103c.

In the surface emitting device 10-3, as an example, the concave mirror 201 as the second reflector includes a dielectric multilayer film provided on the entire area of the first convex surface structure 50a.

### <<Operation of Surface Emitting Device>>

The surface emitting device 10-3 operates substantially in the same manner as the surface emitting device 10-1 according to Example 1.

### <<Method for Manufacturing Surface Emitting Device>>

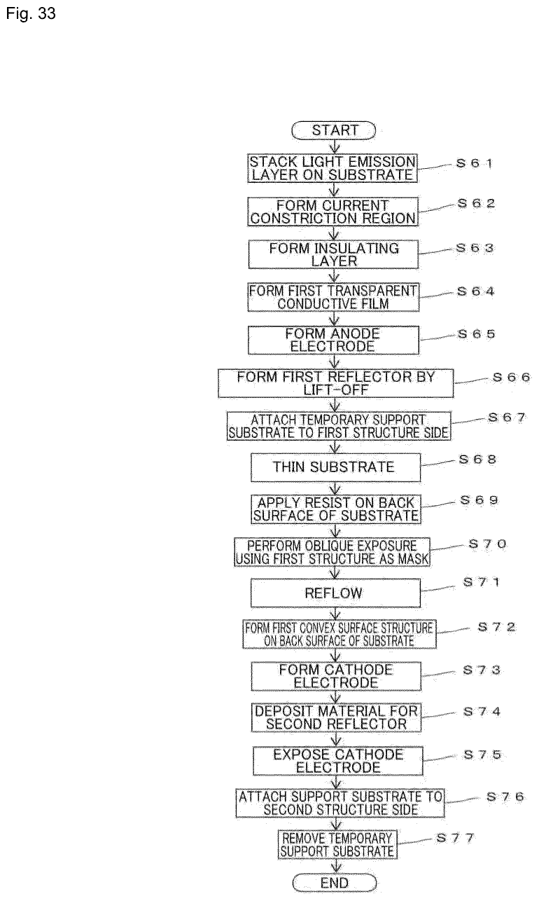

Hereinafter, a method for manufacturing the surface emitting device 10-3 will be described with reference to the flowchart in FIG. 33. Here, as an example, a plurality of surface emitting devices 10-3 are simultaneously produced on a single wafer (semiconductor substrate (such as an n-GaN substrate)) that is to be a base material for the substrate 50. Then, the plurality of surface emitting devices 10-3 in an integral form are separated from each other to obtain chip-shaped surface emitting devices 10-3 (surface emitting device chips).

In the first step S61, the light emission layer 101 (active layer) is stacked on the substrate 50 (see FIG. 4A). Specifically a laminate is produced by stacking the light emission layer 101 on the substrate 50 in a growth chamber by metal organic chemical vapor deposition (MOCVD) or molecular beam epitaxy (MBE).

In the next step S62, the current constriction region 300 is formed (see FIG. 4B). Specifically to start with, a protection film for example made of resist and SiO₂ is formed to cover the part of the laminate other than the part where the current constriction region 300 is to be formed (the part where the current injection region is to be formed). In this case, the protection film is formed so that the center of the current injection region is at a position apart from the center of gravity G1 of the first structure ST1 by Δd in the +X direction in plan view. Then, using the protection film as a mask, ions (for example, B++) are implanted into the laminate from the side of the light emission layer 101. In this case, the ions are implanted to such a depth that they reach inside of the substrate 50.

In the next step S63, the insulating layer 106 is formed. Specifically to start with, the insulating layer 106 is deposited on the entire surface for example by vacuum evaporation or sputtering (see FIG. 5A). Next, the center of the insulating layer 106 is removed by photolithography to form the insulating layer 106 in an annular shape (see FIG. 5B).

In the next step S64, the first transparent conductive film 104 is formed (see FIG. 6A). Specifically to start with, a transparent conductive film, which is a material for the first transparent conductive film 104, is deposited on the entire surface for example by vacuum evaporation or sputtering. Then, the first transparent conductive film 104 is formed by removing a peripheral part of the transparent conductive film by photolithography.

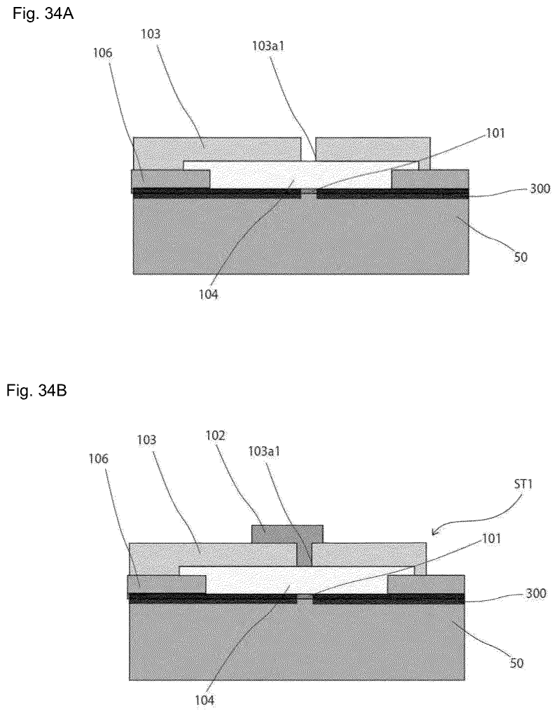

In the next step S65, the anode electrode 103 is formed (see FIG. 34A). Specifically, for example, the first and second electrode pads 103a and 103b and the connection part 103c of the anode electrode 103 are formed integrally by lift-off. In this way, the anode electrode 103 is formed so that the center of the through hole 103a1 and the center of the current injection region are substantially coincident in plan view. The electrode material for the anode electrode 103 is formed for example by vacuum evaporation or sputtering.

In the next step S66, the reflector 102 as the first reflector is formed by lift-off (see FIG. 34B). Specifically, to start with, resist is formed to cover the areas where the reflector 102 (for example, plane mirror) is not formed. Then, a dielectric multilayer film, which is a material for the reflector 102, is deposited on the entire surface for example by vacuum evaporation, sputtering, or CVD.

Then, the resist and the dielectric multilayer film on the resist are removed. As a result, the reflector 102 is formed.

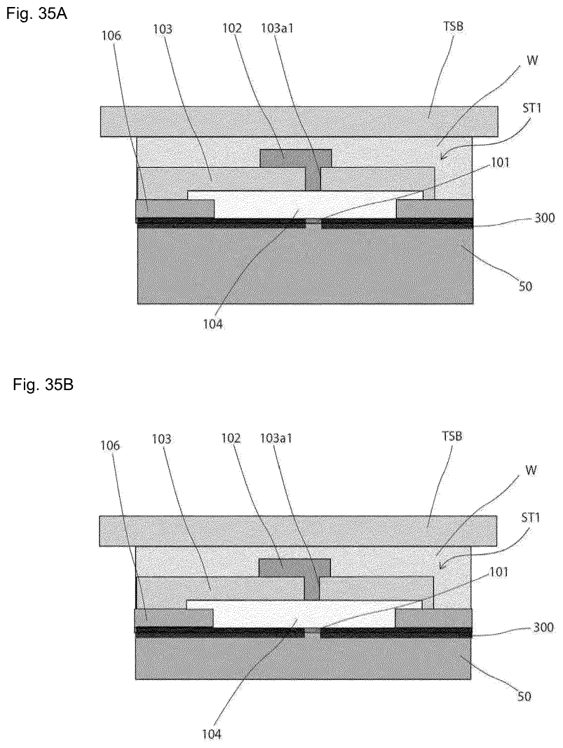

In the next step S67, a temporary support substrate TSB is attached to the side of the first structure ST1 (see FIG. 35A). Specifically, the temporary support substrate TSB (such as a sapphire substrate) is attached to the side of the first structure ST1 through wax W.

In the next step S68, the substrate 50 is thinned (see FIG. 35B). Specifically, the substrate 50 is thinned by polishing the back surface of the substrate 50 using for example a CMP (chemical mechanical polishing) device.

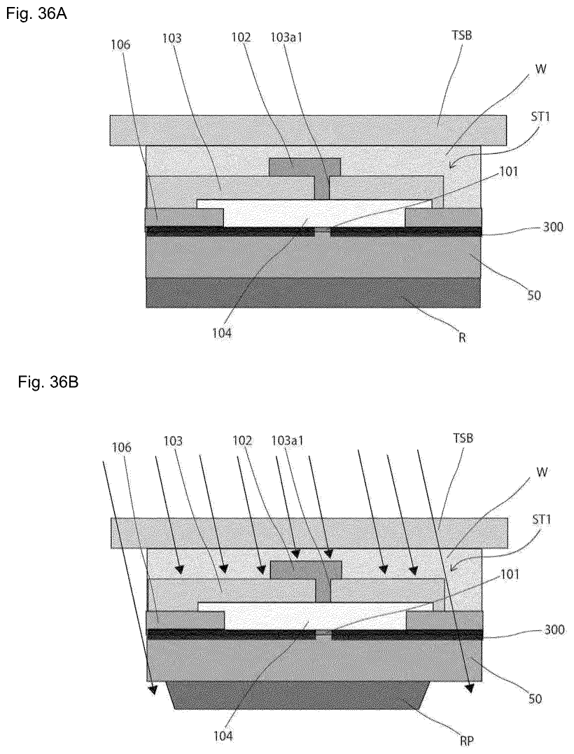

In the next step S69, resist R (such as positive photoresist) is applied on the back surface of the substrate 50 (see FIG. 36A). Specifically the resist R is applied flat on the backside of the substrate 50.

In the next step S70, oblique exposure is performed using the first structure ST1 as a mask (see FIG. 36B). Specifically to start with, exposure light with the above-described prescribed wavelength (exposure wavelength) is obliquely entered at a prescribed angle of incidence θ along an XZ plane (see FIG. 32A) from the side of the first structure ST1 by an exposure device. At the time, the exposure light is blocked by the anode electrode 103 and the reflector 102, which are opaque with respect to the prescribed wavelength, and transmitted through the first transparent conductive film 104, which is transparent to the prescribed wavelength. As a result, a latent image corresponding to the mask pattern of the first structure ST1 is formed on the resist R. Then, the resist R is immersed in a developing solution to reveal the latent image. As a result, a resist pattern RP is formed by the parts not irradiated with the exposure light. The resist pattern RP has a substantially similar form in plan view to the first structure ST1, and its center of gravity does not coincide with that of the first structure ST1. Here, the angle of incidence θ corresponding to the distance D and Δd is selected in order in order to shift the center of gravity of the resist pattern RP from the center of gravity G1 of the first structure ST1 in the +X direction by Δd in plan view. The angle of incidence θ is preferably set while directly measuring the angle of incidence of the exposure light emitted from the exposure device and entered on the first structure ST1.

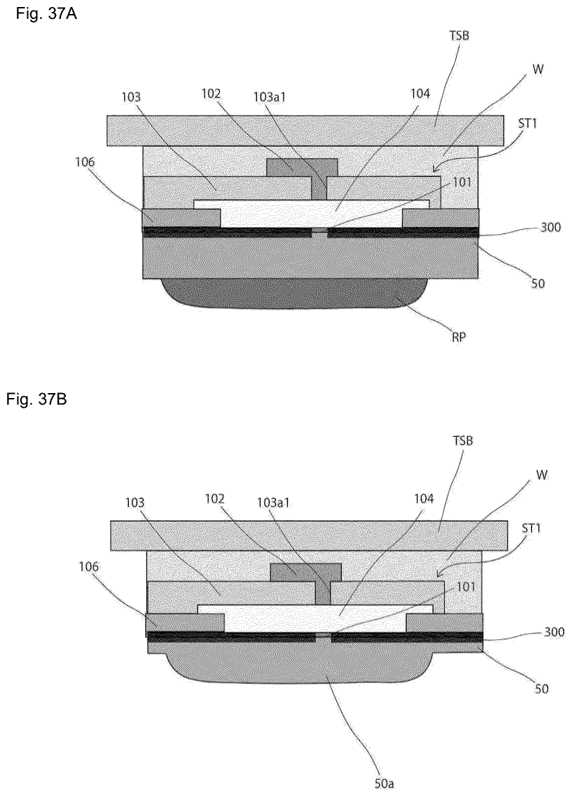

In the next step S71, reflow (for example at 200° C.) is performed (see FIG. 37A). Specifically the resist pattern balls up by reflow and is formed into a convex surface shape with a large diameter.

In the next step S72, the first convex surface structure 50a is formed on the back side of the substrate 50 (see FIG. 37B). Specifically by etching (for example by dry etching) the substrate 50 using the resist pattern RP which has balled up as a mask, the first convex surface structure 50a with a large diameter is formed.

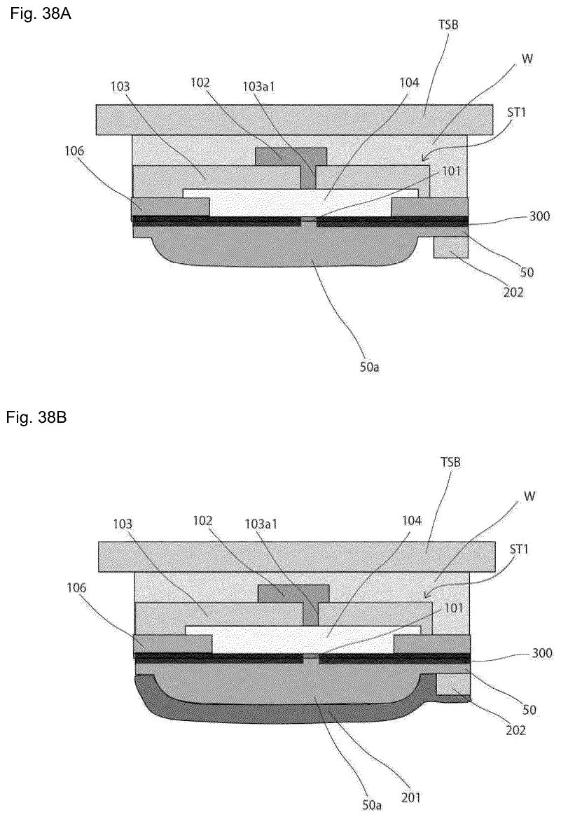

In the next step S73, the cathode electrode 202 is formed (see FIG. 38A). Specifically the cathode electrode 202 is formed on the back surface of the substrate 50 for example by lift-off. In this case, the electrode material for the cathode electrode 202 is deposited for example by vacuum evaporation or sputtering.

In the next step S74, a material for the concave mirror 201 as the second reflector is deposited (see FIG. 38B). Specifically a dielectric multilayer film, which is a material for the concave mirror 201a, is deposited on the entire surface for example by vacuum evaporation, sputtering, or CVD.

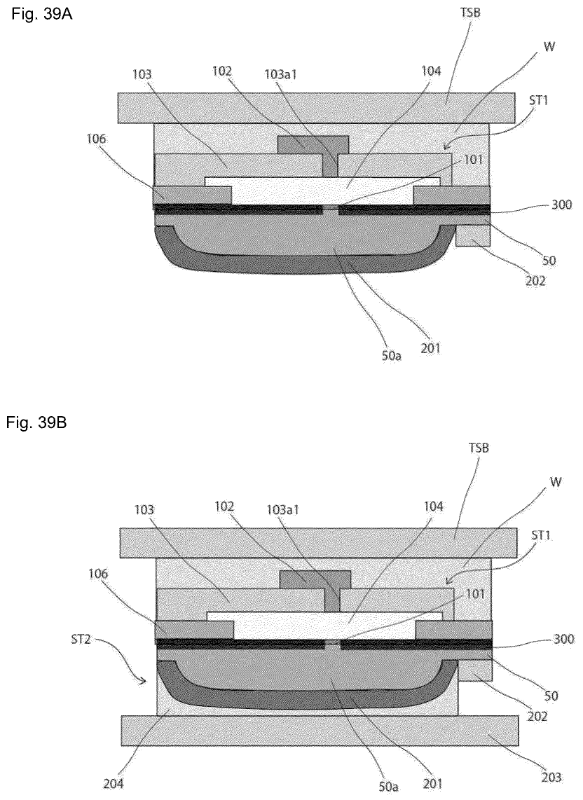

In the next step S75, the cathode electrode 202 is exposed (see FIG. 39A). Specifically the dielectric multilayer film on the cathode electrode 202 is removed for example by dry etching.

In the next step S76, the support substrate 203 is attached to the side of the second structure ST2 (see FIG. 39B). Specifically the support substrate 203 is attached to the side of the second structure ST2 through wax 204.

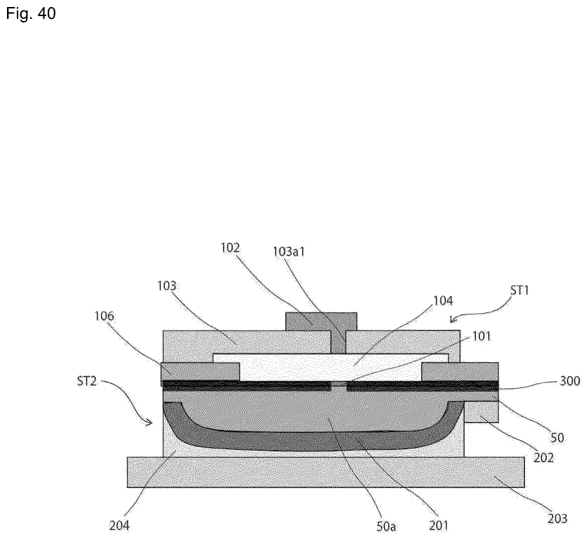

In the final step S77, the temporary support substrate TSB is removed (see FIG. 40). Specifically the wax W is dissolved by heating, and the temporary support substrate TSB and the wax W are removed. As a result, a plurality of surface emitting devices 10-3 are produced on the wafer (a semiconductor substrate (such as an n-GaN substrate)). Thereafter, the plurality of surface emitting devices 10-3 in an integral form are separated by dicing to obtain chip-shaped surface emitting devices 10-3 (surface emitting device chips).

### <<Advantageous Effects of Surface Emitting Device>>

In the surface emitting device 10-3, the anode electrode 103 includes a single electrode pad in which the first and second electrode pads 103a and 103b are connected through the plurality of connection parts 103c, and therefore the current density in the first transparent conductive film 104 can be reduced, so that the reliability and thus the electrical characteristics can be improved. In addition, the increased diameter (increased radius of curvature) of the first convex surface structure 50a also allows for lateral mode suppression.

### 4. SURFACE EMITTING DEVICE ACCORDING TO EXAMPLE 4 OF THE EMBODIMENT OF THE PRESENT TECHNOLOGY

Hereinafter, a surface emitting device according to Example 4 of the embodiment of the present technology will be described with reference to the drawings.

### <<Configuration of Surface Emitting Device>>

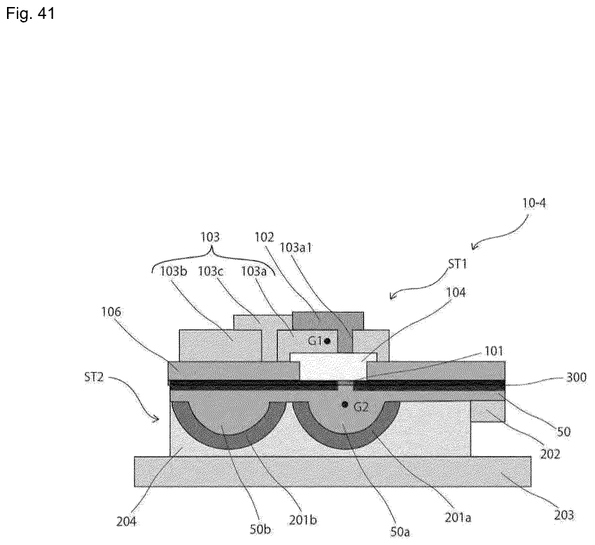

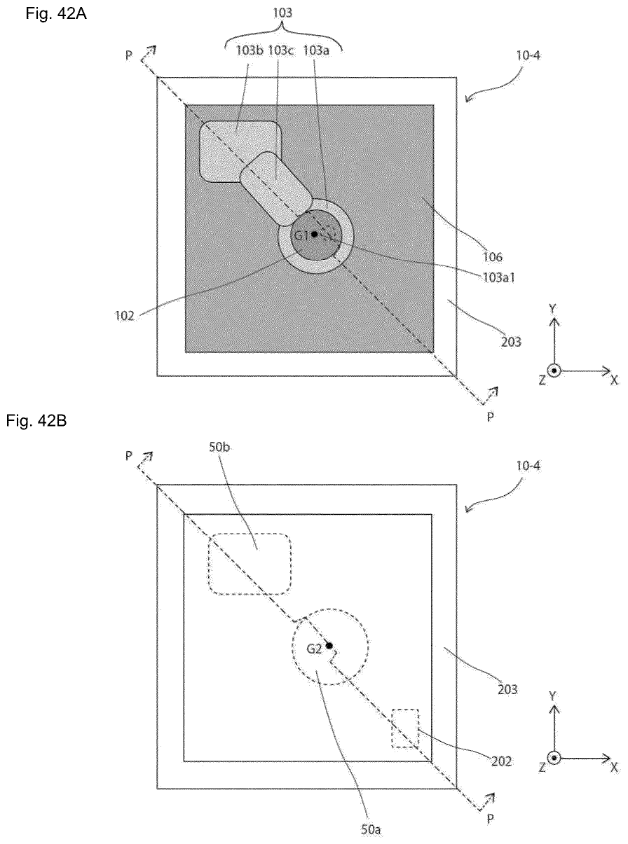

FIG. 41 is a cross-sectional view of a surface emitting device 10-4 according to Example 4 of the embodiment of the present technology. FIG. 42A is a plan view of the surface emitting device in FIG. 40. FIG. 42B is a view of a second structure of the surface emitting device in FIG. 41 from the side of a first structure. FIG. 41 is a cross-sectional view taken along line P-P in FIGS. 42A and 42B.

As shown in FIGS. 41, 42A, and 42B, the surface emitting device 10-4 has substantially the same configuration as the surface emitting device 10-2 according to Example 2 except that the second electrode pad 103b does not surround the first electrode pad 103a and the anode electrode 103 has a connection part 103c that connects the first and second electrode pads 103a and 103b.

In the surface emitting device 10-4, as an example, the connection part 103c overlaps at least one (for example, both) of the first and second electrode pads 103a and 103b. The connection part 103c is discrete from the first and second electrode pads 103a and 103b. The connection part 103c may be made of the same electrode material as the electrode material of the first and second electrode pads 103a and 103b or may be made of a different electrode material.

### <<Operation of Surface Emitting Device>>

The surface emitting device 10-4 operates substantially in the same manner as that of the surface emitting device 10-1 according to Example 1.

### <<Method for Manufacturing Surface Emitting Device>>

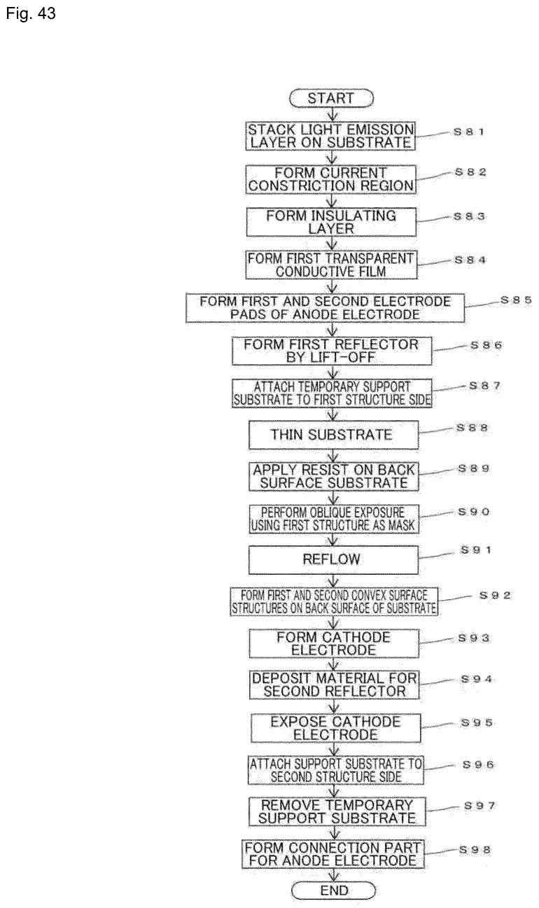

A method for manufacturing the surface emitting device 10-4 will be described for example with reference to the flowchart in FIG. 43. Here, as an example, a plurality of surface emitting devices 10-4 are simultaneously produced on a single wafer (a semiconductor substrate (such as an n-GaN substrate)) that is to be a base material for the substrate 50. Then, the plurality of surface emitting devices 10-4 in an integral form are separated from each other to obtain chip-shaped surface emitting devices 10-4 (surface emitting device chips).

In the first step S81, the light emission layer 101 (active layer) is stacked on the substrate 50 (see FIG. 4A). Specifically a laminate is produced by stacking the light emission layer 101 on the substrate 50 in a growth chamber by metal organic chemical vapor deposition (MOCVD) or molecular beam epitaxy (MBE).

In the next step S82, the current constriction region 300 is formed (see FIG. 4B). Specifically to start with, a protection film for example made of resist and SiO₂ is formed to cover the part of the laminate other than the part where the current constriction region 300 is to be formed (the part where the current injection region is to be formed). During the process, the protection film is formed so that the center of the current injection region is at a position apart from the center of gravity G1 of the first structure ST1 by Δd in the +X direction in plan view. Then, using the protection film as a mask, ions (for example, B++) are implanted into the laminate from the side of the light emission layer 101. In this case, the ions are implanted to such a depth that they reach inside of the substrate 50.

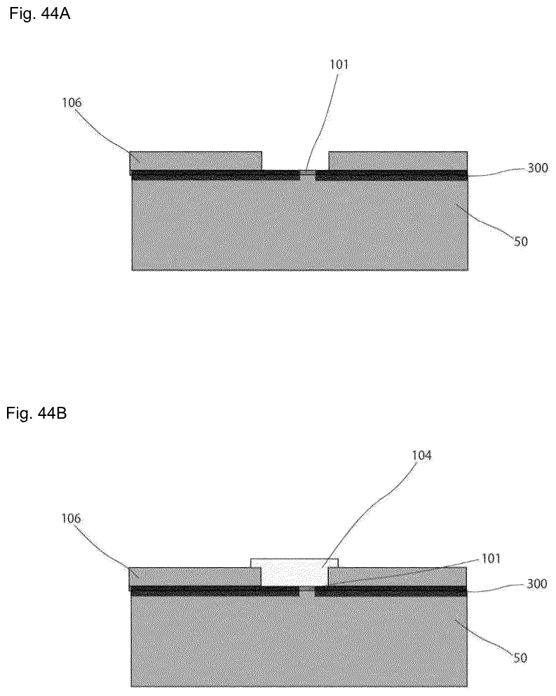

In the next step S83, the insulating layer 106 is formed. Specifically to start with, the insulating layer 106 is deposited on the entire surface for example by vacuum evaporation or sputtering (see FIG. 5A). Then, a center part of the insulating layer 106 is removed by photolithography to form the insulating layer 106 in an annular shape (see FIG. 44A).

In the next step S84, the first transparent conductive film 104 is formed (see FIG. 44B). Specifically to start with, a transparent conductive film, which is a material for the first transparent conductive film 104, is deposited on the entire surface for example by vacuum evaporation or sputtering. Then, a peripheral part of the transparent conductive film is removed by photolithography to form the first transparent conductive film 104.

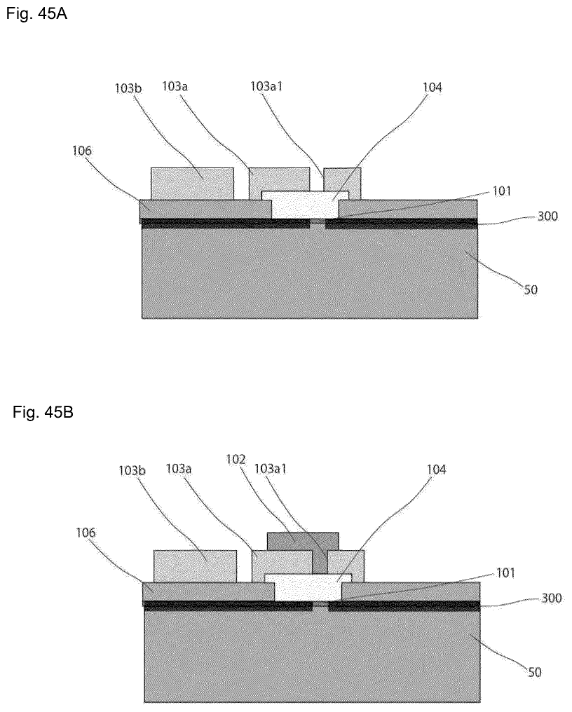

In the next step S85, the first and second electrode pads 103a and 103b of the anode electrode 103 are formed (see FIG. 45A). Specifically, the first and second electrode pads 103a and 103b of the anode electrode 103 are formed for example by lift-off. During the process, the first electrode pad 103a is formed so that the center of the through hole 103a1 of the first electrode pad 103a and the center of the current injection region are substantially coincident. The electrode material for the anode electrode 103 is deposited for example by vacuum evaporation or sputtering.

In the next step S86, the reflector 102 as the first reflector is formed by lift-off (see FIG. 45B). Specifically, to start with, resist is formed to cover the part where the reflector 102 (for example, plane mirror) is not formed. Then, a dielectric multilayer film, which is a material for the reflector 102, is deposited on the entire surface for example by vacuum evaporation, sputtering, or CVD. Then, the resist and the dielectric multilayer film on the resist are removed. As a result, the reflector 102 is formed.

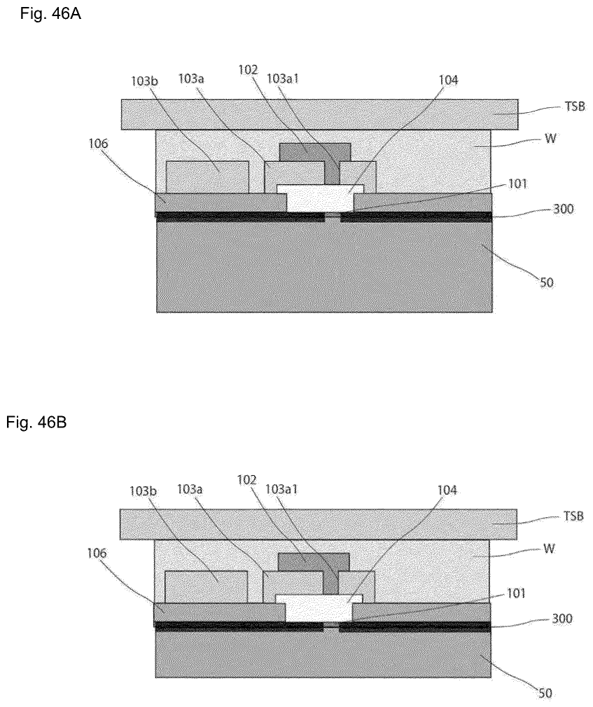

In the next step S87, the temporary support substrate TSB is attached to the side of the first structure ST1 (see FIG. 46A). Specifically, the temporary support substrate TSB (such as a sapphire substrate) is attached to the side of the first structure ST1 through wax W.

In the next step S88, the substrate 50 is thinned (see FIG. 46B). Specifically, the substrate 50 is thinned by polishing the back surface of the substrate 50 using for example a CMP (chemical mechanical polishing) device.

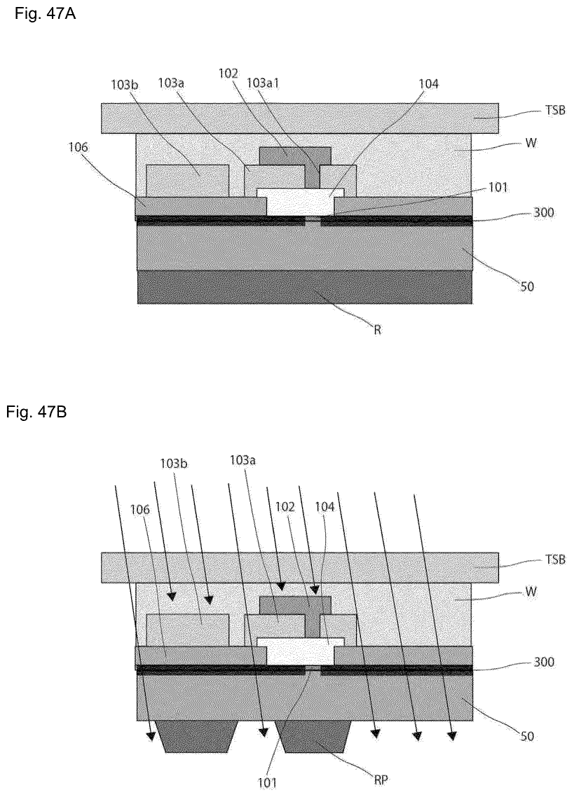

In the next step S89, resist R (such as positive photoresist) is applied on the back surface of the substrate 50 (see FIG. 47A). Specifically the resist R is applied flat on the backside of the substrate 50.

In the next step S90, oblique exposure is performed using the first structure ST1 as a mask (see FIG. 47B). Specifically to start with, exposure light with the above-described prescribed wavelength (exposure wavelength) is obliquely entered at a prescribed angle of incidence θ along an XZ plane (see FIG. 42A) from the side of the first structure ST1 by an exposure device. The exposure light is blocked by the anode electrode 103 and the reflector 102, which are opaque parts with respect to the prescribed wavelength, and transmitted through the first transparent conductive film 104, which is transparent to the prescribed wavelength. As a result, a latent image corresponding to the mask pattern of the first structure ST1 is formed on the resist R. Then, the resist R is immersed into a developing solution to reveal the latent image. As a result, a resist pattern RP is formed by the parts not irradiated with the exposure light. The resist pattern RP has a substantially similar form in plan view to the first structure ST1, and its center of gravity does not coincide with that of the first structure ST1. Here, an angle of incidence θ corresponding to the distance D and Δd is selected in order to shift the center of gravity of the resist pattern RP from the center of gravity G1 of the first structure ST1 in the +X direction by Δd in plan view. The angle of incidence θ is preferably set while directly measuring the angle of incidence of the exposure light emitted from the exposure device and entered on the first structure ST1.

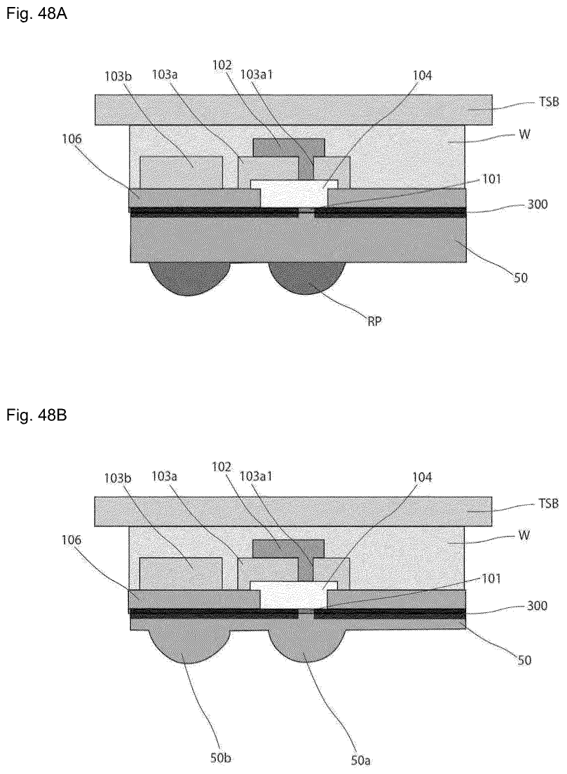

In the next step S91, reflow is performed (see FIG. 48A). Specifically the resist pattern RP balls up by reflow (for example at 200° C.) and is formed into a convex surface shape.

In the next step S92, the first and second convex surface structures 50a and 50b are formed on the back surface of the substrate 50 (see FIG. 48B). Specifically the first and second convex surface structures 50a and 50b are formed by etching (for example by dry etching) the substrate 50 using the resist pattern RP that has balled up as a mask.

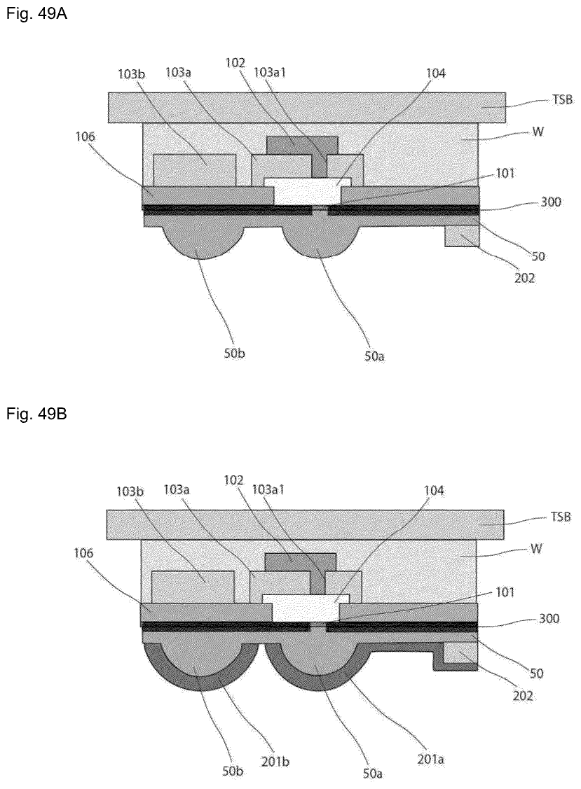

In the next step S93, the cathode electrode 202 is formed (see FIG. 49A). Specifically the cathode electrode 202 is formed on the back surface of the substrate 50 for example by lift-off. In this case, an electrode material for the cathode electrode 202 is deposited for example by vacuum evaporation or sputtering.

In the next step S94, a material for the concave mirror 201 as the second reflector is deposited (see FIG. 49B). Specifically a dielectric multilayer film, which is a material for the concave mirror 201a, is deposited on the entire surface for example by vacuum evaporation, sputtering, or CVD.

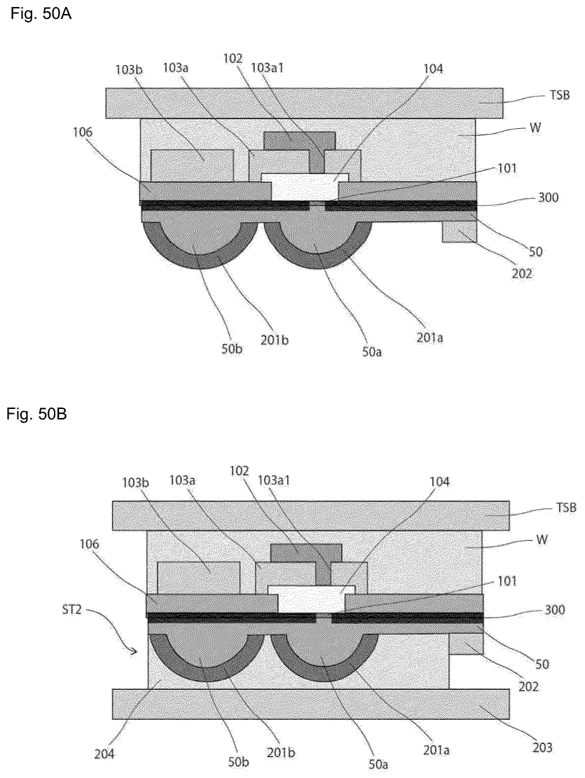

In the next step S95, the cathode electrode 202 is exposed (see FIG. 50A). Specifically the dielectric multilayer film on the cathode electrode 202 is removed example by dry etching.

In the next step S96, the support substrate 203 is attached to the side of the second structure ST2 (see FIG. 50B). Specifically, the support substrate 203 is attached to the side of the second structure ST2 through wax 204.

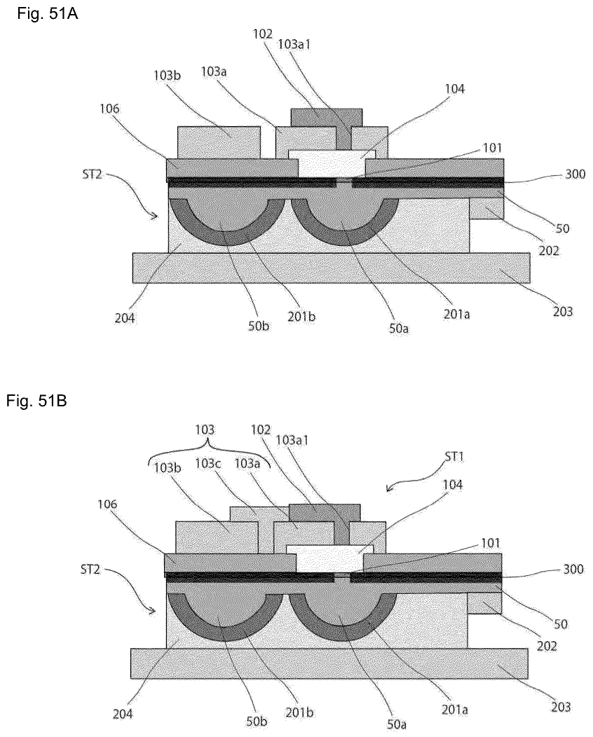

In the next step S97, the temporary support substrate TSB is removed (see FIG. 51A). Specifically the wax W is dissolved by heating, and the temporary support substrate TSB and the wax W are removed. As a result, a plurality of surface emitting devices 10-4 are produced on the wafer (semiconductor substrate (such as an n-GaN substrate)). Thereafter, the plurality of surface emitting devices 10-4 in an integral form are separated by dicing to obtain chip-shaped surface emitting devices 10-4 (surface emitting device chips).

In the final step S98, the connection part 103c of the anode electrode 103 is formed (see FIG. 51B). Specifically an electrode material for the connection part 103c is formed for example by lift-off to fill the gap between the first and second electrode pads 103a and 103b and to extend over the first and second electrode pads 103a and 103b.

### <<Advantageous Effects of Surface Emitting Device>>

In the surface emitting device 10-4, the second electrode pad 103b is reduced in size, so that the device area can be reduced and the yield can be increased. Furthermore, the surface emitting device 10-4 allows the wiring resistance to be reduced, and therefore the light emission efficiency can be improved (with reduced threshold current).

### 5. SURFACE EMITTING DEVICE ACCORDING TO EXAMPLE 5 OF THE EMBODIMENT OF THE PRESENT TECHNOLOGY

Hereinafter, a surface emitting device according to Example 5 of the embodiment of the present technology will be described with reference to the drawings.

### <<Configuration of Surface Emitting Device>>

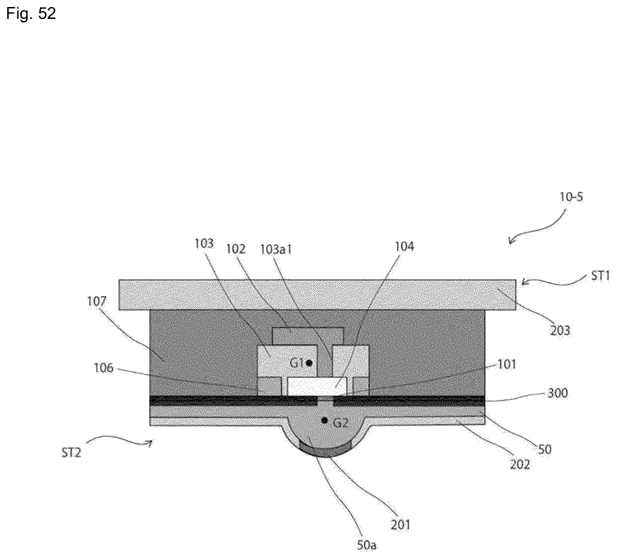

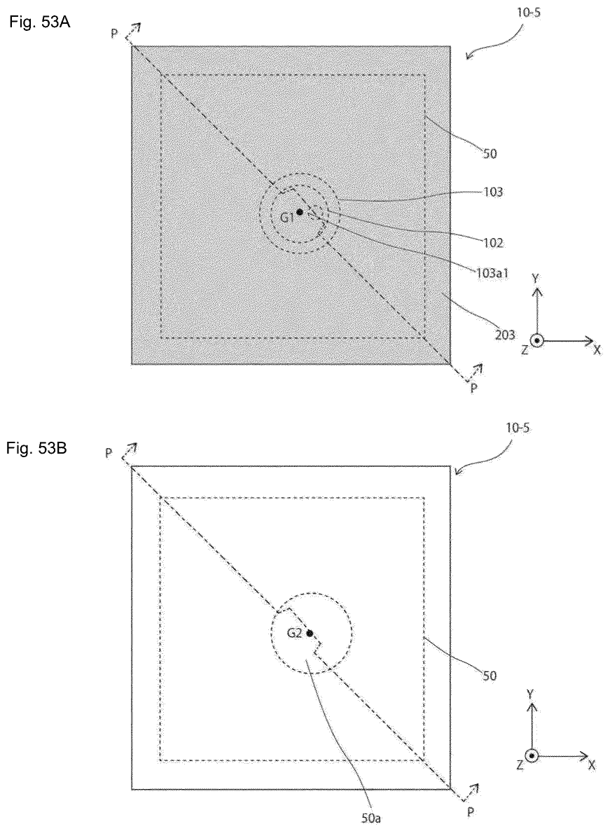

FIG. 52 is a cross-sectional view of the surface emitting device 10-5 according to Example 5 of the embodiment of the present technology. FIG. 53A is a plan view of the surface emitting device FIG. 52. FIG. 53B is a view of a second structure of the surface emitting device in FIG. 52 as viewed from the side of a first structure. FIG. 52 is a cross-sectional view along line P-P of FIGS. 53A and 53B.

As shown in FIGS. 52, 53A, and 53B, the surface emitting device 10-5 has substantially the same configuration as the surface emitting device 10-1 according to Example 1 except that the anode electrode 103 includes only the first electrode pad, the second transparent conductive film 105 is not provided, the support substrate 203 is attached through conductive paste 107 (a conductive material) to the opaque part and/or the transparent part with respect to the above-described prescribed wavelength, and the second convex surface structure 50b is not provided.

Examples of the conductive paste 107 include Ag paste, Cu paste, and Au paste.

The surface emitting device 10-5 is a back-emitting surface emitting laser that emits light to the back (bottom) side of the substrate 50.

In the surface emitting device 10-5, as an example, the concave mirror 201 is provided near the top of the first convex surface structure 50a. The cathode electrode 202 is provided on the back surface of the substrate 50 in the periphery of the region provided with the concave mirror 201.

In the surface emitting device 10-5, as an example, the lower part of the anode electrode 103 is provided between the first transparent conductive film 104 and the insulating layer 106.

### <<Operation of Surface Emitting Device>>

The surface emitting device 10-5 operates substantially in the same manner as the surface emitting device 10-1 according to Example 1.

### <<Method for Manufacturing Surface Emitting Device>>

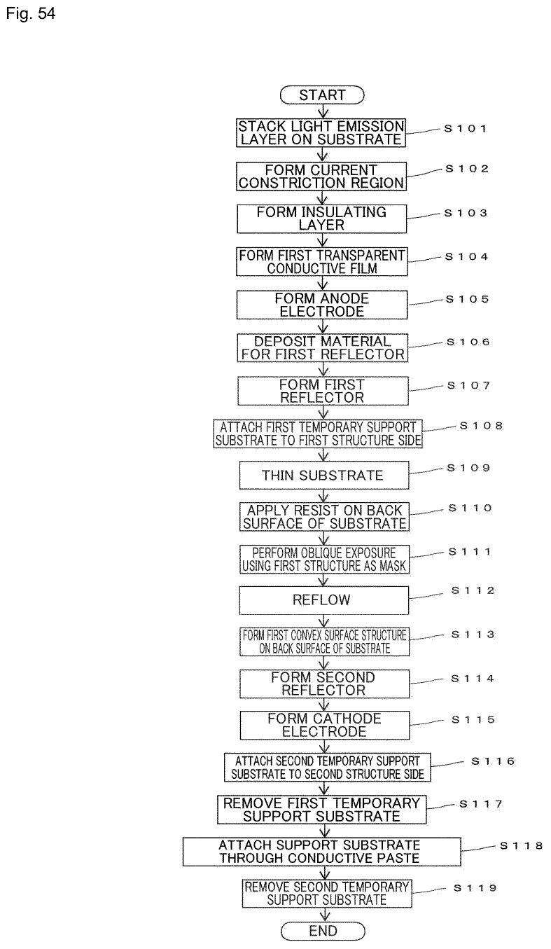

Hereinafter, a method for manufacturing the surface emitting device 10-5 will be described with reference to the flowchart in FIG. 54. Here, as an example, a plurality of surface emitting devices 10-5 are simultaneously produced on a single wafer (a semiconductor substrate (such as an n-GaN substrate)) that is to be a base material for the substrate 50. Then, the plurality of surface emitting devices 10-5 in an integral form are separated from each other to obtain chip-shaped surface emitting devices 10-5 (surface emitting device chips).

In the first step S101, the light emission layer 101 (active layer) is stacked on the substrate 50 (see FIG. 4A). Specifically a laminate is produced by stacking the light emission layer 101 on the substrate 50 in a growth chamber by metal organic chemical vapor deposition (MOCVD) or molecular beam epitaxy (MBE).

In the next step S102, the current constriction region 300 is formed (see FIG. 4B). Specifically to start with, a protection film for example made of resist and SiO₂ is formed to cover the part of the laminate other than the part where the current constriction region 300 is to be formed (the part where the current injection region is to be formed). During the process, the protection film is formed so that the center of the current injection region is at a position apart from the center of gravity G1 of the first structure ST1 by Δd in the +X direction in plan view. Then, using the protection film as a mask, ions (for example, B++) are implanted into the laminate from the side of the light emission layer 101. In this case, the ions are implanted to such a depth that they reach inside of the substrate 50.

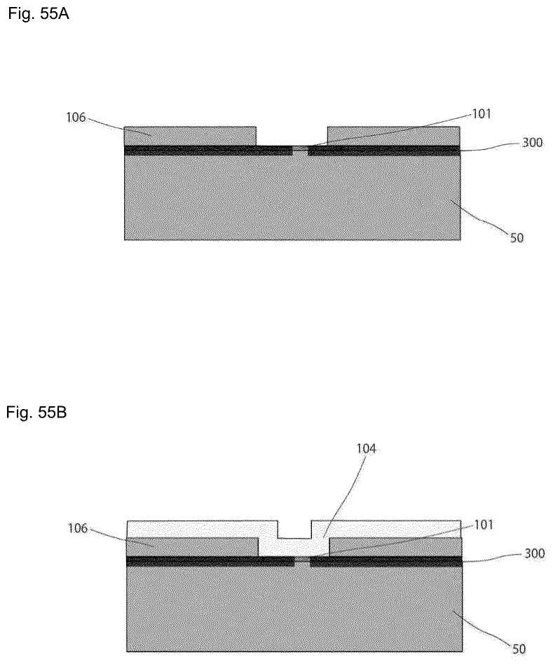

In the next step S103, the insulating layer 106 is formed. Specifically to start with, the insulating layer 106 is deposited on the entire surface for example by vacuum evaporation or sputtering (see FIG. 5A). Then, a center part of the insulating layer 106 is removed by photolithography to form the insulating layer 106 in an annular shape (see FIG. 55A).

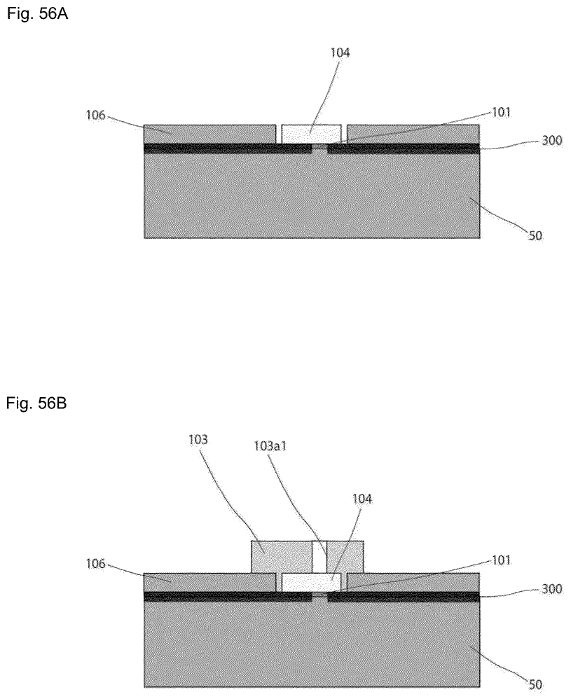

In the next step S104, the first transparent conductive film 104 is formed. Specifically to start with, a transparent conductive film, which is a material for the first transparent conductive film 104 is deposited on the entire surface for example by vacuum evaporation or sputtering (see FIG. 55B). Then, the first transparent conductive film 104 is formed by removing a peripheral part of the transparent conductive film by photolithography (see FIG. 56A). During the process, a peripheral part of the transparent conductive film is removed so that a gap is formed between the first transparent conductive film 104 and the insulating layer 106.

In the next step S105, the anode electrode 103 is formed (see FIG. 56B). Specifically the anode electrode 103 is formed for example by lift-off During the process, the anode electrode 103 is formed so that the center of the through hole 103a1 of the anode electrode 103 and the center of the current injection region are substantially coincident in plan view. An electrode material for the anode electrode 103 is deposited for example by vacuum evaporation or sputtering.

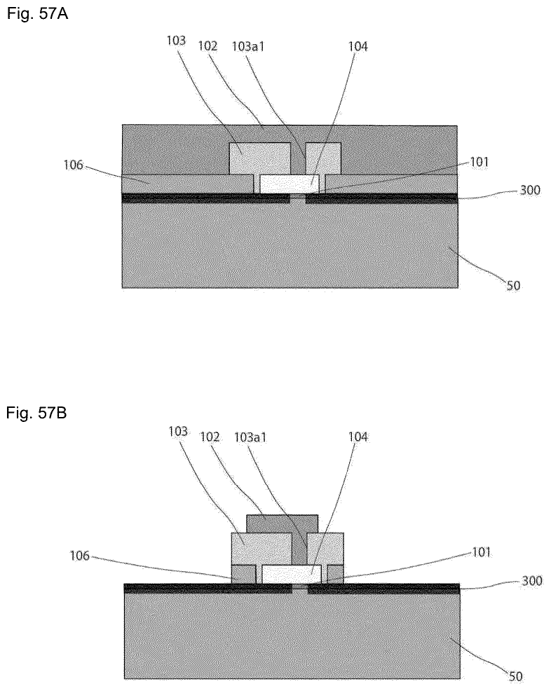

In the next step S106, a material for the reflector 102 as the first reflector is deposited (see FIG. 57A). Specifically a dielectric multilayer film which is the material for the reflector 102 (for example, plane mirror) is deposited on the entire surface for example by vacuum evaporation, sputtering or CVD.

In the next step S107, the reflector 102 as the first reflector is formed (see FIG. 57B). Specifically, the part of the dielectric multilayer film other than the part that is to be the reflector 102 is removed by photolithography to form the reflector 102. During the process, the corresponding part of the insulating layer 106 is also removed.

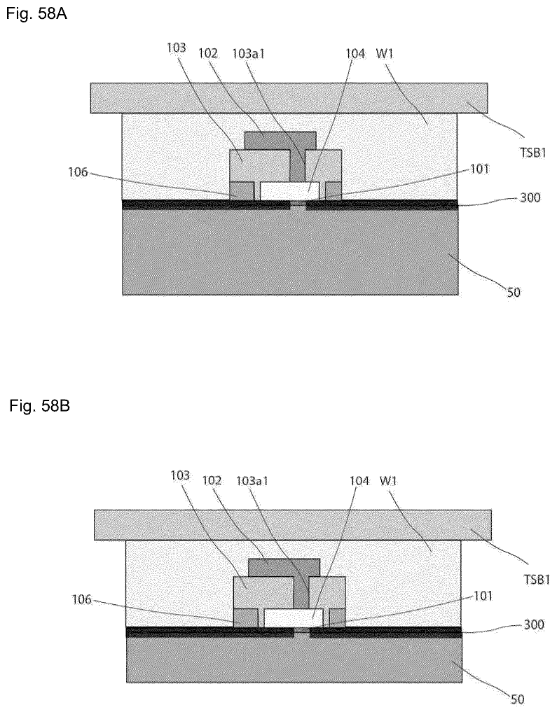

In the next step S108, the first temporary support substrate TSB1 is attached to the side of the first structure ST1 (see FIG. 58A). Specifically, the first temporary support substrate TSB1 (such as a sapphire substrate) is attached to the side of the first structure ST1 via wax W1.

In the next step S109, the substrate 50 is thinned (see FIG. 58B). Specifically, the substrate 50 is thinned by polishing the back surface of the substrate 50 using for example a CMP (chemical mechanical polishing) device.

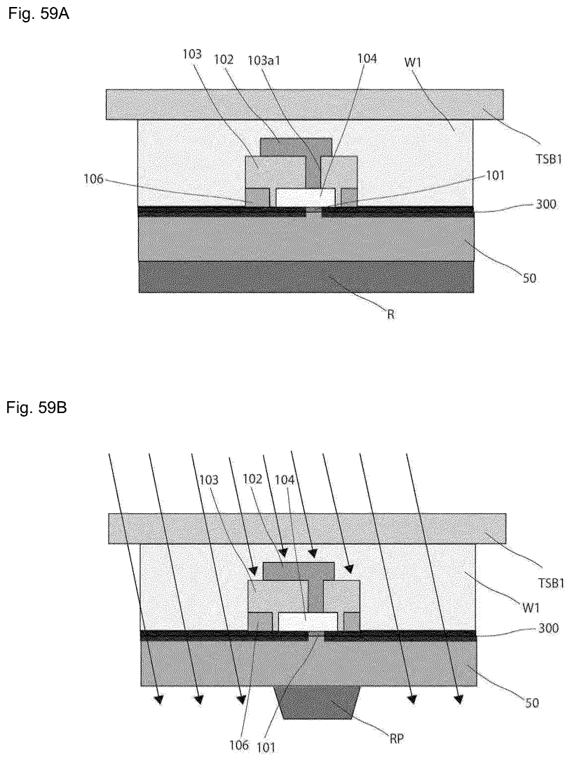

In the next step S110, resist R (such as positive photoresist) is applied to the back surface of the substrate 50 (see FIG. 59A). Specifically the resist R is applied flat on the back surface of the substrate 50.

In the next step S111, oblique exposure is performed using the first structure ST1 as a mask (see FIG. 59B). Specifically to start with, exposure light with the above-described prescribed wavelength (exposure wavelength) is obliquely entered at a prescribed angle of incidence θ along an XZ plane (see FIG. 53A) from the side of the first structure ST1 by an exposure device. The exposure light is blocked by the anode electrode 103 and the reflector 102 which are opaque parts with respect to the prescribed wavelength and transmitted through the first transparent conductive film 104 which is transparent with respect to the prescribed wavelength. As a result, a latent image corresponding to the mask pattern of the first structure ST1 is formed on the resist R. Then, the resist R is immersed in a developing solution to reveal the latent image. As a result, the resist pattern RP is formed by the parts not irradiated with the exposure light. The resist pattern RP has a substantially similar form in plan view to the first structure ST1, and its center of gravity does not coincide with that of the first structure ST1. Here, the angle of incidence θ corresponding to the distance D and Δd is selected to shift the center of gravity of the resist pattern RP from the center of gravity G1 of the first structure ST1 in the +X direction by Δd in plan view. The angle of incidence θ is preferably set while directly measuring the angle of incidence of the exposure light emitted from the exposure device and entered on the first structure ST1.

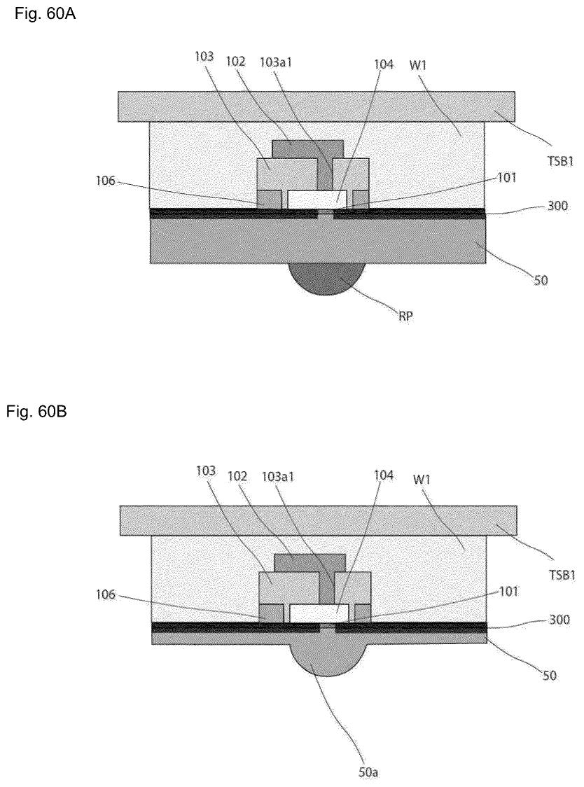

In the next step S112, reflow is performed (see FIG. 60A). Specifically the resist pattern balls up by reflow (for example at 200° C.) and is formed into a substantially hemispherical convex surface shape.

In the next step S113, the first convex surface structure 50a is formed on the back surface of the substrate 50 (see FIG. 60B). Specifically, the first convex surface structure 50a is formed by etching (for example by dry etching) the substrate 50 using the balled-up resist pattern RP as a mask.

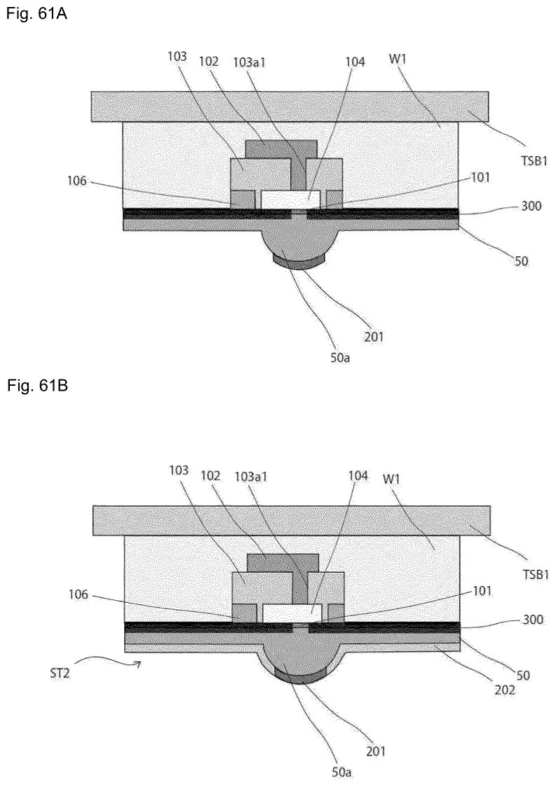

In the next step S114, the concave mirror 201 as the second reflector is formed (see FIG. 61A). Specifically, to start with, a dielectric multilayer film, which is a material for the concave mirror 201 is deposited on the entire surface for example by vacuum evaporation, sputtering or CVD. Then, the dielectric multilayer film around the top of the first convex surface structure 50a is removed by photolithography.

In the next step S115, the cathode electrode 202 is formed (see FIG. 61B). Specifically the cathode electrode 202 is formed around the concave mirror 201 on the back surface of the substrate 50 for example by lift-off. During the process, an electrode material for the cathode electrode 202 is deposited for example by vacuum evaporation or sputtering.

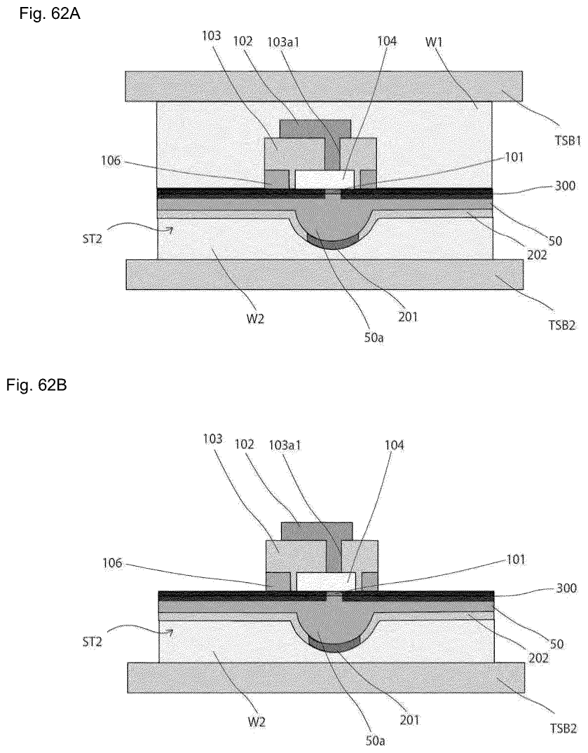

In the next step S116, the second temporary support substrate TSB2 is attached to the side of the second structure ST2 (see FIG. 62A). Specifically the second temporary support substrate TSB2 is attached to the side of the second structure ST2 through wax W2.

In the next step S117, the first temporary support substrate TSB1 is removed (see FIG. 62B). Specifically the wax W1 is dissolved by heating, and the first temporary support substrate TSB1 and the wax W1 are removed.

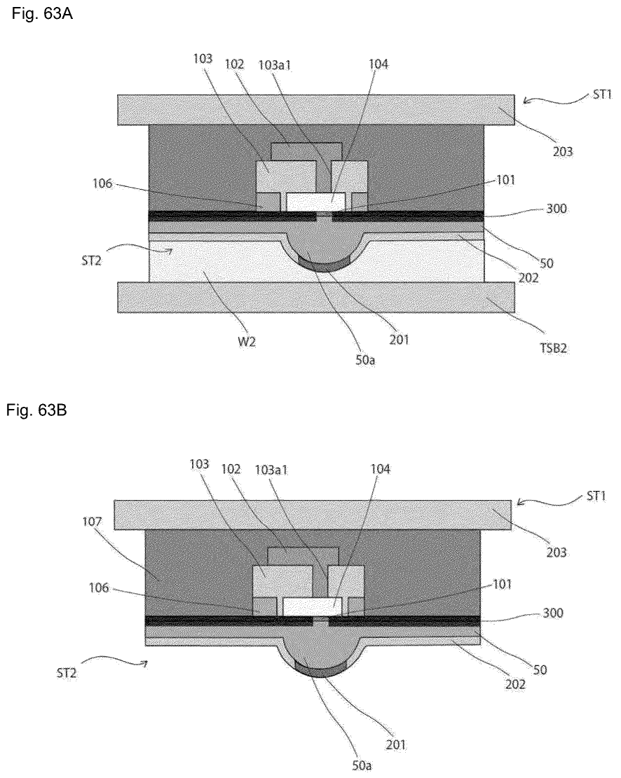

In the next step S118, the support substrate 203 is attached to the opaque and/or transparent parts with respect to the above-described prescribed wavelength through conductive paste 107 (see FIG. 63A).

In the final step S119, the second temporary support substrate TSB2 is removed. Specifically the wax W2 is dissolved by heating, and the second temporary support substrate TSB2 and the wax W2 are removed. As a result, a plurality of surface emitting devices 10-5 are produced on the wafer (a semiconductor substrate (such as an n-GaN substrate)). Thereafter, the plurality of surface emitting devices 10-5 in an integral form are separated by dicing to obtain chip-shaped surface emitting devices 10-5 (surface emitting device chips).

### <<Advantageous Effects of Surface Emitting Device>>

In the surface emitting device 10-5, the heat dissipation of heat generated in the light emission layer 101 can be improved because the opaque and/or transparent parts with respect to the above-described prescribed wavelength and the support substrate 203 are bonded through the conductive paste 107.

### 6. SURFACE EMITTING DEVICE ACCORDING TO EXAMPLE 6 OF THE EMBODIMENT OF THE PRESENT TECHNOLOGY AND A LIGHT SOURCE DEVICE INCLUDING THE SURFACE EMITTING DEVICE

Hereinafter, a surface emitting device according to Example 6 of the embodiment of the present technology and a light source device including the surface emitting device will be described with reference to the drawings.

### <<Configurations of Surface Emitting Device and Light Source Device>>

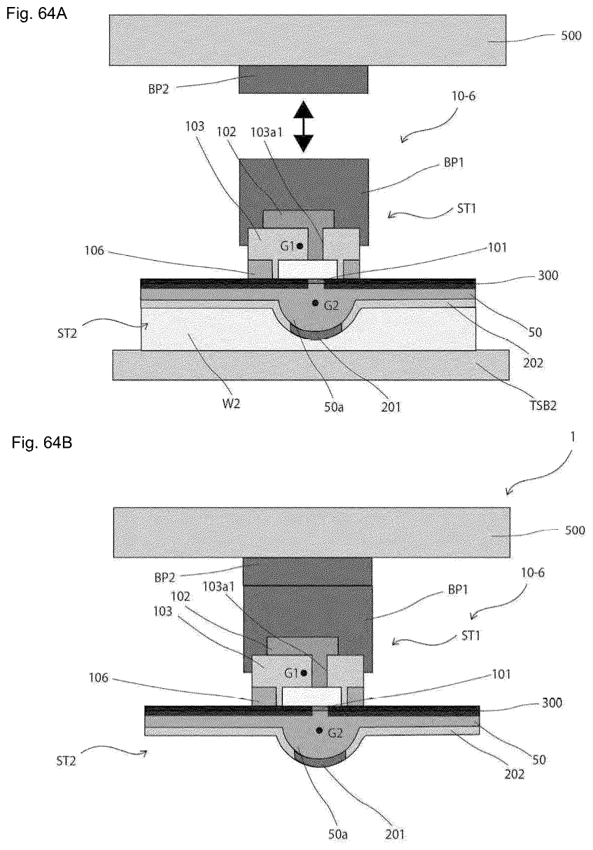

FIG. 64A is a cross-sectional view of a light source device 1 including a surface emitting device 10-6 according to Example 6 of the embodiment of the present technology showing a state before flip chip connection. FIG. 64B is a cross-sectional view of a light source device 1 including the surface emitting device 10-6 according to Example 6 of the embodiment of the present technology.

The light source device 1 includes a plurality of the surface emitting devices 10-6 arranged in an array (only one surface emitting device 10-6 is shown in FIGS. 64A and 64B for the sake of convenience) and laser drivers 500 bonded with the first structures ST1 of the plurality of surface emitting devices 10-6 through conductive bumps.

The surface emitting device 10-6 has the same configuration as the surface emitting device 10-5 according to Example 5 except that a conductive bump BP1 is provided in the first structure ST1 instead of the conductive paste 107 and the support substrate 203. The conductive bump BP1 is for example made of Au.

A conductive bump BP2 is provided in the driver IC of the laser driver 500. The conductive bump BP2 is made of the same material as the conductive bump BP1 (for example, Au).

The surface emitting device 10-6 is flip-chip mounted (junction-down mounted) by metal-bonding (for example, Au—Au bonding) the conductive bumps BP1 and BP2 (see FIGS. 64A and 64B).

### <<Operation of Surface Emitting Device>>

Each of the surface emitting devices 10-6 operates substantially in the same manner as the surface emitting device 10-1 according to Example 1.

### <<Method for Manufacturing Surface Emitting Device>>

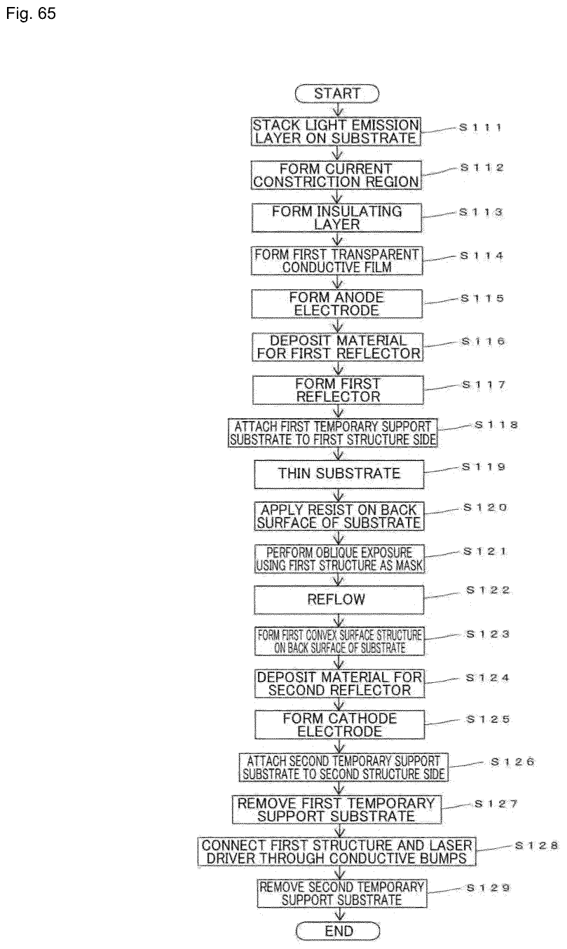

Hereinafter, a method for manufacturing the light source device 1 including the surface emitting devices 10-6 will be described for example with reference to the flowchart in FIG. 65. Here, as an example, a plurality of surface emitting devices 10-6 are simultaneously produced on a single wafer (a semiconductor substrate (such as an n-GaN substrate)) which is to be the substrate 50 (steps S111 to S127 in FIG. 65 (similar to steps S101 to S117 in FIG. 54)). Then, the first structure ST1 of each of the plurality of surface emitting devices 10-6 and the laser driver 500 are bonded together through the conductive bumps BP1 and BP2 (step S128, see FIG. 64A). Finally the second temporary support substrate TSB2 is removed (see step S128 in FIG. 64B).

### <<Advantageous Effects of Light Source Device>>

In the light source device 1, each of the plurality of surface emitting devices 10-6 is junction-down mounted and can be individually driven.

### 7. SURFACE EMITTING DEVICE ARRAY INCLUDING MULTIPLE SURFACE EMITTING DEVICES ARRANGED IN AN ARRAY ACCORDING TO AN EMBODIMENT OF THE PRESENT TECHNOLOGY

Hereinafter, a surface emitting device array having a plurality of surface emitting devices arranged in an array according to an embodiment of the present technology will be described with reference to the drawings.

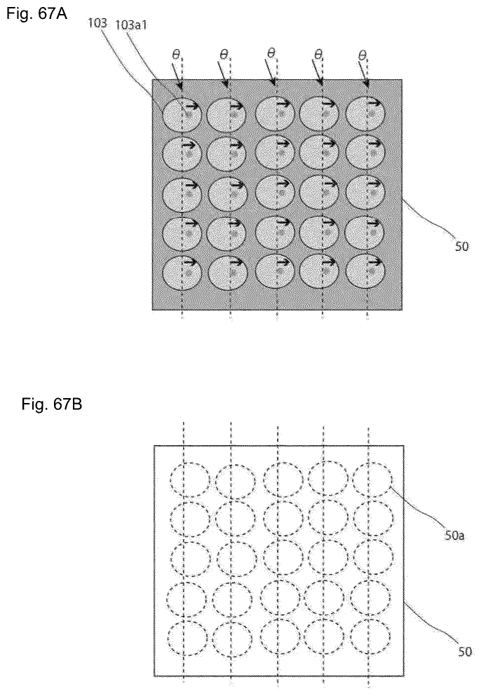

FIG. 67A is a plan view of an exemplary array configuration including a plurality of surface emitting devices arranged in an array according to the embodiment of the present technology FIG. 67B is a view of second structures in the surface emitting device array as viewed from the side of the first structures.

The surface emitting device array has a plurality of pairs of first and second structures ST1, the distances between the centers of gravity of the plurality of pairs of first and second structures ST1 and ST2 are substantially equal in plan view, and the separation directions of the centers of gravity of the plurality of pairs of first and second structures substantially coincide in plan view.

An example of a method for manufacturing the surface emitting device array will be briefly described. For example, photoresist coated on the (000-1) plane of the surface emitting device array for example having a thickness of 30 μm is exposed to light from the (0001) plane by an aligner and is patterned. At the time, the aligner tilts the ultraviolet light by 0.95° from the (000-1) plane in the [−12-10]direction due to the tilt of the mirror in the device. In this case, the angle of exposure (angle of incidence) is constant in all planes, so that the through-hole 103a1 of the anode electrode 103 of each surface emitting device can be formed at a position 0.5 μm apart from the center of the first transparent conductive film 104 in the [−12-10] direction.

In surface emitting device array the manners in which the centers of gravity of the surface emitting devices are displaced (the amount and direction of displacement) can be the same, so that the performance (laser characteristics) of the surface emitting devices can be made uniform.

### 8. SURFACE EMITTING DEVICE ACCORDING TO MODIFICATION 1 OF EXAMPLE 6 OF THE EMBODIMENT OF THE PRESENT TECHNOLOGY

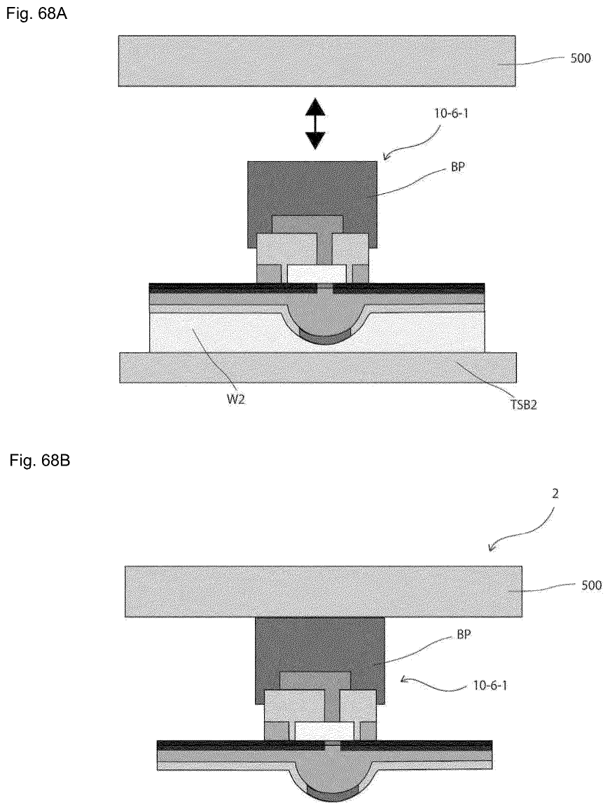

FIG. 68A is a cross-sectional view of a light source device including a surface emitting device 10-6-1 according to Modification 1 of Example 6 of the embodiment of the present technology showing a state before flip chip connection. FIG. 68B is a cross-sectional view of a light source device 2 including the surface emitting device 10-6-1 according to Modification 1 of Example 6 of the embodiment of the present technology.

As shown in FIGS. 68A and 68B, the light source device 2 including the surface emitting device 10-6-1 has the same configuration as the light source device 1 including the surface emitting device 10-6 according to Example 6, except that conductive bumps BP are provided only on the surface emitting device 10-6-1 before bonding.

### 9. SURFACE EMITTING DEVICE ACCORDING TO MODIFICATION 2 OF EXAMPLE 6 OF THE EMBODIMENT OF THE PRESENT TECHNOLOGY

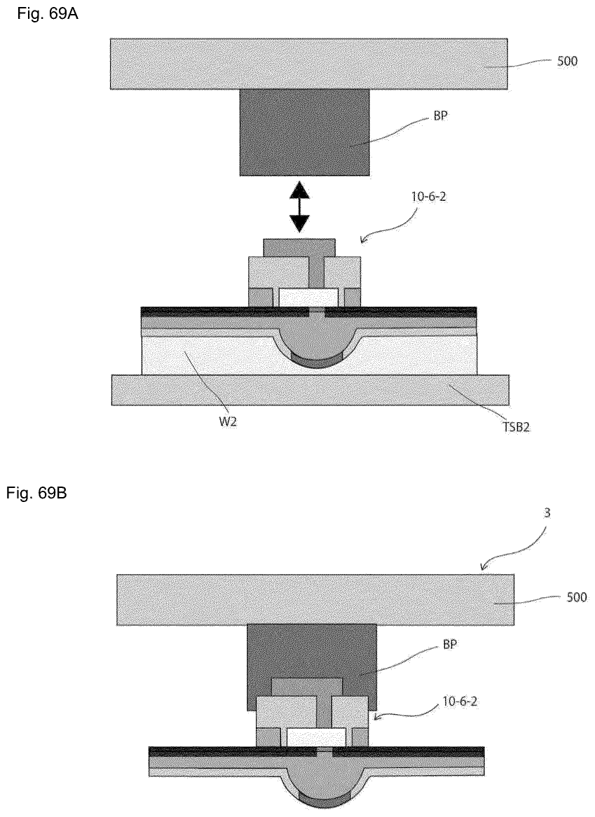

FIG. 69A is a cross-sectional view of a light source device including a surface emitting device 10-6-2 according to Modification 2 of Example 6 of the embodiment of the present technology showing a state before flip chip connection. FIG. 69B is a cross-sectional view of the light source device 2 including the surface emitting device 10-6-2 according to Modification 2 of Example 6 of the embodiment of the present technology.

As shown in FIGS. 69A and 69B, the light source device 3 including the surface emitting device 10-6-2 has the same configuration as the light source device 1 including the surface emitting device 10-6 according to Example 6, except that conductive bumps BP are provided only on the laser driver 500 before bonding.

### 10. SURFACE EMITTING DEVICE ACCORDING TO A MODIFICATION OF THE EMBODIMENT OF THE PRESENT TECHNOLOGY

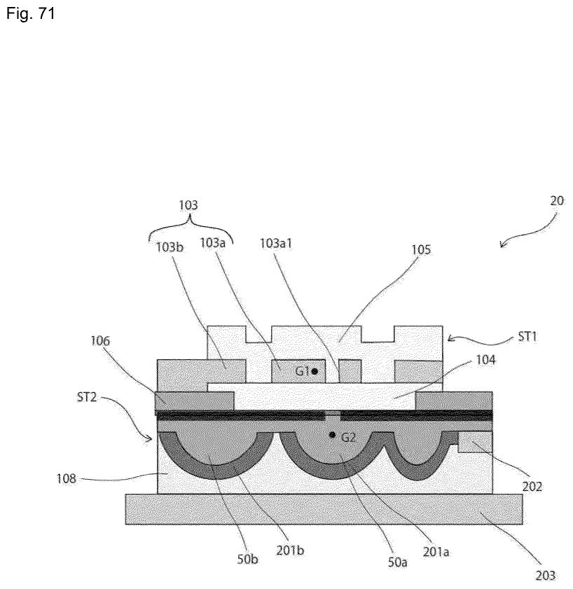

FIG. 71 is a cross-sectional view of a surface emitting device 20 according to a modification of the embodiment of the present technology. The surface emitting device 20 has substantially the same configuration as the surface emitting device according to the embodiment of the present technology except that the reflector 102 is not provided. In other words, the surface emitting device 20 is an LED (light emitting diode). In FIG. 71, wax is designated by reference 108. In the surface emitting device 20, when electric current is injected into the light emission layer 101, light emitted upwards from the light emission layer 101 is emitted externally through the through hole 103a1, and light emitted downwards from the light emission layer 101 is focused by the concave mirror 201a through the substrate 50 to for example the first transparent conductive film 104 or the through hole 103a1, and emitted externally through the through hole 103a1. At the time, the through-hole 103a1 serves as an aperture, so that the light emitted upward and downward from the light emission layer 101 can be emitted to the outside as broad light.

### 11. SURFACE EMITTING DEVICE ACCORDING TO A MODIFICATION OF EXAMPLE 1 OF THE EMBODIMENT OF THE PRESENT TECHNOLOGY

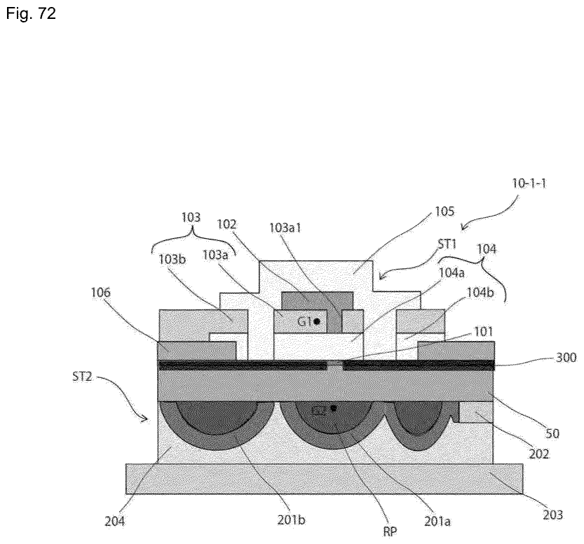

FIG. 72 is a cross-sectional view of a surface emitting device 10-1-1 according to a modification of Example 1 of the embodiment of the present technology. The surface emitting device 10-1-1 has the same configuration as the surface emitting device 10-1 according to Example 1 except that instead of the first convex surface structure 50a, a resist pattern RP is used as a base for the concave mirror 201a. In other words, in the surface emitting device 10-1-1, the second structure ST2 includes the resist pattern RP as a photosensitive material provided between the back surface of the substrate 50 and the concave mirror 201a.

In the surface emitting device 10-1-1, it is not necessary to form the first convex surface structure 50a, so that the manufacturing process can be simplified and the manufacturing cost can be reduced.

### 12. OTHER MODIFICATIONS OF THE PRESENT TECHNOLOGY

The present technology is not limited to the above examples and modifications, and various modifications are possible.

In each of the examples and modifications described above, the positive type resist is used in the manufacture of the surface emitting devices, but negative type resist can be used by reversing the parts of the first structure ST1 that are transparent and opaque with respect to the prescribed wavelength.

In each of the examples and modifications described above, the resist is used as a photosensitive material in the manufacture of the surface emitting device, but photocurable resin may also be used.

In each of the examples and modifications described above, the GaN substrate is used as the substrate 50, but alternatively a GaAs substrate or InP substrate may be used. When for example a GaAs substrate is used as the substrate 50, an oxidation constriction region may be used as the current constriction region.

The conductivity types (p-type and n-type) of the layers of the surface emitting devices according to the examples and modifications may be reversed.

Parts of the configurations of the surface-emitting devices according to the above examples and modifications may be combined to such an extent that there are no contradictions between each other.

In the examples and modifications described above, for example the material, thickness, width, length, shape, size, and arrangement of each of the elements of the surface emitting devices may be changed as appropriate, provided that the resulting device can function as the surface emitting device.

### 13. EXAMPLE OF APPLICATION TO ELECTRONIC DEVICE

The technology according to the present disclosure (present technology) can be applied to various products. For example, the technology according to the present disclosure may be implemented as an apparatus (such as a distance measurement device and a form recognition device) mounted on any kind of mobile object such as an automobile, an electric vehicle, a hybrid electric vehicle, a motorcycle, a bicycle, a personal mobility an airplane, a drone, a ship, and a robot.

The surface emitting device according to the present technology may be applied for example as a light source for a device that forms or displays images using laser light (such as a laser printer, a laser copier, a projector, a head-mounted display and a head-up display), or as a display itself.

### 14. EXAMPLE OF APPLICATION OF THE SURFACE EMITTING DEVICE TO A DISTANCE MEASUREMENT DEVICE

Hereinafter, an example of application of surface emitting devices according to the embodiments and modifications described above will be described.

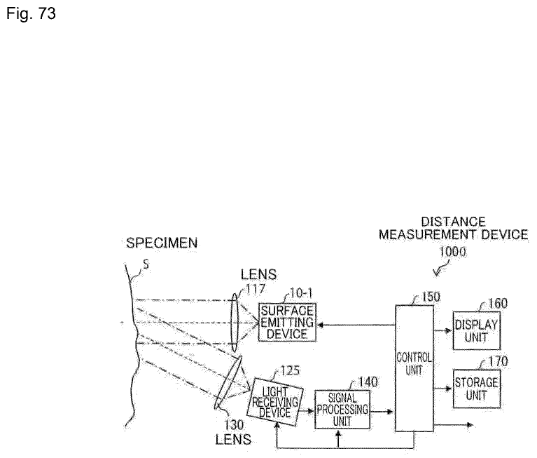

FIG. 73 illustrates an example of a general configuration of a distance measurement device (ranging device) 1000 including the surface emitting device 10-1 as an example of an electronic device according to the present technology.

The distance measurement device 1000 measures the distance to a specimen S by the TOF (Time Of Flight) method. The distance measurement device 1000 includes the surface emitting device 10-1 as a light source. The distance measurement device 1000 may include the surface emitting device 10-1, a light receiving device 125, lenses 117 and 130, a signal processing unit 140, a control unit 150, a display unit 160, and a storage unit 170.

The surface emitting device 10-1 is driven by a laser driver. The laser driver has an anode terminal and a cathode terminal connected to the anode electrode and the cathode electrode, respectively of the surface emitting device 10-1 through wiring or conductive bumps. The laser driver for example includes circuit elements such as a capacitor and a transistor.

The light receiving device 125 detects light reflected by the specimen S. The lens 117 is a collimating lens that collimates light emitted from the surface emitting device 10-1 into parallel light. The lens 130 is a collection lens that collects light reflected by the specimen S and guides the light to the light receiving device 125.

The signal processing unit 140 is a circuit that generates a signal corresponding to the difference between a signal input from the light receiving device 125 and a reference signal input from the control unit 150. The control unit 150 includes a Time-to-Digital converter (TDC). The reference signal may be a signal input from the control unit 150 or an output signal from a detection unit that directly detects an output from the surface emitting device 10-1. The control unit 150 is for example a processor that controls the surface emitting device 10-1, the light receiving device 125, the signal processing unit 140, the display unit 160 and the storage unit 170. The control unit 150 is a circuit that measures the distance to the specimen S on the basis of a signal generated by the signal processing unit 140. The control unit 150 generates a video signal for indicating information about the distance to the specimen S and outputs the generated signal to the display unit 160. The display unit 160 displays information about the distance to the specimen S on the basis of the video signal input from the control unit 150. The control unit 150 stores information about the distance to the specimen S in the storage unit 170.

In this application example, instead of the surface emitting device 10-1, any of the above-described surface emitting devices 10-2, 10-3, 10-4, 10-5, 10-6, 10-6-1, 10-6-2, 20, 10-1-1, and the light source devices 1, 2 and 3 can also be applied to the distance measurement device 1000.

### 15. EXAMPLE OF A DISTANCE MEASUREMENT DEVICE PROVIDED IN A MOBILE OBJECT

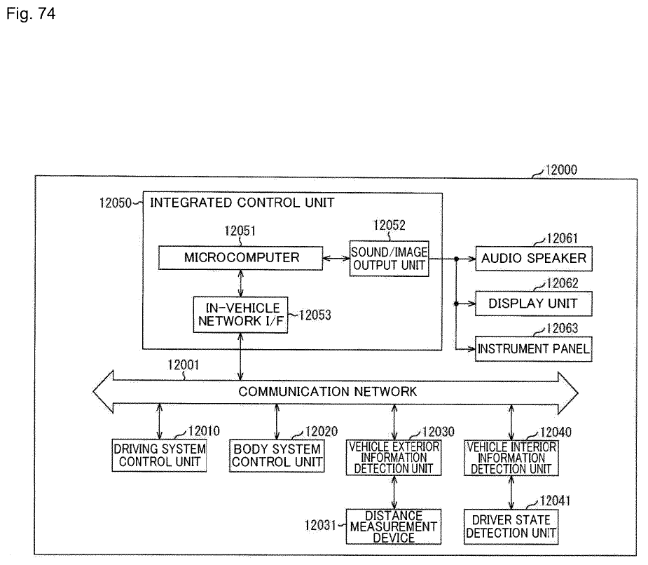

FIG. 74 is a block diagram illustrating a schematic configuration example of a vehicle control system, which is an example of a mobile object control system to which the technology according to the present disclosure can be applied.

The vehicle control system 12000 includes a plurality of electronic control units connected thereto via a communication network 12001. In the example illustrated in FIG. 74, the vehicle control system 12000 includes a drive system control unit 12010, a body system control unit 12020, a vehicle exterior information detection unit 12030, a vehicle interior information detection unit 12040, and an integrated control unit 12050. In addition, as a functional configuration of the integrated control unit 12050, a microcomputer 12051, a sound/image output unit 12052, and an in-vehicle network interface (I/F) 12053 are illustrated.

The drive system control unit 12010 controls the operation of an apparatus related to a drive system of a vehicle according to various programs. For example, the drive system control unit 12010 functions as a driving force generator for generating a driving force of a vehicle such as an internal combustion engine or a driving motor, a driving force transmission mechanism for transmitting a driving force to wheels, a steering mechanism for adjusting a turning angle of a vehicle, and a control apparatus such as a braking apparatus that generates a braking force of a vehicle.

The body system control unit 12020 controls operations of various devices mounted in the vehicle body according to various programs. For example, the body system control unit 12020 functions as a control device of a keyless entry system, a smart key system, a power window device, or various lamps such as a headlamp, a back lamp, a brake lamp, a turn signal, and a fog lamp. In this case, radio waves transmitted from a portable device that substitutes for a key or signals of various switches may be input to the body system control unit 12020. The body system control unit 12020 receives inputs of the radio waves or signals and controls a door lock device, a power window device, and a lamp of the vehicle.

The vehicle exterior information detection unit 12030 detects information outside of the vehicle provided with the vehicle control system 12000. For example, the vehicle exterior information detection unit 12030 is connected with the distance measurement device 12031. The distance measurement device 12031 includes the distance measurement device 1000 described above. The vehicle exterior information detection unit 12030 has the distance measurement device 12031 measure the distance to an object (specimen S) outside of the vehicle and obtains the resulting distance data. The vehicle exterior information detection unit 12030 may perform object detection processing for example for people, vehicles, obstacles, and signs on the basis of the obtained distance data.

The vehicle interior information detection unit 12040 detects information on the inside of the vehicle. For example, a driver state detection unit 12041 that detects a driver's state is connected to the vehicle interior information detection unit 12040. The driver state detection unit 12041 includes, for example, a camera that captures an image of a driver, and the vehicle interior information detection unit 12040 may calculate a degree of fatigue or concentration of the driver or may determine whether or not the driver is dozing on the basis of detection information input from the driver state detection unit 12041.

The microcomputer 12051 can calculate a control target value of the driving force generation device, the steering mechanism, or the braking device on the basis of information inside and outside of the vehicle acquired by the vehicle exterior information detection unit 12030 or the vehicle interior information detection unit 12040, and output a control command to the drive system control unit 12010. For example, the microcomputer 12051 can perform cooperative control for the purpose of realizing functions of an ADAS (advanced driver assistance system) including vehicle collision avoidance, impact mitigation, following traveling based on an inter-vehicle distance, vehicle speed maintenance driving, vehicle collision warning, vehicle lane deviation warning, and the like.

Further, the microcomputer 12051 can perform cooperative control for the purpose of automated driving or the like in which autonomous travel is performed without depending on operations of the driver, by controlling the driving force generator, the steering mechanism, or the braking device and the like on the basis of information about the surroundings of the vehicle, the information being acquired by the vehicle exterior information detection unit 12030 or the vehicle interior information detection unit 12040.

In addition, the microcomputer 12051 can output a control command to the body system control unit 12020 based on the information acquired by the vehicle exterior information detection unit 12030 outside of the vehicle. For example, the microcomputer 12051 can perform cooperative control for the purpose of preventing glare, such as switching from a high beam to a low beam, by controlling the headlamp according to the position of a preceding vehicle or an oncoming vehicle detected by the vehicle exterior information detection unit 12030.

The sound/image output unit 12052 transmits an output signal of at least one of sound and an image to an output device capable of visually or audibly notifying a passenger or the outside of the vehicle of information. In the example in FIG. 74, an audio speaker 12061, a display unit 12062, and an instrument panel 12063 are illustrated as examples of the output device. The display unit 12062 may include for example at least one of an on-board display and a head-up display.

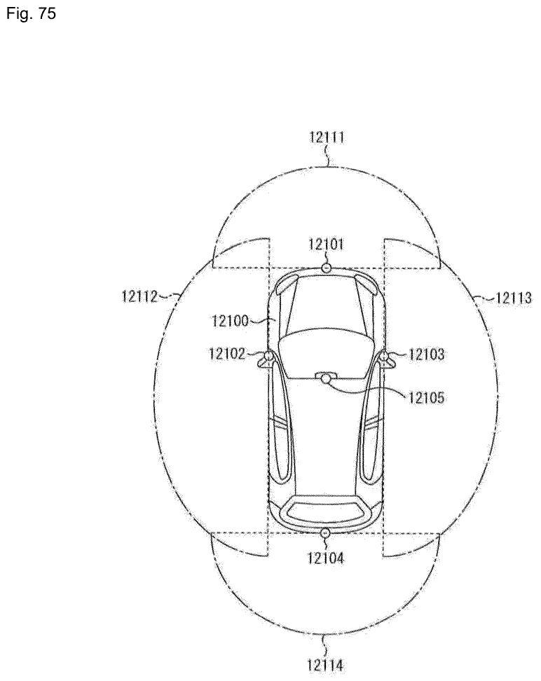

FIG. 75 is a diagram showing an example of an installation position of the distance measurement device 12031.

In FIG. 75, a vehicle 12100 includes distance measurement devices 12101, 12102, 12103, 12104, and 12105 as the distance measurement device 12031.

The distance measurement devices 12101, 12102, 12103, 12104, and 12105 are provided for example at positions of a front nose, sideview mirrors, a rear bumper, a back door, an upper portion of a vehicle internal front windshield, and the like of the vehicle 12100. The distance measurement device 12101 provided on a front nose and the distance measurement device 12105 provided in an upper portion of the vehicle internal front windshield mainly acquire data on an area in front of the vehicle 12100. The distance measurement devices 12102 and 12103 provided in the sideview mirrors mainly acquire data on areas on the sides of the vehicle 12100. The distance measurement device 12104 provided in the rear bumper or the back door mainly acquires data on an area behind the vehicle 12100. The data on the front area acquired by the distance measurement devices 12101 and 12105 are mainly used for detection of preceding vehicles, pedestrians, obstacles, traffic lights, traffic signs, and the like.

FIG. 75 illustrates an example of detection ranges by the distance measurement devices 12101 to 12104. A detection range 12111 indicates a detection range by the distance measurement device 12101 provided at the front nose, detection ranges 12112 and 12113 respectively indicate detection ranges by the distance measurement devices 12102 and 12103 provided at the side-view mirrors, and a detection range 12114 indicates a detection range by the distance measurement device 12104 provided at the rear bumper or the back door.

For example, the microcomputer 12051 can extract, particularly a closest three-dimensional object on a path through which the vehicle 12100 is traveling, which is a three-dimensional object traveling at a prescribed speed (for example, 0 km/h or higher) in the substantially same direction as the preceding vehicle 12100, as a vehicle ahead by obtaining a distance to each three-dimensional object in the detection ranges 12111 to 12114 and temporal change in the distance (a relative speed with respect to the vehicle 12100) based on distance data obtained from the distance measurement devices 12101 to 12104. The microcomputer 12051 can also set a following distance to the vehicle ahead to be maintained in advance and perform automatic brake control (including following stop control) and automatic acceleration control (including following start control). Thus, it is possible to perform cooperative control for the purpose of, for example, automated driving in which the vehicle travels in an automated manner without requiring the driver to perform operations.

For example, the microcomputer 12051 can classify and extract three-dimensional data regarding three-dimensional objects into two-wheeled vehicles, normal vehicles, large vehicles, pedestrians, and other three-dimensional objects such as electric poles based on distance data obtained from the distance measurement devices 12101 to 12104 and can use the three-dimensional data to perform automated avoidance of obstacles. For example, the microcomputer 12051 identifies obstacles in the vicinity of the vehicle 12100 into obstacles that can be visually recognized by the driver of the vehicle 12100 and obstacles that are difficult to be visually recognized by the driver. Then, the microcomputer 12051 can determine a risk of collision indicating the degree of risk of collision with each obstacle and can perform driving assistance for collision avoidance by outputting a warning to the driver through the audio speaker 12061 or the display unit 12062 and performing forced deceleration or avoidance steering through the drive system control unit 12010 when the risk of collision has a value equal to or greater than a set value and there is a possibility of collision.

An example of the mobile object control system to which the technology according to the present disclosure can be applied has been described above. The technology according to the present disclosure can be applied to the distance measurement device 12031 among the configurations described above.

In addition, the present technology can also have the following configurations.

(1) A surface emitting device including a substrate;
a first structure provided on one surface of the substrate and including a light emission layer; and
a second structure provided on another surface of the substrate and including a concave mirror,
wherein
the substrate is transparent with respect to a prescribed wavelength,
the first structure has an opaque part and a transparent part with respect to the prescribed wavelength,
the first and second structures have substantially similar forms in plan view, and their centers of gravity are not coincident.

(2) The surface emitting device according to (1), wherein the distance between a center of the light emission region of the light emission layer and a center of the concave mirror is shorter than the distance between the centers of gravity of the first and second structures in plan view.

(3) The surface emitting device according to (1) or (2), wherein the distance between the centers of gravity of the first and second structures is at least 50 nm in plan view.

(4) The surface emitting device according to (1) to (3), wherein the distance between a center of the light emission region of the light emission layer and a center of the concave mirror is at most 500 nm in plan view.

(5) The surface emitting device according to any one of (1) to (4), wherein the second structure has a plan view shape which is a Fourier transformed shape of a plan view shape of the first structure.

(6) The surface emitting device according to any one of (1) to (5), wherein the second structure has a plan view shape which is a similar form to a Fourier transformed shape of a plan view shape of the first structure, with a coefficient of determination of at least 70%.

(7) The surface emitting device according to any one of (1) to (6), wherein the opaque part has first and second parts arranged in an in-plane direction.

(8) The surface emitting device according to (7), wherein the second part surrounds the first part.

(9) The surface emitting device according to (7) or (8), wherein the opaque part has a connection part which connects the first and second parts.

(10) The surface emitting device according to (9), wherein the connection part overlaps at least one of the first and second parts.

(11) The surface emitting device according to any one of (1) to (10), wherein the first structure has a support substrate connected through a conductive material to the opaque part and/or the transparent part.

(12) The surface emitting device according to any one of (1) to (11) wherein the opaque part is made of dielectric or a metal.

(13) The surface emitting device according to any one of (1) to (12), wherein the second structure includes a photosensitive material provided between the other surface and the concave mirror.

(14) The surface emitting device according to any one of (1) to (13), wherein the other surface has a convex surface structure, and the concave mirror is provided along the convex surface structure.

(15) The surface emitting device according to (1), including a plurality of pairs of the first and second structures, wherein the distances between centers of gravity of the plurality of pairs of the first and second structures are substantially equal in plan view, and separation directions of the centers of gravity of the plurality of pairs of the first and second structures substantially coincide in plan view.

(16) The surface emitting device according to any one of (1) to (15), wherein the first structure includes a reflector provided on a side of the light emission layer opposite to the concave mirror.

(17) A light source device including the surface emitting device according to any one of (1) to (16), and a laser driver connected to the first structure of the surface emitting device through a conductive bump.

(18) A method for manufacturing a surface emitting device including: forming a first structure including a light emission layer on one surface of a substrate transparent to a prescribed wavelength, the first structure having an opaque part and a transparent part with respect to the prescribed wavelength;
applying a photosensitive material on another surface of the substrate;
performing oblique exposure with light having the prescribed wavelength from the side of the first structure; and
forming a second structure including a concave mirror using a pattern formed on the photosensitive material.

(19) The method for manufacturing the surface emitting device according to (18), wherein the first structure includes a current constriction region that defines a light emission region of the light emission layer, and informing the first structure, the current constriction region is formed so that the light emission region is in a position corresponding to an exposure condition in the oblique exposure and a total of the thickness of the first structure and the thickness of the substrate.

(20) The method for manufacturing the surface emitting device according to (19), wherein the exposure condition is set according to the total or the total is set according to the exposure condition.

### REFERENCE SIGNS LIST

10-1, 10-1-1, 10-2, 10-3, 10-4, 10-5, 10-6, 10-6-1, 10-6-2, 20 Surface emitting device
50 Substrate
50a First convex surface structure
101 Light emission layer
102 Reflector (opaque part)
103 Anode electrode (opaque part)
103a First electrode pad (first part)
103b Second electrode pad (second part)
103c Connection part
104 First transparent conductive film (transparent part)
105 Second transparent conductive film (transparent part)
107 Conductive paste (conductive material)
201, 201a Concave mirror
203 Support substrate
300 Current constriction region
ST1 First structure
ST2 Second structure
G1 Center of gravity of first structure
G2 Center of gravity of second structure
RP Resist pattern (photosensitive material)

1. A surface emitting device comprising:
a substrate;
a first structure provided on one surface of the substrate and including a light emission layer; and
a second structure provided on another surface of the substrate and including a concave mirror,
wherein
the substrate is transparent with respect to a prescribed wavelength,
the first structure has an opaque part and a transparent part with respect to the prescribed wavelength,
the first and second structures have substantially similar forms in plan view, and their centers of gravity are not coincident.

2. The surface emitting device according to claim 1, wherein the distance between a center of a light emission region of the light emission layer and a center of the concave mirror is shorter than the distance between the centers of gravity of the first and second structures in plan view.

3. The surface emitting device according to claim 1, wherein the distance between the centers of gravity of the first and second structures is at least 50 nm in plan view.

4. The surface emitting device according to claim 1, wherein the distance between a center of a light emission region of the light emission layer and a center of the concave mirror is at most 500 nm in plan view.

5. The surface emitting device according to claim 1, wherein the second structure has a plan view shape which is a Fourier transformed shape of a plan view shape of the first structure.

6. The surface emitting device according to claim 1, wherein the second structure has a plan view shape which is a similar form to a Fourier transformed shape of a plan view shape of the first structure, with a coefficient of determination of at least 70%.

7. The surface emitting device according to claim 1, wherein the opaque part has first and second parts arranged in an in-plane direction.

8. The surface emitting device according to claim 7, wherein the second part surrounds the first part.

9. The surface emitting device according to claim 7, wherein the opaque part has a connection part which connects the first and second parts.

10. The surface emitting device according to claim 9, wherein the connection part overlaps at least one of the first and second parts.

11. The surface emitting device according to claim 1, wherein the first structure has a support substrate connected through a conductive material to the opaque part and/or the transparent part.

12. The surface emitting device according to claim 1, wherein the opaque part is made of dielectric or a metal.

13. The surface emitting device according to claim 1, wherein the second structure includes a photosensitive material provided between the other surface and the concave mirror.

14. The surface emitting device according to claim 1, wherein the other surface has a convex surface structure, and
the concave mirror is provided along the convex surface structure.

15. The surface emitting device according to claim 1, comprising a plurality of pairs of the first and second structures, wherein
the distances between centers of gravity of the plurality of pairs of the first and second structures are substantially equal in plan view, and separation directions of the centers of gravity of the plurality of pairs of the first and second structures substantially coincide in plan view.

16. The surface emitting device according to claim 1, wherein the first structure includes a reflector provided on a side of the light emission layer opposite to the concave mirror.

17. A light source device comprising the surface emitting device according to claim 1, and
a laser driver connected to the first structure of the surface emitting device through a conductive bump.

18. A method for manufacturing a surface emitting device comprising:
forming a first structure including a light emission layer on one surface of a substrate transparent to a prescribed wavelength, the first structure having an opaque part and a transparent part with respect to the prescribed wavelength;
applying a photosensitive material on another surface of the substrate;
performing oblique exposure with light having the prescribed wavelength from the side of the first structure; and
forming a second structure including a concave mirror using a pattern formed on the photosensitive material.

19. The method for manufacturing the surface emitting device according to claim 18, wherein the first structure includes a current constriction region that defines a light emission region of the light emission layer, and
in forming the first structure, the current constriction region is formed so that the light emission region is in a position corresponding to an exposure condition in the oblique exposure and a total of the thickness of the first structure and the thickness of the substrate.

20. The method for manufacturing the surface emitting device according to claim 19, wherein the exposure condition is set according to the total or the total is set according to the exposure condition.
